(19) United States
(12) Patent Application Publication
(10) Pub. No.: US 2014/0117289 A1
(43) Pub. Date: May 1, 2014

(54) MATERIALS FOR ORGANIC ELECTROLUMINESCENT DEVICES

(71) Applicants: Junyou Pan, Frankfurt am Main (DE); Niels Schulte, Kelkheim (DE)

(72) Inventors: Junyou Pan, Frankfurt am Main (DE); Niels Schulte, Kelkheim (DE)

(73) Assignee: Merck Patent GmbH, Darmstadt (DE)

(21) Appl. No.: 14/126,500

(22) PCT Filed: May 18, 2012
(86) PCT No.: PCT/EP2012/002143

§ 371 Date: Dec. 16, 2013

(30) Foreign Application Priority Data
Jun. 17, 2011 (DE) 10 2011 104 745.3

(51) Int. Cl. H01L 51/00

(52) U.S. Cl. CPC H01L 51/0043
USPC 252/500; 528/7; 548/418; 548/405; 546/88

(57) ABSTRACT

The present invention describes copolymers containing indenocarbazole derivatives having electron- and hole-transporting properties, in particular for use in the interlayer, emission and/or charge-transport layer of electroluminescent devices, and the monomers which are necessary for the preparation of the copolymers. The invention furthermore relates to a process for the preparation of the copolymers according to the invention, and to electronic devices comprising same.

The present invention describes novel non-linear copolymers, in particular those having electronic charge-transport properties, which are particularly suitable for use in the interlayer, emission and/or charge-transport layer of electroluminescent devices, and the monomers which are necessary for the preparation of the copolymers. The invention furthermore relates to a process for the preparation of the copolymers according to the invention, and to electronic devices comprising same.

In the past, predominantly small molecules were employed as useful components, for example as phosphorescence emitters, in organic electroluminescent devices. The use of small molecules in organic electroluminescent devices (SMOLED) enables good colour efficiencies, long lifetimes and the requisite low operating voltages. However, the disadvantage of such systems is the complex production. Thus, for example, the deposition of layers of small molecules requires complex processes, such as, for example, thermal coating processes, which results in a limited maximum device size.

For some time, conjugated polymers having the corresponding properties have therefore been used for opto-electronic applications, since they can be applied easily and inexpensively as a layer by spin coating or print coating. Conjugated polymers have already been investigated intensively for some time as highly promising materials in OLEDs. OLEDs which comprise polymers as organic materials are frequently also known as PLEDs (PLED=polymer light emitting device). Their simple production holds the promise of inexpensive production of corresponding electroluminescent devices.

PLEDs consist either only of one layer, which is able to combine as far as possible all functions (charge injection, charge transport, recombination and emission) of an OLED in itself, or they consist of a plurality of layers which have the respective functions individually or partially combined. For the preparation of polymers having the corresponding properties, the polymerisation is carried out using different monomers which take on the corresponding functions. Thus, it is generally necessary for the generation of all three emission colours to copolymerise certain monomers into the corresponding polymers. In order to generate white light by light mixing, light in the three colours red, green and blue is required. In order to ensure high light efficiency, triplet emitters (phosphorescence) are preferred to weaker-light singlet emitters (fluorescence). In accordance with the prior art, conjugated polymers are only suitable as host materials for red- or yellow-emitting triplet emitters, but not for triplet emitters having relatively high energy (blue- or green-emitting triplet emitters), since the low triplet energies of the conjugated polymers quench the emission from any triplet emitters having relatively high energy (relatively short wavelengths). The main problem consists in that the “triplet energy” of the phosphorescence emitter is transferred back into the conjugated polymer if the triplet level of the polymer matrix is lower than that of the metal complex (see Evans et. al., “Triplet Energy Back Transfer in Conjugated Polymers with Pendant Phosphorecent Iridium Complexes”, J. Am. Chem. Soc., 128[20], 6647-6656, 2006). Conjugated polymers known to date, such as, for example, polyphenylenevinylenes, poly(para-phenylenes), polyfluorenes, always have the following linear structures (I), where A and B are recurring units which are conjugated in a rod shape, characterised in that the axes of the two recurring units A and B are along the backbone of the polymer.

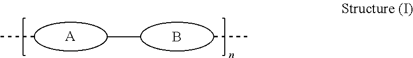

Polymers conjugated in this way usually have a low triplet level, which is why it was hitherto not possible to provide a conjugated polymer matrix for, for example, green phosphorescence emitters.

In order to circumvent the said problem of quenching, non-conjugated or partially conjugated polymers, which have a high triplet level, have been employed. However, these have to date had the disadvantage that the lifetime of such systems is unsatisfactory. Thus, for example, poly-N-vinylcarbazole (see, for example, U.S. Pat. No. 7,250,226 B2) is a known system for a phosphorescence emitter in the green region. However, opto-electronic devices produced therefrom have extremely short lifetimes and, owing to the non-conjugated polymer backbone, charge transport in the device may in addition be hindered, which results in a high operating voltage.

For this reason, conjugated polymers having a high triplet level are still required.

Accordingly, it was an object of the present invention to provide a novel class of conjugated polymers and compounds having a high triplet level which facilitate green and even blue organic phosphorescent electroluminescent devices comprising conjugated polymers as matrix having a longer lifetime and a lower operating voltage.

The invention is furthermore directed to PLEDs having an interlayer. Single-layered PLEDs, in which hole transport, electron transport and the emitter function are combined in one layer, are simple to produce, but have only short lifetimes.

WO 2004/084260 A2 discloses a PLED in which an improved lifetime compared with single-layered PLEDs has been achieved with an interlayer arranged between a hole-injection layer and an emission layer. An interlayer of this type usually has at least one hole-transport and electron-blocking function, but it is desirable to have further functions in the interlayer, in particular an exciton-blocking function, in order to keep the excitons in the emission layer. This is particularly desired in the case of triplet emitters. However, high demands are made of the interlayer polymers here, for example a suitable HOMO energy level, a high LUMO and a high triplet level is necessary. Interlayer polymers known from the prior art do not to date have these properties owing to their conjugation, in particular they have an inadequate triplet level and an excessively low LUMO.

A further object of the invention therefore consisted in the provision of a suitable interlayer polymer and/or electron-blocking polymer and/or exciton-blocking polymer for high-performance singlet and triplet OLEDs.

The object of the present invention is achieved by a copolymer containing, as structural unit, the compound of the general formula (1).

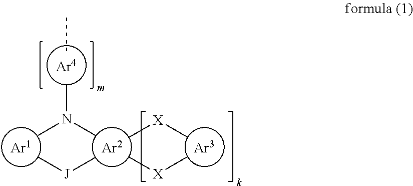

where the following applies to the symbols and indices:
J is on each occurrence, identically or differently, a single covalent bond or a divalent bridge selected from the group consisting of N(R¹), B(R¹), C(R¹)₂, O, Si(R¹)₂, C═C(R¹)₂, S, S═O, SO₂, P(R¹) and P(═O)R¹;
R¹ is, identically or differently on each occurrence, —H, —F, —Cl, Br, I, —CN, —NO₂, —CF₃, B(OR²)₂, Si(R²)₃, a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², O, S, —COO— or CONR² and where one or more H atoms may be replaced by D, F, Cl, Br, I, CN or N₂, or arylamines, or substituted or unsubstituted carbazoles, each of which may be substituted by one or more radicals R², or an aryl or heteroaryl group having 5 to 40 ring atoms, which by one or more aromatic;
R² is on each occurrence, identically or differently, H, D or an aliphatic or aromatic hydrocarbon radical having 1 to 20 C atoms or a substituted or unsubstituted aromatic or heteroaromatic ring system having 5 to 40 ring atoms;
k is either 0 or 1, where, for k=0, the bonding to an adjacent monomer unit in the polymer takes place via Ar²;
m is either 0 or 1;
X is on each occurrence identical or different from one another and is selected from

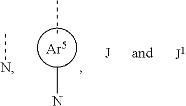

with the proviso that at least one X is not equal to J, where, in the case where k=1 and X is equal to J and J¹, the bonding to an adjacent monomer unit in the polymer takes place via Ar³;
Ar¹-Ar⁵ are selected, identically or differently on each occurrence, from an unsubstituted or R¹-substituted aromatic or heteroaromatic ring system;
J¹ is on each occurrence, identically or differently, a divalent bridge selected from the group consisting of N(R¹), B(R¹), C(R¹)₂, O, Si(R¹)₂, C═C(R¹)₂, S, S═O, SO₂, P(R¹) and P(═O)R¹;
   and where the dashed line represents a bond to an adjacent monomer unit in the polymer.

For the purposes of the present inventions, preference is given to copolymers mentioned herein in which k is equal to 1 for the units of the general formula (1).

In a furthermore preferred embodiment, the present invention relates to copolymers containing, as structural unit, the compounds of the general formulae (2), (3), (4), (5), (6), (7), (8) or (9).

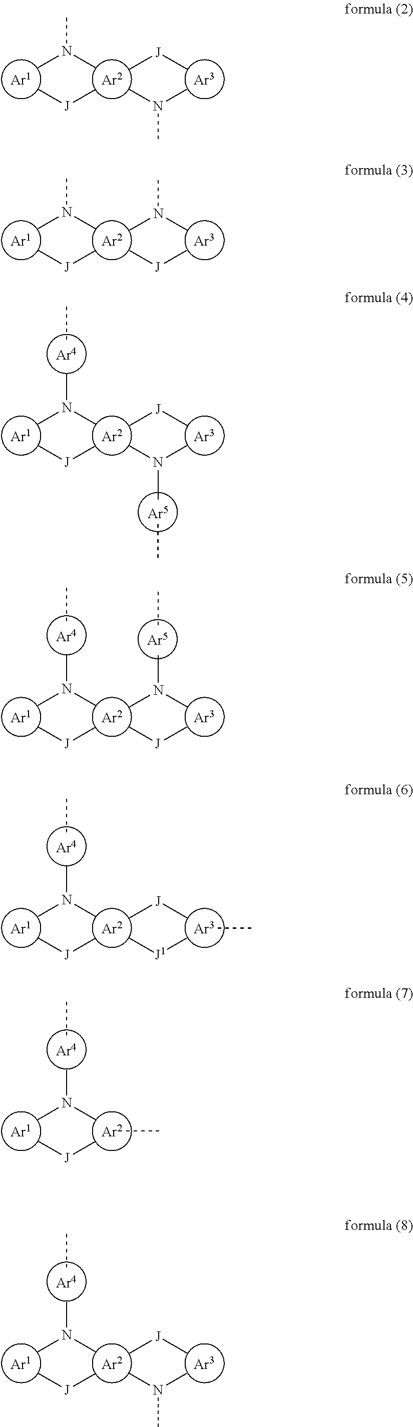

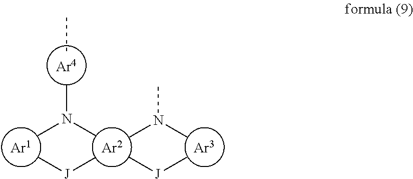

where the above definitions apply to the symbols and indices used and where the dashed line again represents a bond to an adjacent monomer unit in the polymer.

A copolymer that contains at least one structural unit of the formula (2), (3), (4), (5), (6), (8) or (9) is preferred here.

It has been found that a copolymer which contains at least one structural unit of the formula (1), preferably where k=1, can serve as matrix material for blue-, green- and red (orange)-emitting phosphorescence emitters, where the emission thereof is not quenched, so that the high emission efficiency of the phosphorescence emitters is retained. In addition, the solubility of the resultant polymers can be adjusted correspondingly through the choice of suitable substituents in the formula (1) to (9), so that the layer application of the polymers for organic electroluminescent devices can be accomplished in a simple and inexpensive process.

For the purposes of the present invention, an alkyl group having 1 to 40 C atoms, in which, in addition, individual H atoms or CH₂ groups may be substituted by —R²C═CR²—, —C≡C—, Si(R²)₂, Ge(R²)₂, Sn(R²)₂, C═O, C═S, C═Se, C═NR², —O—, —S—, —COO— or —CONR²—, is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, n-heptyl, cycloheptyl, n-octyl, cyclooctyl, 2-ethylhexyl, trifluoromethyl, pentafluoroethyl and 2,2,2-trifluoroethyl. An alkenyl group in the sense of this invention is taken to mean, in particular, ethenyl, propenyl, butenyl, pentenyl, cyclopentenyl, hexenyl, cyclohexenyl, heptenyl, cycloheptenyl, octenyl and cyclooctenyl. An alkynyl group in the sense of this invention is taken to mean, in particular, ethynyl, propynyl, butynyl, pentynyl, hexynyl or octynyl. A C₁- to C₄₀-alkoxy group is preferably taken to mean methoxy, trifluoromethoxy, ethoxy, n-propoxy, i-propoxy, n-butoxy, i-butoxy, s-butoxy, t-butoxy or 2-methylbutoxy.

Halogen in the present invention is taken to mean fluorine, chlorine, bromine or iodine, where chlorine, bromine and iodine are preferred and bromine and iodine are particularly preferred.

An aryl group or aromatic group in the sense of this invention preferably contains 5 to 40 C atoms, more preferably 5 to 25 C atoms, most preferably 6 to 20 C atoms; a heteroaryl group or heteroaromatic group in the sense of this invention preferably contains 2 to 40 C atoms and at least one heteroatom, more preferably 3 to 25 C atoms and at least one heteroatom, most preferably 5 to 20 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, triazine, thiophene, etc., or a polycyclic condensed aryl or heteroaryl group, for example naphthalene, anthracene, phenanthrene, benzanthracene, quinoline, isoquinoline, benzothiophene, benzofuran and indole, etc.

An aromatic ring system in the sense of this invention contains 5 to 40 C atoms, more preferably 5 to 25 C atoms, most preferably 6 to 20 C atoms in the ring system. A heteroaromatic ring system in the sense of this invention contains 2 to 40 C atoms and at least one heteroatom in the ring system, more preferably 3 to 25 C atoms and at least one heteroatom, most preferably 5 to 20 C atoms and at least one heteroatom, with the proviso that the sum of C atoms and heteroatoms is at least 5. The heteroatoms are preferably selected from N, O and/or S. An aromatic or heteroaromatic ring system in the sense of this invention is, in addition, intended to be taken to mean a system which does not necessarily contain only aryl or heteroaryl groups, but instead in which, in addition, a plurality of aryl or heteroaryl groups may be interrupted by a non-aromatic unit (preferably less than 10% of the atoms other than H), such as, for example, an sp³-hybridised C, N or O atom. Thus, for example, systems such as 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are interrupted, for example, by a linear or cyclic alkyl group or by a silyl group.

An aromatic or heteroaromatic ring system having 5-40 ring atoms, which may also in each case be substituted by the above-mentioned radicals R and which may be linked to the aromatic or heteroaromatic ring system via any desired positions, is taken to mean, in particular, groups derived from benzene, naphthalene, anthracene, phenanthrene, pyrene, chrysene, benzanthracene, perylene, fluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, cis- or trans-indenocarbazole, cis- or trans-indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The aromatic or heteroaromatic ring system may be monocyclic or polycyclic, i.e. it may have one ring (for example phenyl) or two or more rings, which may be condensed (for example naphthyl) or covalently linked (for example biphenyl), or contain a combination of condensed and linked rings. Fully conjugated ring systems are preferred.

In the present application, the term “polymer” or “copolymer” is taken to mean both polymeric compounds, oligomeric compounds and dendrimer, where, for the preparation of dendrimers, other, trifunctional structural units must also be added in addition to the structural units according to the invention. The polymeric compounds according to the invention preferably have 10 to 10,000, particularly preferably 20 to 5000 and in particular 50 to 2000 structural units. The oligomeric compounds according to the invention preferably have 2 to 9 structural units.

According to an embodiment, it is preferred for at least one structural unit of the formula (1), preferably where k=1, to be linked to a further structural unit of the formula (1), preferably where k=1, or to a different structural unit to form a nonlinear-conjugated system. This can be illustrated diagrammatically by the following representation, where the elliptical shapes indicated represent the structural units of the formula (1), preferably where k=1, and structures (II) to (IV) are structures according to the invention, whereas A are units which are not according to the invention (see structure (I)).

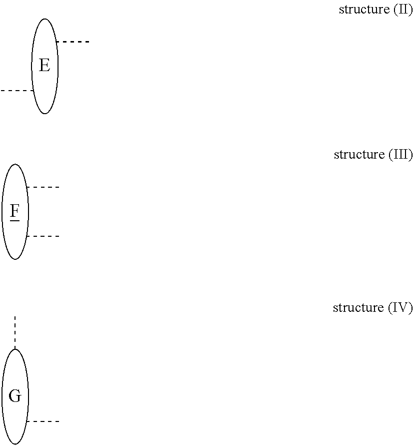

Examples of such links are represented below, without this being intended to be limiting.

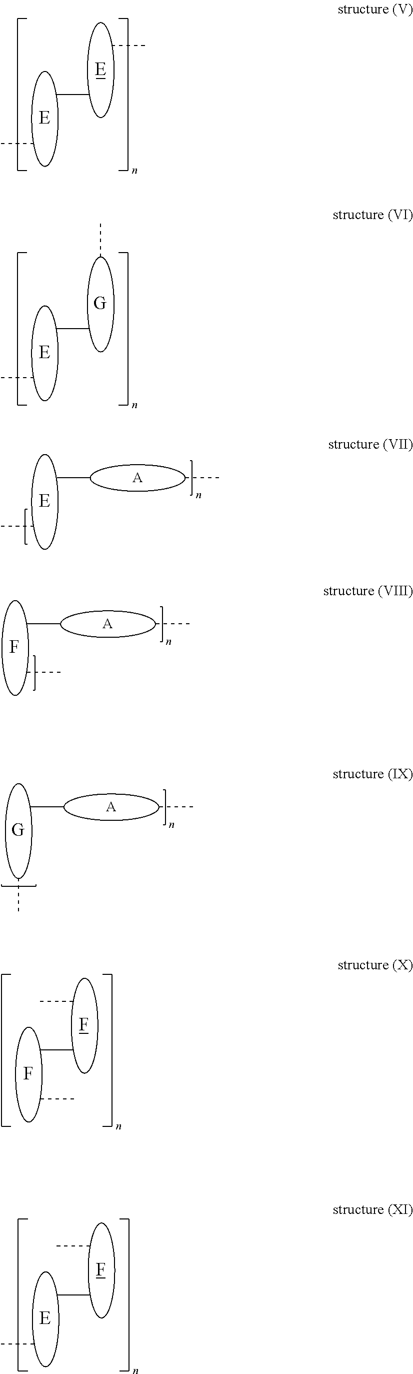

The person skilled in the art can, without being inventive, add further links between recurring units according to the invention and between recurring units according to the invention and recurring units which are not according to the invention, such as, for example, between E and F or between F and G.

In a preferred embodiment of the present invention, Ar¹, Ar² and Ar³ in the structural units of the formulae (1) and/or (2) to (9) are selected, identically or differently on each occurrence, from an unsubstituted or R¹-substituted aromatic ring system.

In a very preferred embodiment of the present invention, Ar¹, Ar² and Ar³ in the structural units of the formulae (1) and/or (2) to (9) are selected, identically or differently on each occurrence, from a monocyclic unsubstituted or R¹-substituted monocyclic aromatic or heteroaromatic rings, preferably monocyclic aromatic rings, where structural units of this type where k=1 are preferred.

In a very particularly preferred embodiment of the present invention, Ar¹, Ar² and Ar³ in the structural units of the formulae (1) and/or (2) to (9) are selected, identically or differently on each occurrence, from a monocyclic unsubstituted aromatic or heteroaromatic ring, preferably from a monocyclic unsubstituted aromatic ring, very preferably Ar¹, Ar² and Ar³ is a monocyclic unsubstituted aromatic 6-membered ring, where structural units of this type where k=1 are preferred.

In a furthermore very particularly preferred embodiment of the present invention, k=1 and Ar¹, Ar² and Ar³ in the structural units of the (1) and/or (2), (3), (4), (5), (6), (8) and (9) are selected, identically or differently on each occurrence, from a monocyclic unsubstituted aromatic or heteroaromatic ring, preferably from a monocyclic unsubstituted aromatic ring, very preferably Ar¹, Ar² and Ar³ is a monocyclic unsubstituted aromatic 6-membered ring.

According to a preferred embodiment of the invention, the compounds of the formulae (1) and/or (2) to (9) correspond to the compounds of the formulae (10) to (28), very preferably (10) to (22) and (24) to (28).

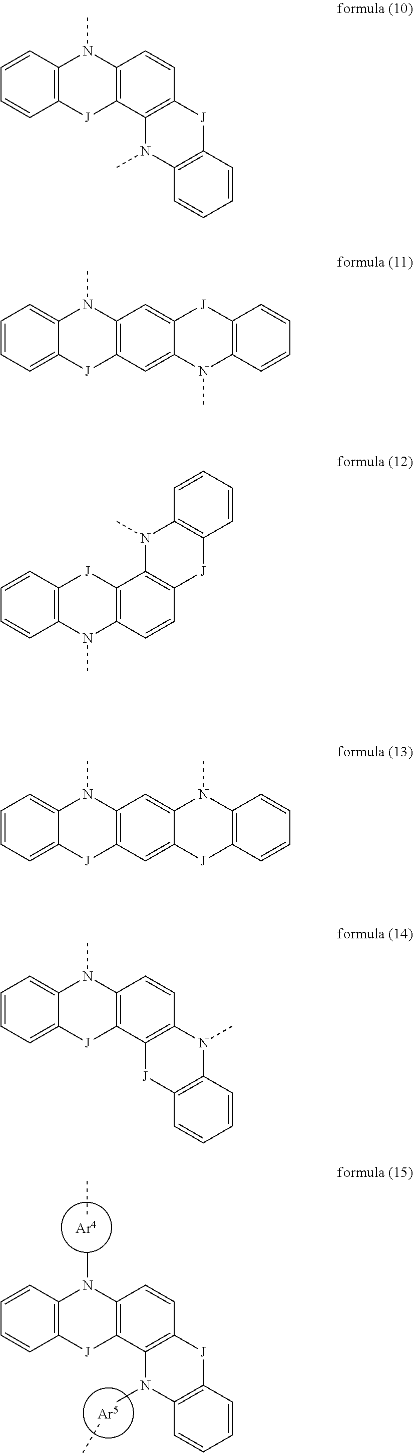

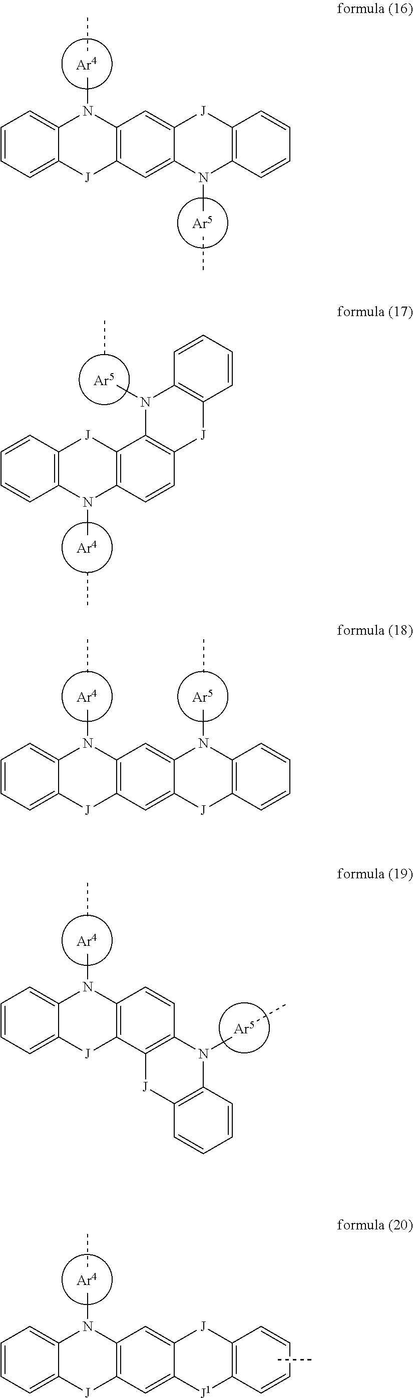

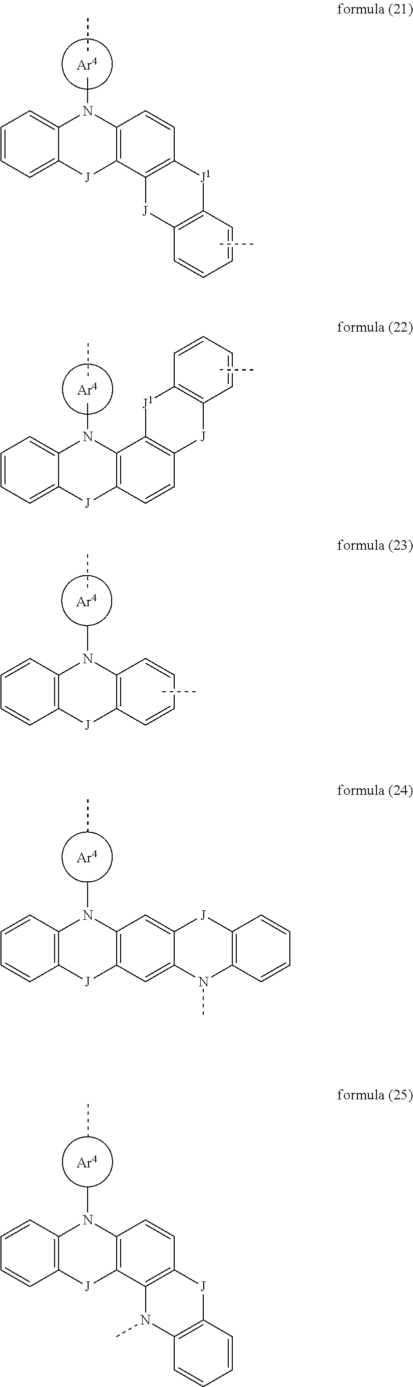

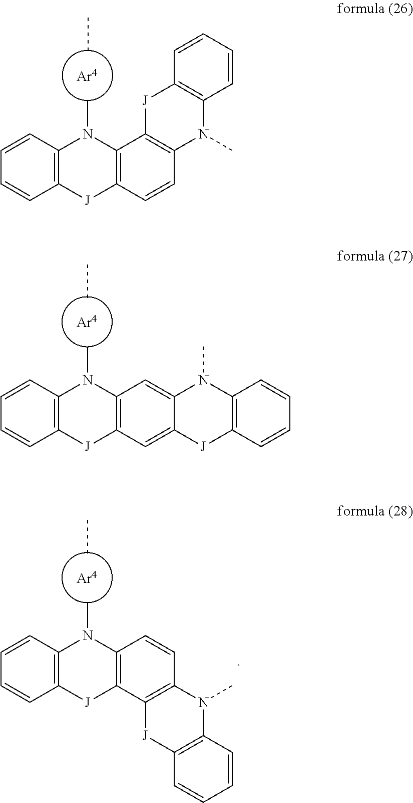

where the symbols and indices have the meaning indicated in Claim 1.

In a preferred embodiment of the present invention, Ar⁴ and Ar⁵ in the structural units of the formulae (1), preferably where k=1, are selected, identically or differently on each occurrence, from an unsubstituted or R¹— substituted aromatic ring system.

In a very preferred embodiment of the present invention, Ar⁴ and Ar⁵ in the above structural units of the general formula (1), preferably where k=1, are selected, identically or differently on each occurrence, from an unsubstituted or R¹-substituted aromatic or heteroaromatic rings, preferably aromatic rings.

According to a further preferred embodiment of the invention, the compounds of the formulae (1) correspond to the compounds of the formulae (29) to (48), where those of the formulae (29) to (42) and (44) to (48) are preferred.

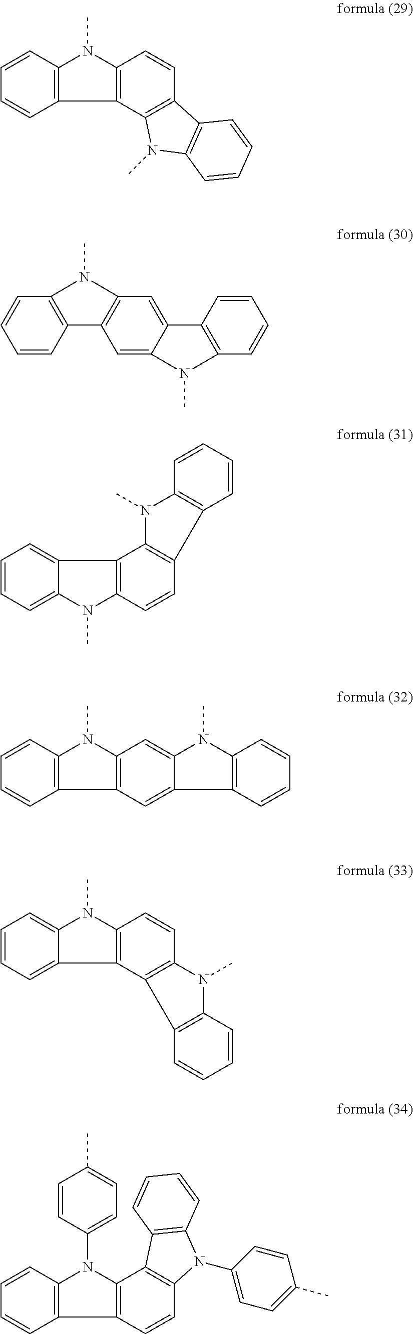

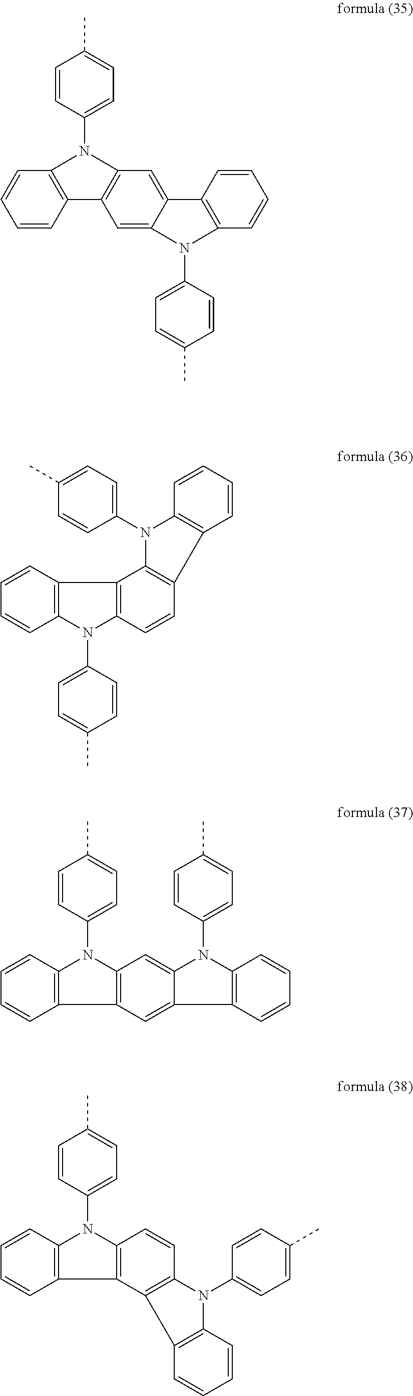

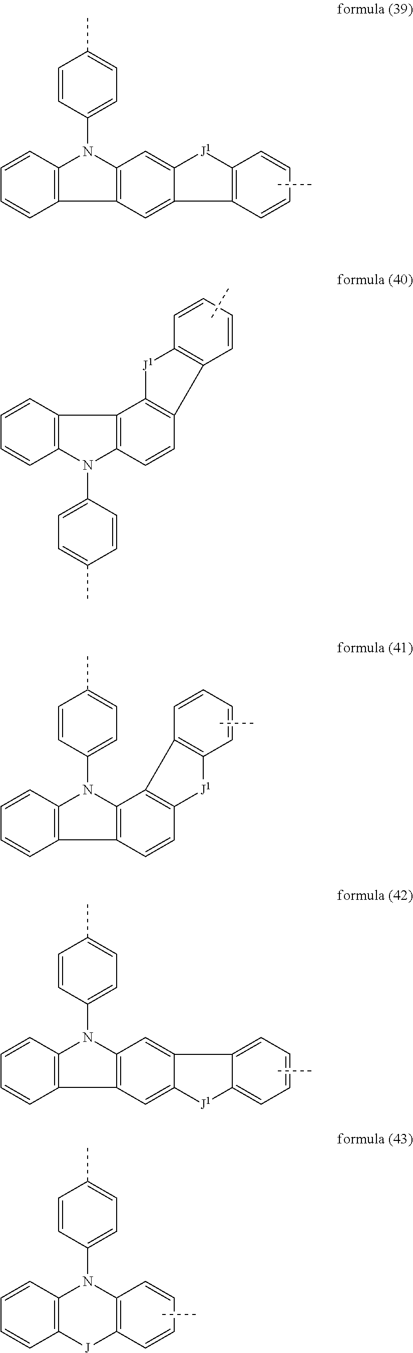

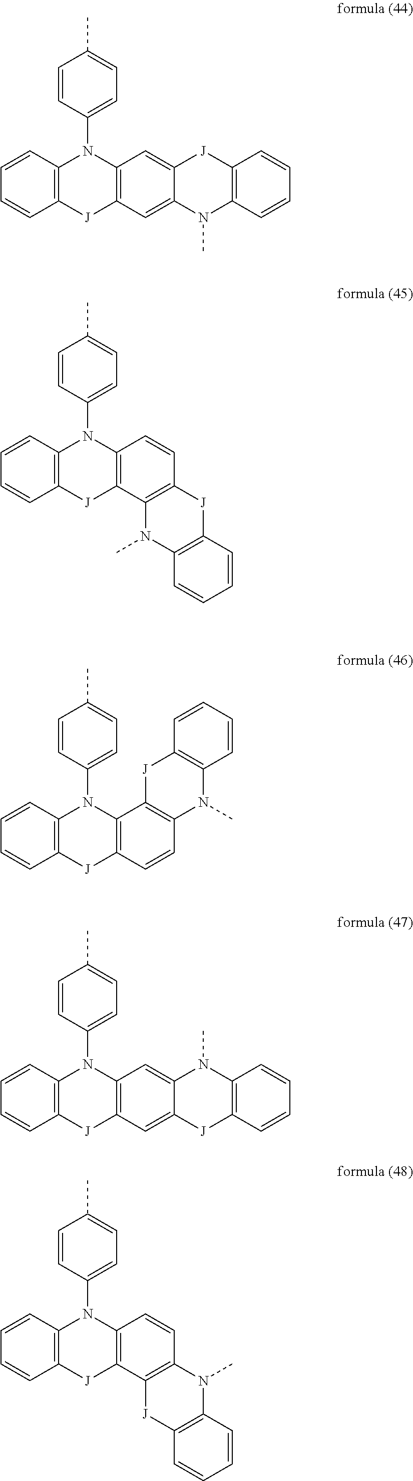

where the symbols and indices have the meaning indicated above.

Further suitable compounds according to the invention are, for example, the following, preferably compounds of the formulae (49) to (80) and (87) to (113):

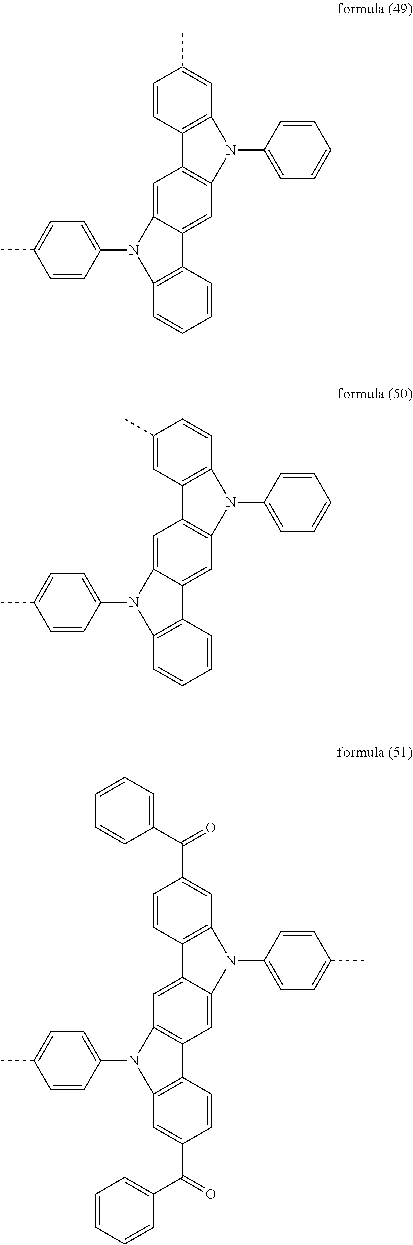

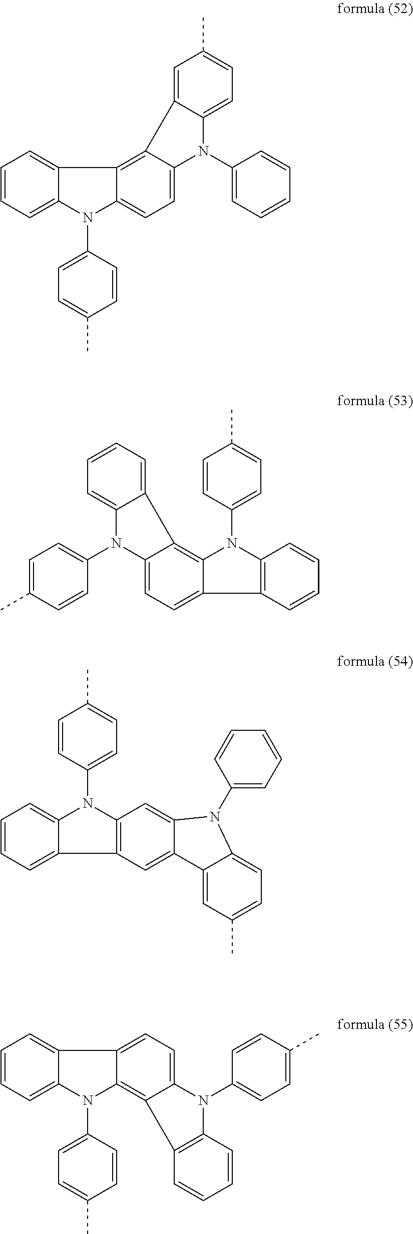

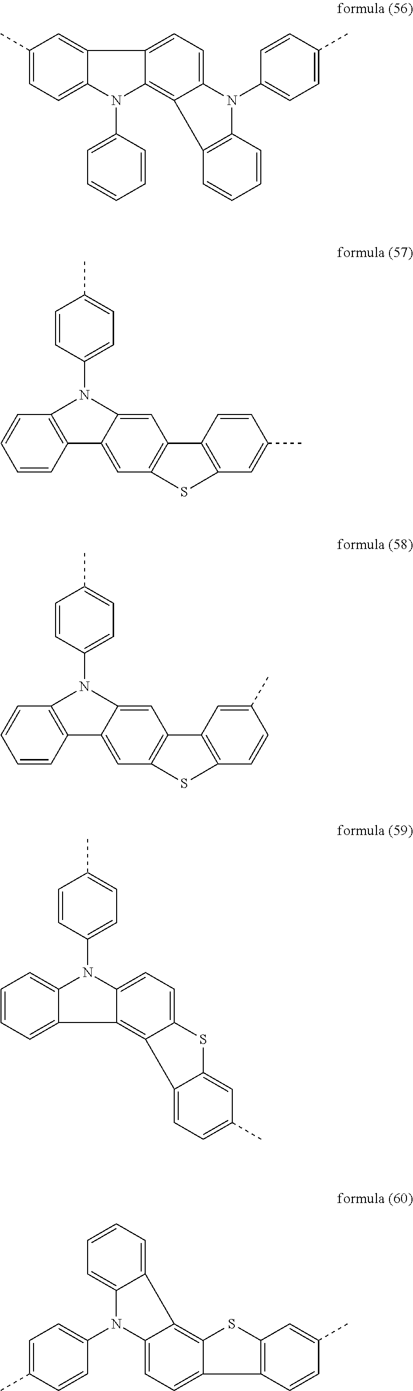

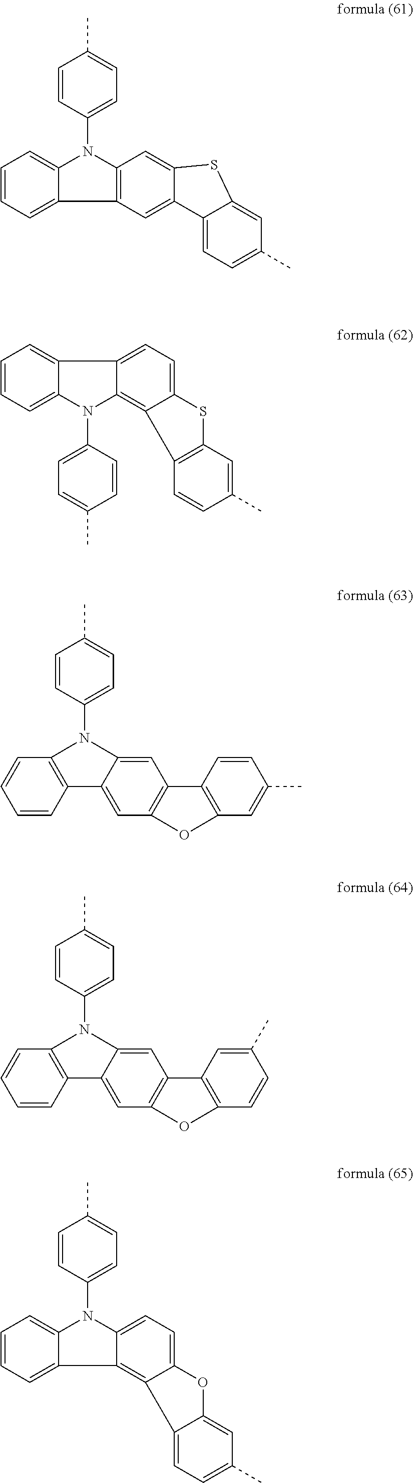

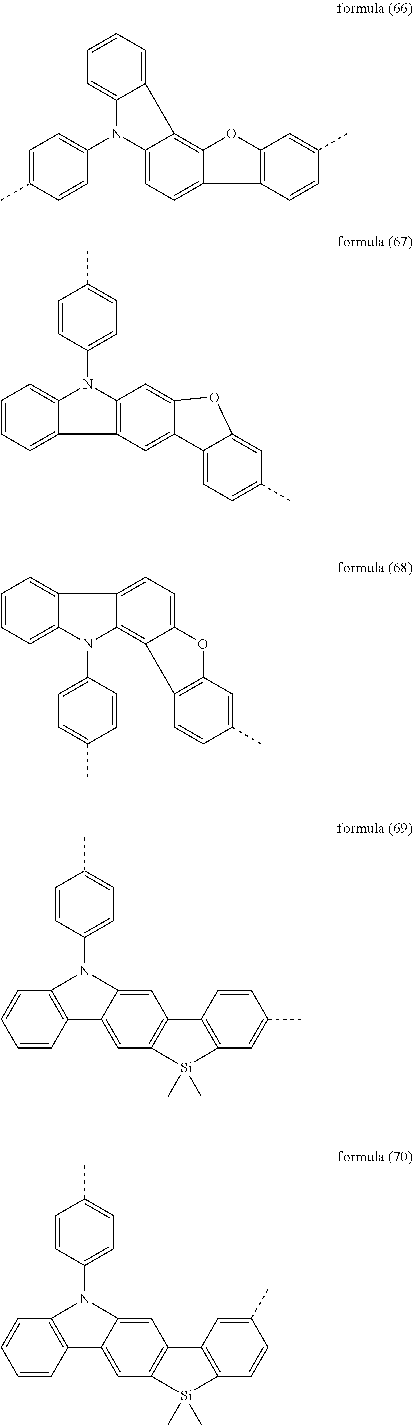

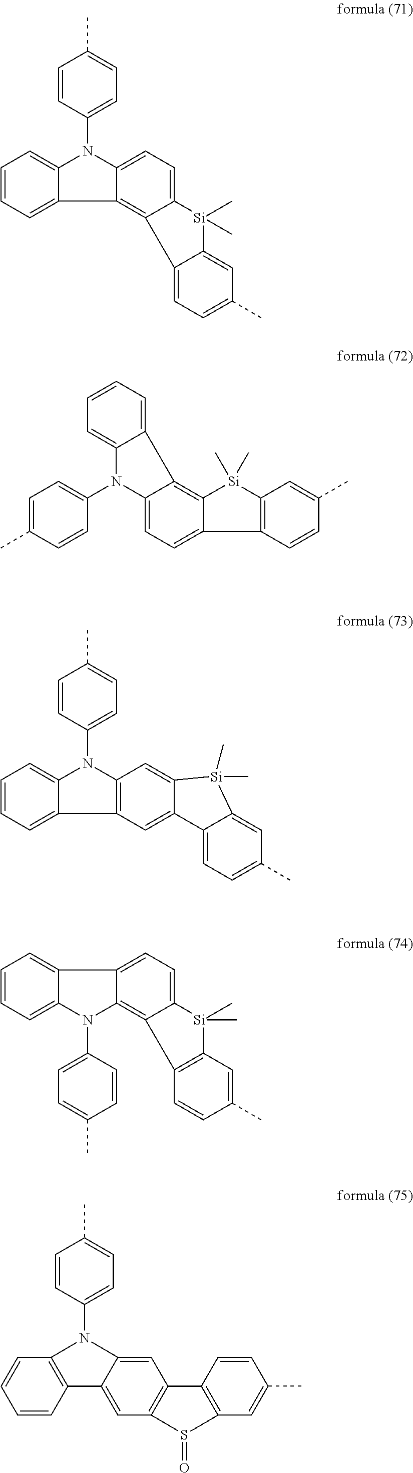

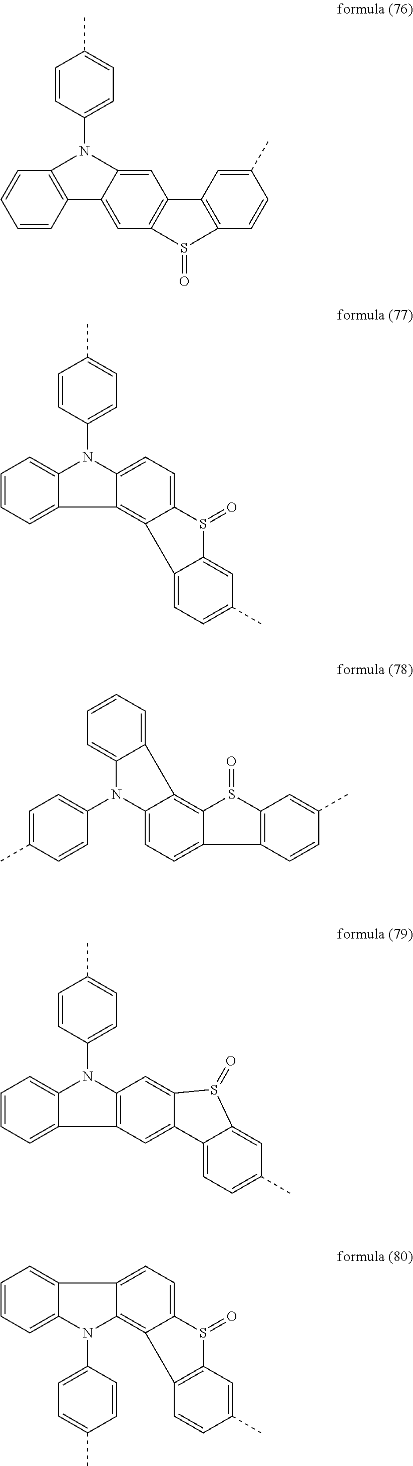

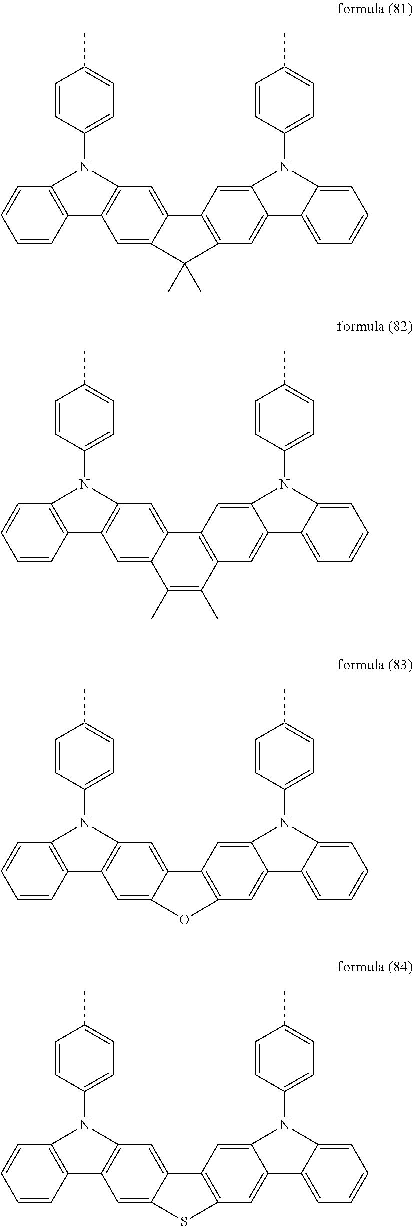

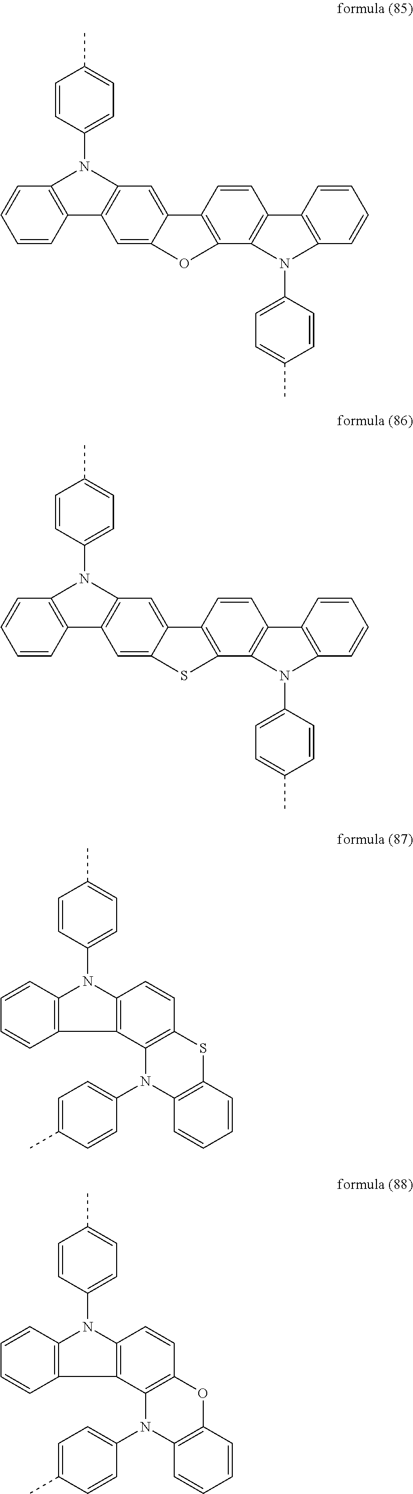

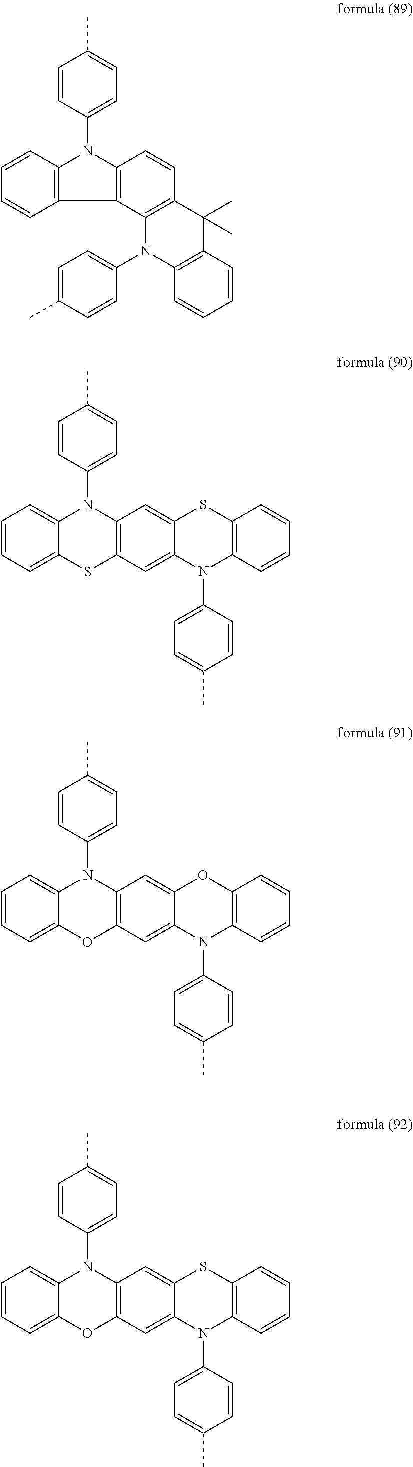

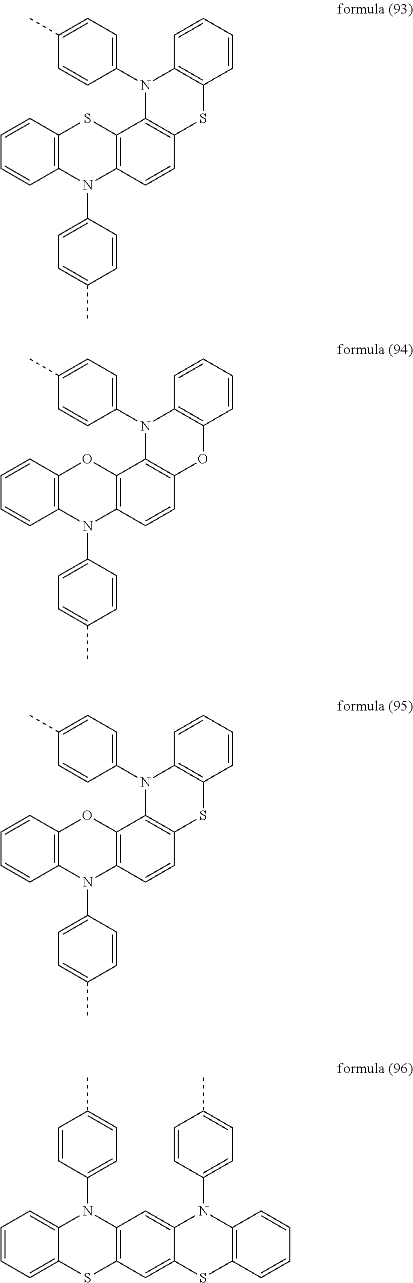

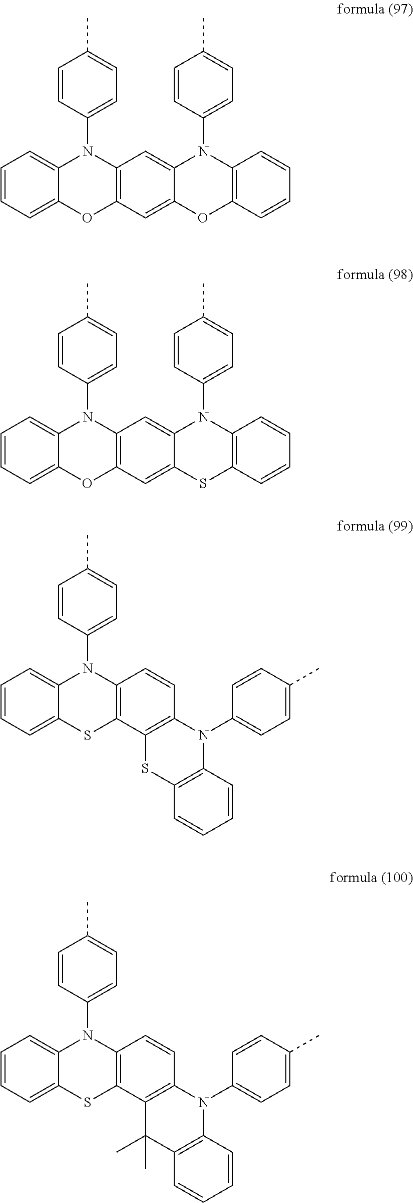

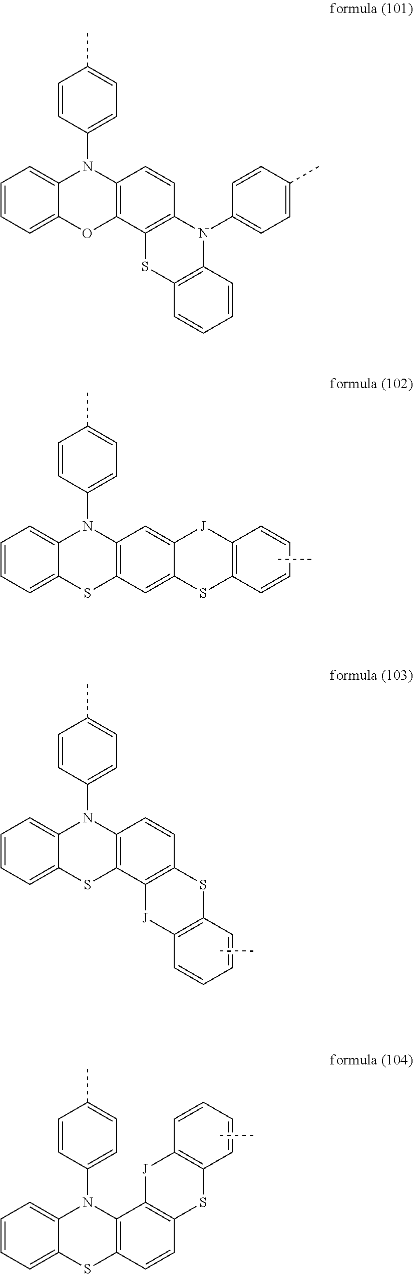

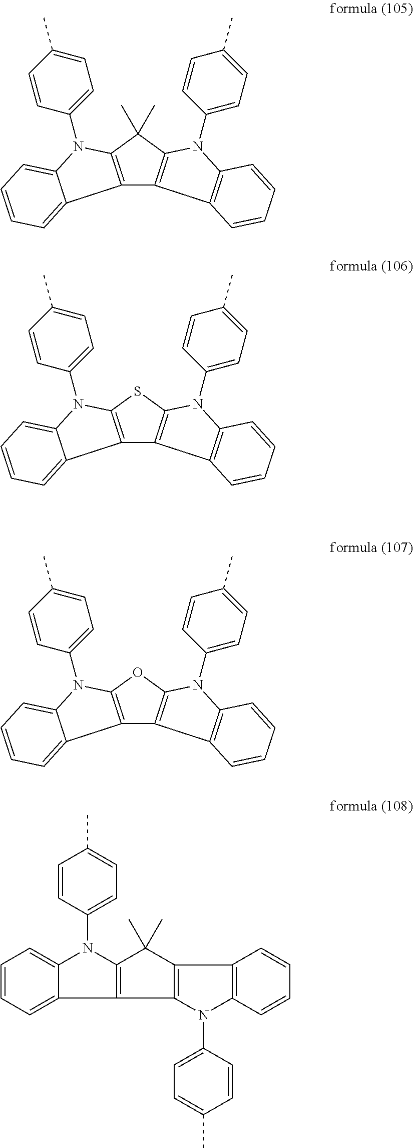

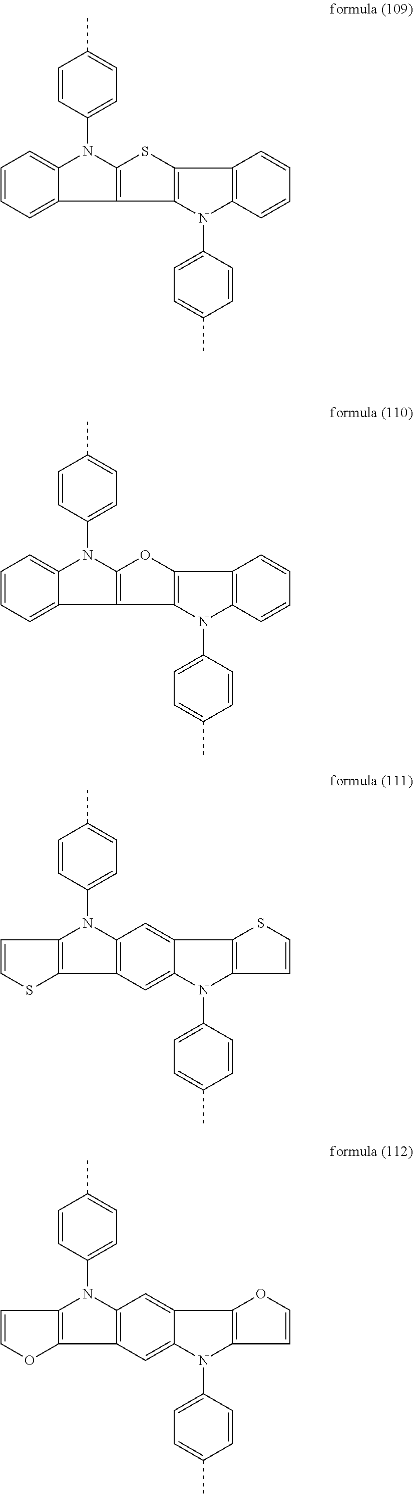

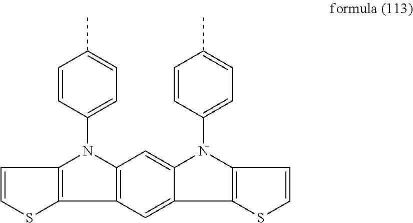

In a further embodiment according to the invention, the proportion of the units of the formula (1), preferably where k=1, in the copolymer is less than 100 mol %, preferably up to 95 mol %, particularly preferably up to 80 mol % and in particular up to 60 mol %. Likewise in a preferred embodiment, the proportion of the units of the formula (1) in the copolymer is at least 0.01 mol %, preferably at least 1 mol %, particularly preferably at least 10 mol % and in particular at least 30 mol %.

The number-average molecular weight Mₙ of the copolymer according to the invention is preferably in the range 4000 to 2000000 g/mol, more preferably 5000 to 1500000 g/mol, most preferably 6000 to 1000000 g/mol. The number-average molecular weight Mₙ is determined by GPC (gel permeation chromatography) using an internal polystyrene standard.

The copolymers may be conjugated, partially conjugated or non-conjugated, preferably conjugated. In a preferred embodiment, the copolymers contain a segment of structure (V) to (IX). In the structures, the structural units of the formula (1), preferably where k=1, to (113) can either be linked directly to one another or they can be linked to one another via a divalent group, for example via a substituted or unsubstituted alkylene group, via a heteroatom or via a divalent aromatic or heteroaromatic group. In a further embodiment of the present invention, the copolymer may be branched. In branched structures, for example, three or more structural units of the formula (1), preferably where k=1, can be linked via a trivalent or polyvalent group, for example via a trivalent or polyvalent aromatic or heteroaromatic group, to form a branched co-oligomer or copolymer. However, the copolymer may also contain further segments which are conjugated in a normal linear manner.

Partially conjugated copolymers can preferably be random copolymers or block copolymers comprising the structural unit according to the invention and at least one further monomer unit. Groups which can be employed as further monomer unit are described below. In the case of partially conjugated copolymers, at least one of the further structural units (monomer units) which is different from the structural unit according to the invention contributes to the copolymer forming a conjugated system, at least in parts.

In the case of non-conjugated copolymers, the copolymer may also be a random or alternating copolymer or block copolymer comprising the structural unit of the formula (1), preferably where k=1, and at least one further monomer unit which are different from the structural units according to the invention. In the case of the random copolymer and block copolymer, the further structural units are preferably units which are themselves non-conjugated. Suitable non-conjugated structural units are selected, for example, from the group consisting of linear or branched alkylene, cycloalkylene, alkylsilylene, silylene, arylsilylene, alkylalkoxyalkylene, arylalkoxyalkylene, alkylthioalkylene, sulfone, alkylenesulfone, sulfone oxide, alkylenesulfone oxide, where the alkylene group in each case has, independently of one another, 1 to 12 C atoms and where one or more H atoms may be replaced by F, Cl, Br, I, alkyl, heteroalkyl, cycloalkyl, aryl or heteroaryl.

In a particularly preferred embodiment, the copolymer according to the invention is a conjugated polymer. Conjugated polymers in the sense of this invention are polymers which contain principally sp²-hybridised carbon atoms, which may also be replaced by corresponding heteroatoms, in the main chain. In the simplest case, this means an alternating presence of double and single bonds in the main chain. Principally means that naturally occurring defects which result in conjugation interruptions do not devalue the term “conjugated polymers”. Furthermore, the term conjugated is likewise used in this application text if, for example, arylamine units and/or certain heterocycles (i.e. conjugation via N, o or S atoms) and/or organometallic complexes (i.e. conjugation via the metal atom) are present in the main chain. In the sense of the present invention, structural units of the general formula (1) are therefore not regarded as being conjugation-interrupting. The same also applies if one or more organometallic complexes are integrated into the copolymer. Quantum-chemical calculations on model compounds (for example monomer, dimer and trimer) can be used to assess qualitatively the delocalisation of the electrons within the copolymer. The method for the calculation of singlet and triplet levels described below also gives, besides these energy levels, the position, shape and distribution of two important molecular orbitals, namely the HOMO and LUMO. In the sense of this invention, an atom X is assumed to be non-conjugation-interrupting if either the HOMO or the LUMO extends over the atom X.

The copolymers according to the invention also, besides one or more structural units of the formula (1), preferably where k=1, contain at least one further structural unit which is different from the structural unit of the formula (1). These are, inter alia, those as disclosed and listed extensively in WO 02/077060 A1 and in WO 2005/014689 A2. These are regarded as part of the present invention by way of reference. The further structural units can originate, for example, from the following classes:
Group 1: hole-injection and/or hole-transport materials (HIM/HTM);
Group 2: electron-injection and/or electron-transport materials (EIM/ETM);
Group 3: fluorescence emitters or singlet emitters;
Group 4: phosphorescence emitters or triplet emitters;
Group 5: units which improve transfer from the singlet state to the triplet
state;
Group 6: units which influence the emission colour of the resultant polymers/copolymers;
Group 7: units which are typically used as backbone;
Group 8: units which influence the film-morphological and/or rheological properties of the resultant polymers/copolymers.

Preferred copolymers according to the invention are those in which at least one structural unit has charge-transport properties, i.e. which contain units from group 1 and/or 2.

Suitable HIM or HTM (group 1) are preferably selected from triarylamine, benzidine, tetraaryl-para-phenylenediamine, triarylphosphine, phenothiazine, phenoxazine, dihydrophenazine, thianthrene, dibenzo-paradioxin, phenoxathiyne, carbazole, azulene, thiophene, pyrrole and furan derivatives and further O-, S- or N-containing heterocycles having a high HOMO (HOMO=highest occupied molecular orbital). These arylamines and heterocycles preferably result in an HOMO in the copolymer of greater than −5.8 eV (against vacuum level), particularly preferably greater than −5.5 eV.

Further suitable HTM or HIM units are, for example, the compounds disclosed in Y. Shirota et al., Chem. Rev. 2007, 107(4), 953-1010, or other materials as employed in accordance with the prior art in the hole-transport layers or hole-injection layers.

Examples of preferred HTM or HIM units which can be bonded into compounds or polymers or oligomers according to the invention are indenofluorenamines and derivatives (for example in accordance with WO 2006/122630 or WO 2006/100896), the amine derivatives disclosed in EP 1661888, hexaazatriphenylene derivatives (for example WO 2001/049806), amine derivatives with condensed aromatic rings (for example in accordance with U.S. Pat. No. 5,061,569), the amine derivatives disclosed in WO 95/09147, monobenzoindenofluorenamines (for example in accordance with WO 2008/006449), dibenzoindenofluorenamines (for example in accordance with WO 2007/140847) or piperidine derivatives (for example in accordance with DE 102009005290). Furthermore suitable hole-transport and hole-injection materials are derivatives of the compounds depicted above, as disclosed in JP 2001/226331, EP 676461, EP 650955, WO 2001/049806, U.S. Pat. No. 4,780,536, WO 98/30071, EP 891121, EP 1661888, JP 2006/253445, EP 650955, WO 2006/073054 and U.S. Pat. No. 5,061,569.

Preferred HTM or HIM units are furthermore, for example, the following materials.

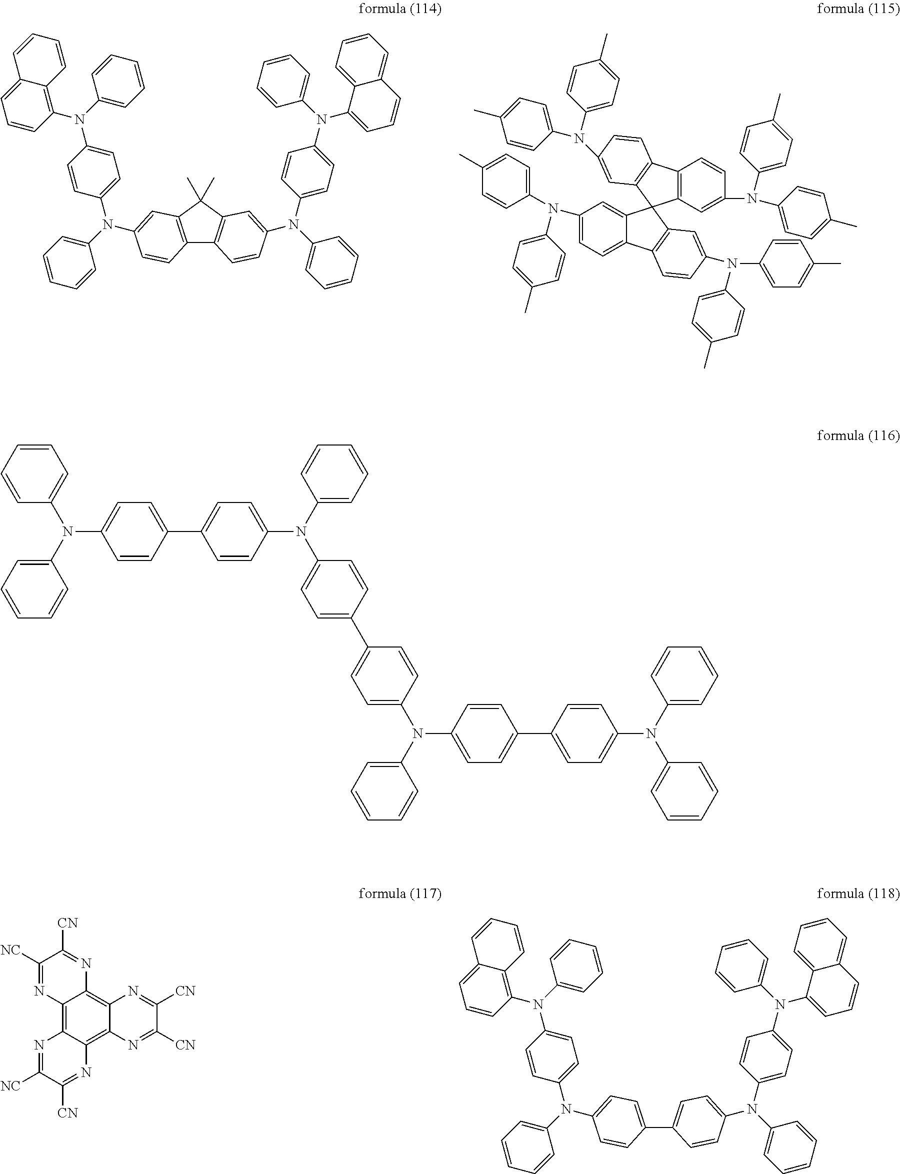

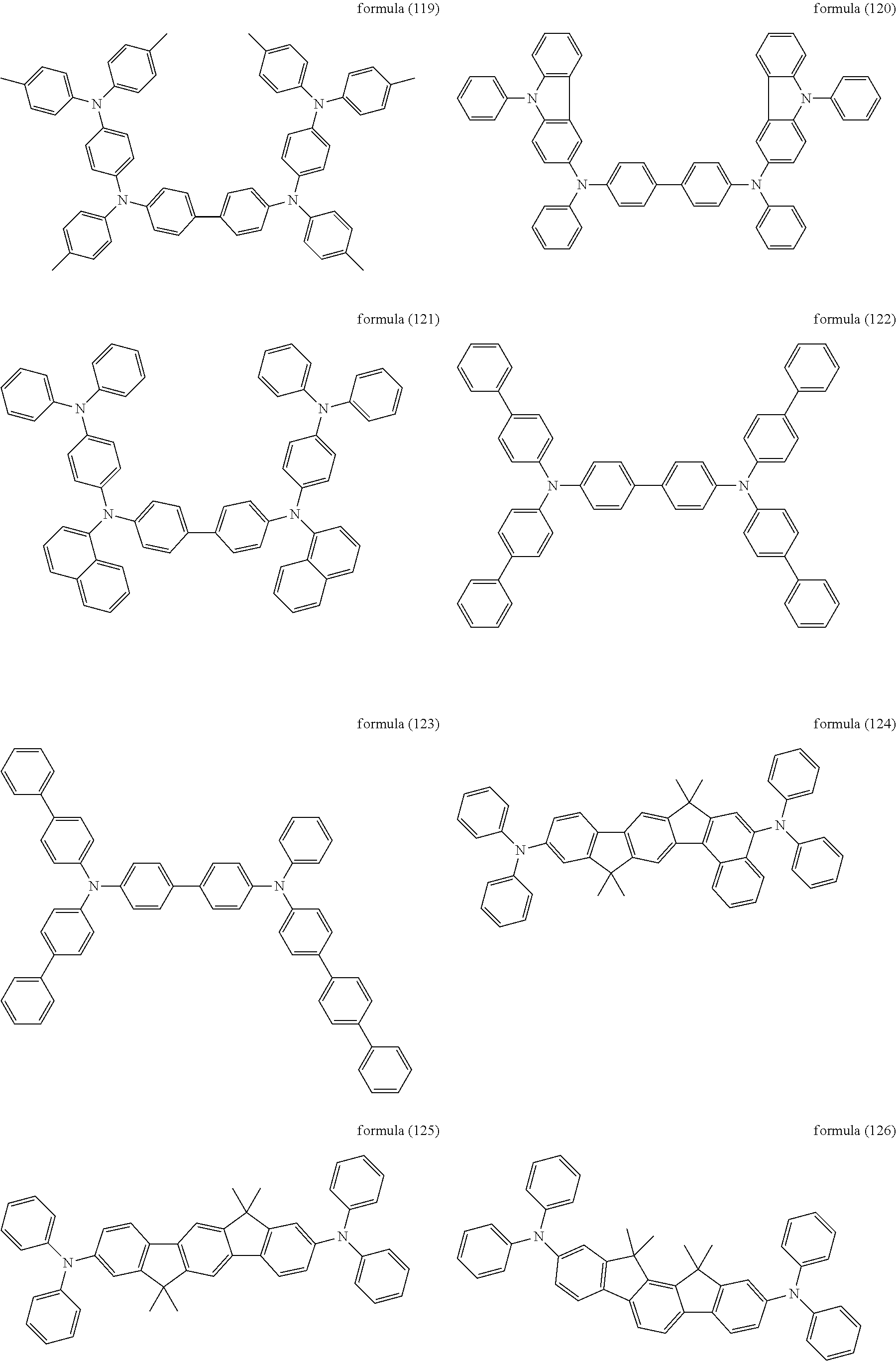

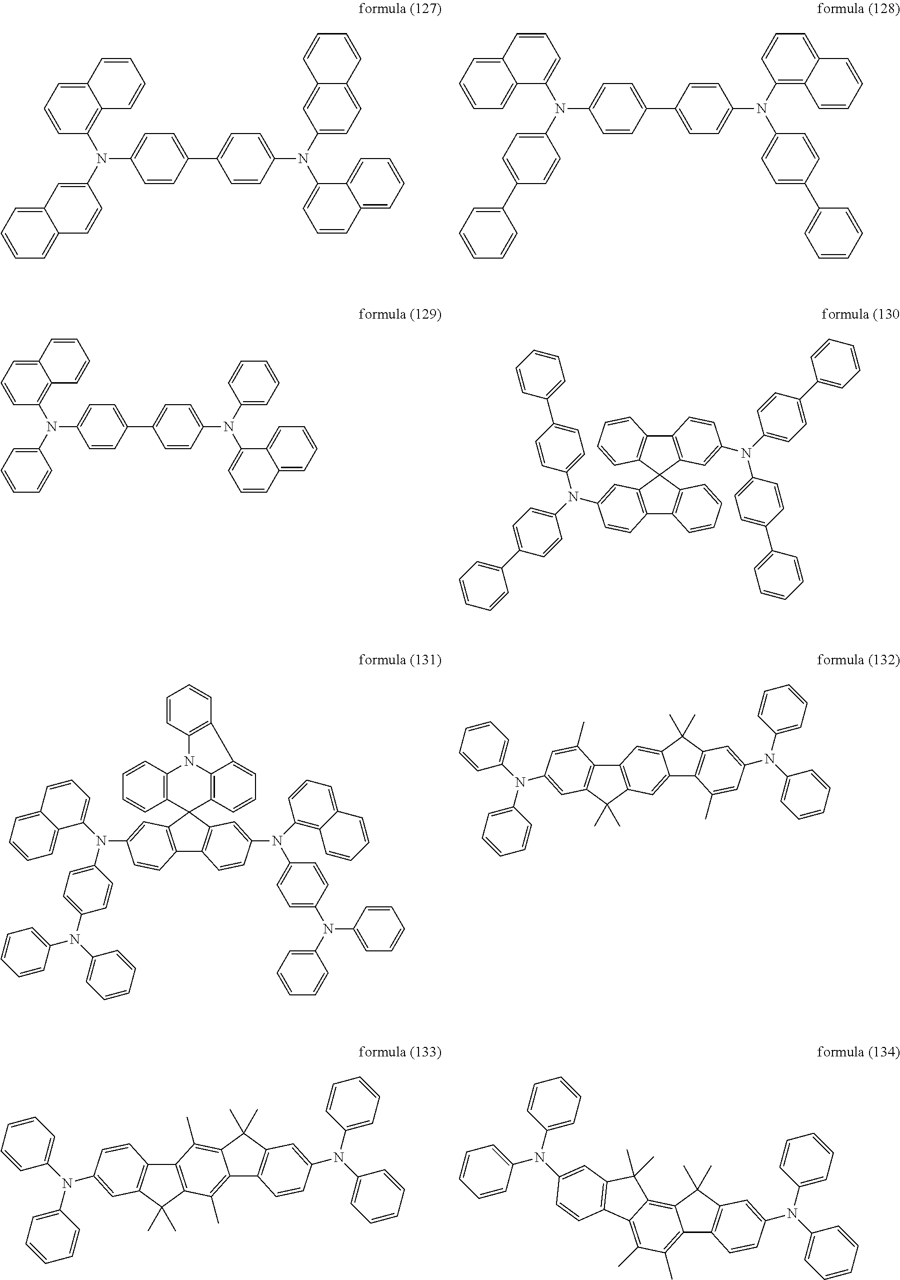

Suitable EIM or ETM (group 2) are preferably selected from pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine derivatives, but also triarylboranes and further O-, S- or N-containing heterocycles having a low LUMO (LUMO=lowest unoccupied molecular orbital). These units in the copolymer preferably result in an LUMO of less than −1.9 eV (against vacuum level), particularly preferably less than −2.5 eV.

It may be the case that the copolymer is intended to emit various colours, such as, for example, red, green and white. This can be achieved by the incorporation of different emitters into the copolymer.

In a preferred embodiment, the emitter is a singlet emitter, in particular if blue emission is desired. A singlet emitter in the sense of this invention is a compound which emits light from an excited singlet state.

In the context of the present invention, the terms singlet emitters, singlet dopants, fluorescent emitters and fluorescent dopants have the same meaning.

Suitable dopants are selected from the class of the monostyrylamines, the distyrylamines, the tristyrylamines, the tetrastyrylamines, the styrylphosphines, the styryl ethers and the arylamines. A monostyrylamine is taken to mean a compound which contains one substituted or unsubstituted styryl group and at least one, preferably aromatic, amine. A distyrylamine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. An arylamine or aromatic amine in the sense of this invention is taken to mean a compound which contains three substituted or unsubstituted aromatic or heteroaromatic ring systems bonded directly to the nitrogen. At least one of these aromatic or heteroaromatic ring systems is preferably a condensed ring system, preferably having at least 14 aromatic ring atoms. Preferred examples thereof are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which one diarylamino group is bonded directly to an anthracene group, preferably in the 2- or 9-position. An aromatic anthracenediamine is taken to mean a compound in which two diarylamino groups are bonded directly to an anthracene group, preferably in the 2,6- or 9,10-position. Aromatic pyrenamines, pyrenediamines, chrysenamines and chrysenediamines are defined analogously thereto, where the diarylamino groups are preferably bonded to the pyrene in the 1-position or in the 1,6-position. Further preferred dopants are selected from indenofluorenamines or indenofluorenediamines, for example in accordance with WO 2006/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847. Examples of dopants from the class of the styrylamines are substituted or unsubstituted tristilbenamines or the dopants described in the patent applications WO 2006/000388, WO 2006/058737, WO 2006/000389, WO 2007/065549 and WO 2007/115610.

Preference is furthermore given to bridged aromatic hydrocarbons, such as, for example, the compounds disclosed in WO 2010/012328.

Preferred fluorescent dopants are the compounds of the following formulae (135) and (136)

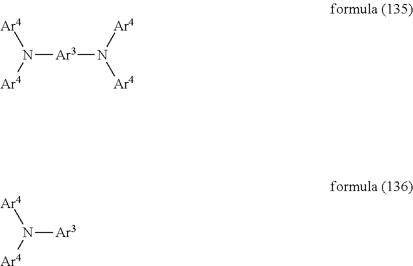

where the following applies to the symbols used:
Ar³ is a condensed aryl or heteroaryl group or a condensed aromatic or heteroaromatic ring system having 10 to 40 aromatic ring atoms, which may be substituted by one or more radicals R²;
Ar⁴ is on each occurrence, identically or differently, an aromatic or heteroaromatic ring system having 5 to 30 aromatic ring atoms, which may be substituted by one or more radicals R²; two radicals Ar⁴ here which are bonded to the same nitrogen atom may also be linked to one another by a single bond or a bridge selected from B(R²), C(R²)₂, Si(R²)₂, C═O, C═NR², C═C(R²)₂, O, S, S═O, SO₂, N(R²), P(R²) and P(═O)R²;
R² is on each occurrence, identically or differently, H, D, F, Cl, Br, I, CHO, N(R³)₂, C(═O)R³, P(═O)(R³)₂, S(═O)R³, S(═O)₂R³, CR³═C(R³)₂, CN, NO₂, Si(R³)₃, B(OR³)₂, B(R³)₂, B(N(R³)₂)₂, OSO₂R³, a straight-chain alkyl, alkoxy or thioalkoxy group having 1 to 40 C atoms or a branched or cyclic alkyl, alkoxy or thioalkoxy group having 3 to 40 C atoms or an alkenyl or alkynyl group having 2 to 40 C atoms, where the alkyl, alkoxy, thioalkoxy, alkenyl or alkynyl group may in each case be substituted by one or more radicals R³, where one or more non-adjacent CH₂ groups may be replaced by R³C═CR³, C≡C, Si(R³)₂, C═O, C═S, C═NR³, P(═O)(R³), SO, SO₂, NR³, O, S or CONR³ and where one or more H atoms may be replaced by D, F, Cl, Br, I, CN or NO₂, or an aromatic or heteroaromatic ring system having 5 to 30 aromatic ring atoms, which may in each case be substituted by one or more radicals R³, or an aryloxy or heteroaryloxy group having 5 to 30 aromatic ring atoms, which may be substituted by one or more radicals R³; two or more adjacent substituents R² here may also form a mono- or polycyclic, aliphatic or aromatic ring system with one another;
R³ is on each occurrence, identically or differently, H, D or an aliphatic, aromatic and/or heteroaromatic hydrocarbon radical having 1 to 20 C atoms, in which, in addition, H atoms may be replaced by D, CN or F; two or more adjacent substituents R³ here may also form a mono- or polycyclic, aliphatic or aromatic ring system with one another.

In a preferred embodiment of the invention, Ar³ is a condensed aryl group or a condensed aromatic ring system. Preferred condensed aryl groups or aromatic ring systems Ar³ are selected from the group consisting of anthracene, pyrene, fluoranthene, naphthacene, chrysene, benzanthracene, benzofluorene, triphenylene, perylene, cis- or trans-monobenzoindenofluorene and cis- or trans-dibenzoindenofluorene, each of which may be substituted by one or more radicals R².

In a preferred embodiment of the invention, Ar⁴ is an aromatic ring system. Preferred aromatic ring systems Ar⁴ are selected, identically or differently on each occurrence, from the group consisting of phenyl, 1- or 2-naphthyl, ortho-, meta- or para-biphenyl, 2-fluorenyl or 2-spirobifluorenyl, each of which may be substituted by one or more radicals R².

Preferred radicals R² are selected, identically or differently on each occurrence, from the group consisting of H, D, F, CN, straight-chain alkyl groups having 1 to 10 C atoms or branched alkyl groups having 3 to 10 C atoms.

Further preferred fluorescent dopants are the compounds of the following formula (137).

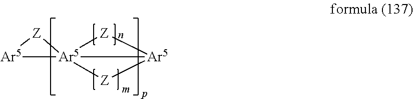

where R² has the above-mentioned meaning and the following applies to the other symbols and indices used:
Ar⁵ is on each occurrence, identically or differently, an aryl or heteroaryl group having 5 to 30 aromatic ring atoms, which may be substituted by one or more radicals R², with the proviso that at least one group Ar⁵ stands for a condensed aryl or heteroaryl group having 10 to 30 aromatic ring atoms;
Z is selected on each occurrence, identically or differently, from the group consisting of BR², C(R²)₂, Si(R²)₂, C═O, C═NR², C═C(R²)₂, O, S, S═O, SO₂, NR², PR² and P(═O)R²;
m, n is 0 or 1, with the proviso that m+n=1;
p is 1, 2 or 3;
   in each case two groups Ar⁵ and Z together form a five-membered ring or a six-membered ring, preferably in each case a five-membered ring.

In a preferred embodiment of the invention, the sum of all π-electrons in the groups Ar⁵ is at least 28 if p=1, and is at least 34 if p=2, and is at least 40 if p=3.

In a preferred embodiment of the invention, at least one group Ar⁵ stands for a condensed aryl group having 10 to 18 C atoms, in particular selected from the group consisting of naphthalene, phenanthrene, anthracene, pyrene, fluoranthene, naphthacene, chrysene, benzanthracene, benzophenanthrene and triphenylene and the other two groups Ar⁵ stand, identically or differently on each occurrence, for an aryl group having 6 having 18 C atoms, preferably, identically or differently on each occurrence, for phenyl or naphthyl.

In a further preferred embodiment of the invention, Z is selected, identically or differently on each occurrence, from the group consisting of C(R²)₂, C═O, NR², O and S, particularly preferably, identically or differently on each occurrence, C(R²)₂ or NR², very particularly preferably C(R²)₂.

Suitable fluorescent dopants are furthermore the structures depicted below, and the structures disclosed in JP 06/001973, WO 2004/047499, WO 2006/098080, WO 2007/065678, US 2005/0260442 and WO 2004/092111.

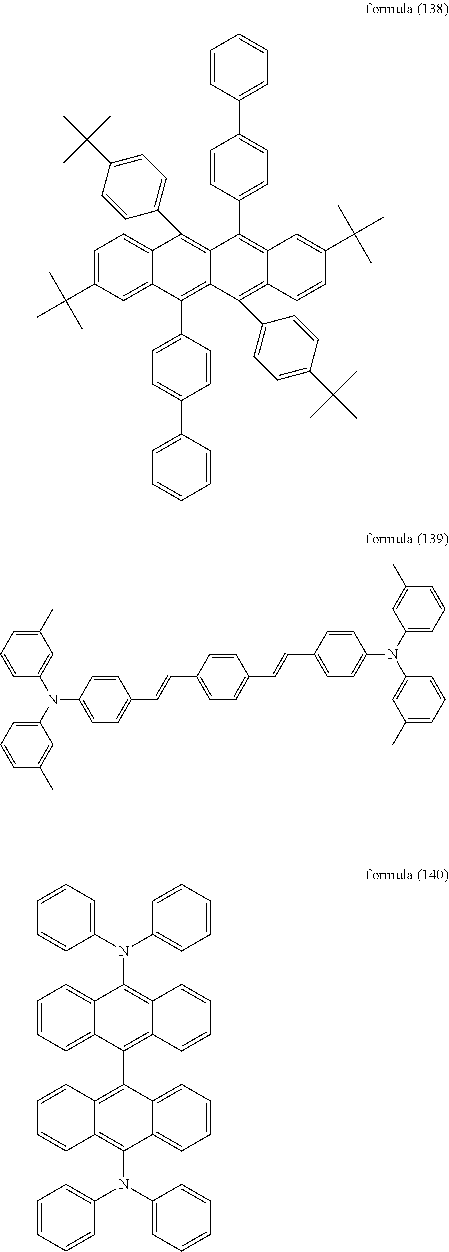

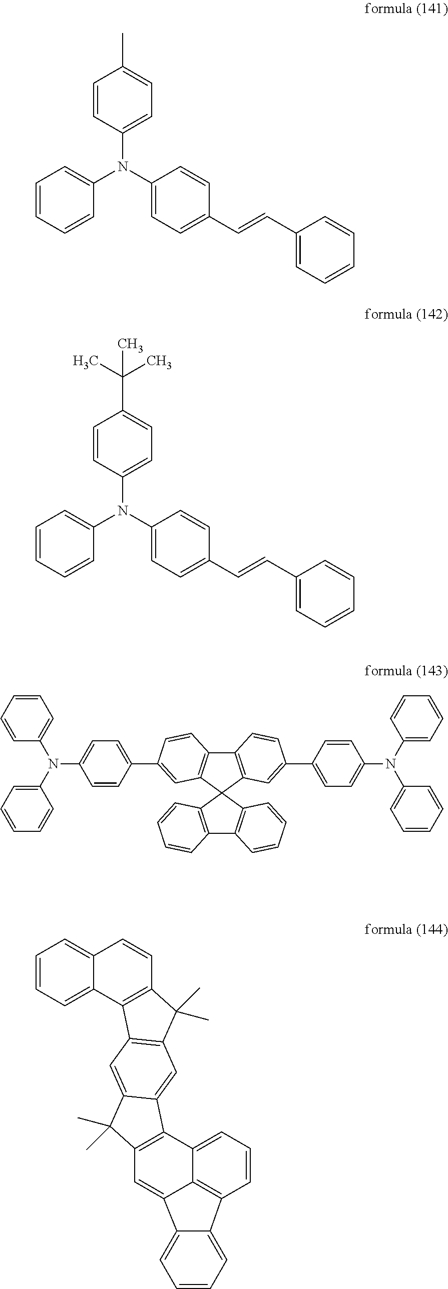

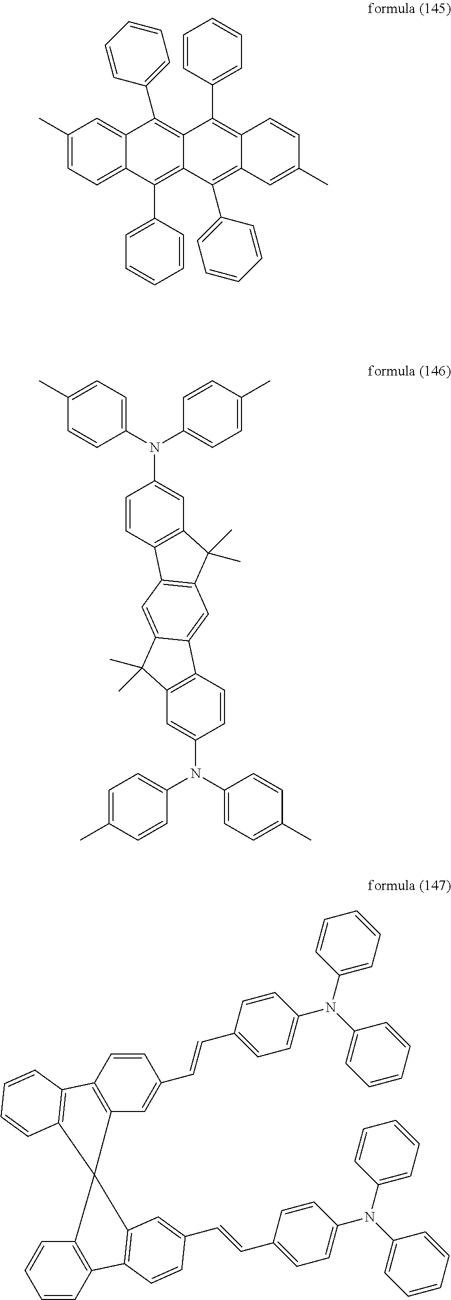

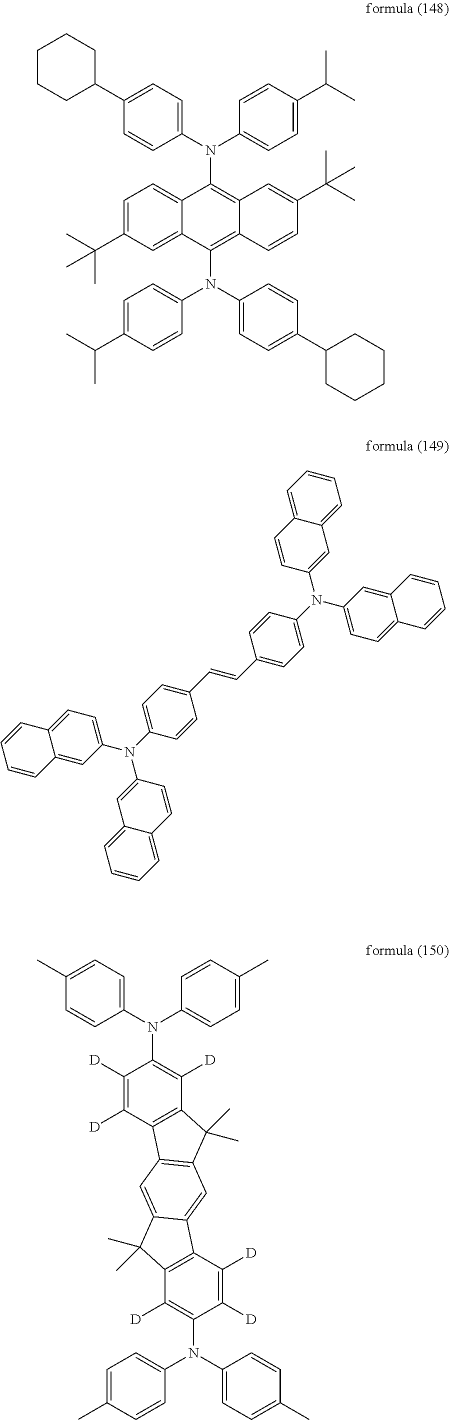

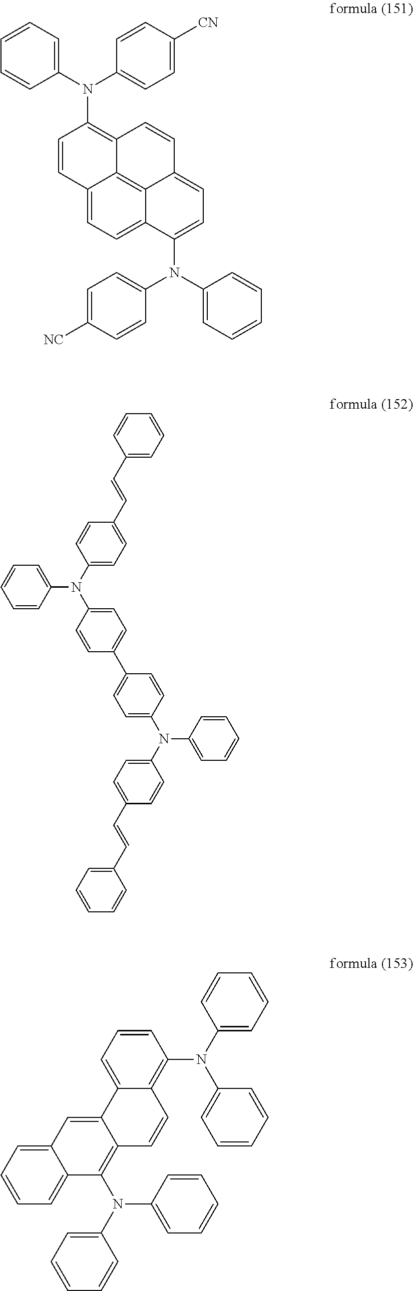 [SMILES: N#Cc1ccc(N(c2ccccc2)c2ccc3ccc4c(N(c5ccccc5)c5ccc(C#N)cc5)ccc5ccc2c3c54)cc1 ; C(=C\c1ccc(N(c2ccccc2)c2ccc(-c3ccc(N(c4ccccc4)c4ccc(/C=C/c5ccccc5)cc4)cc3)cc2)cc1)/c1ccccc1 ; c1ccc(N(c2ccccc2)c2cccc3c2ccc2c(N(c4ccccc4)c4ccccc4)c4ccccc4cc23)cc1]

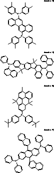

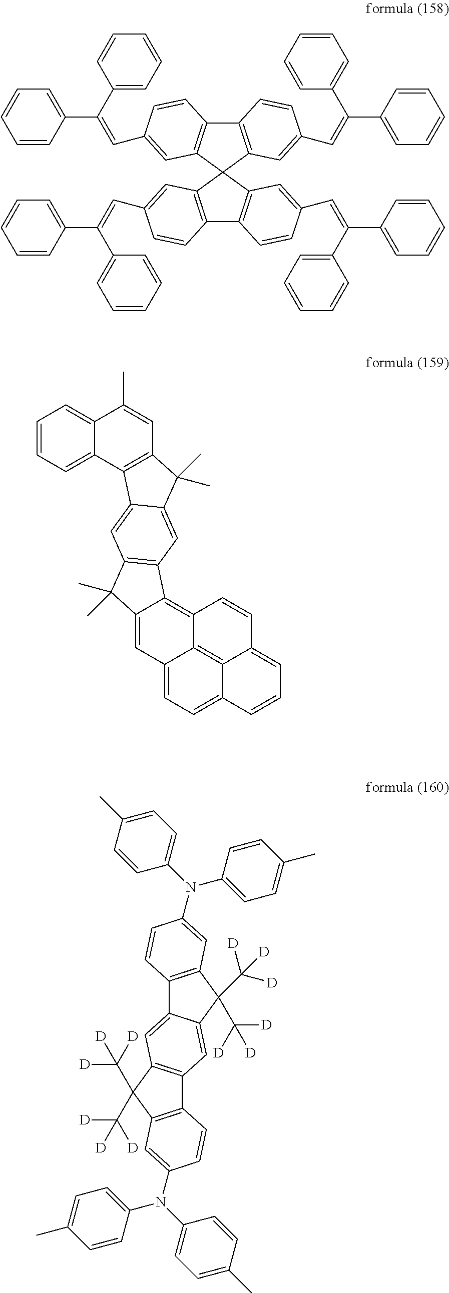

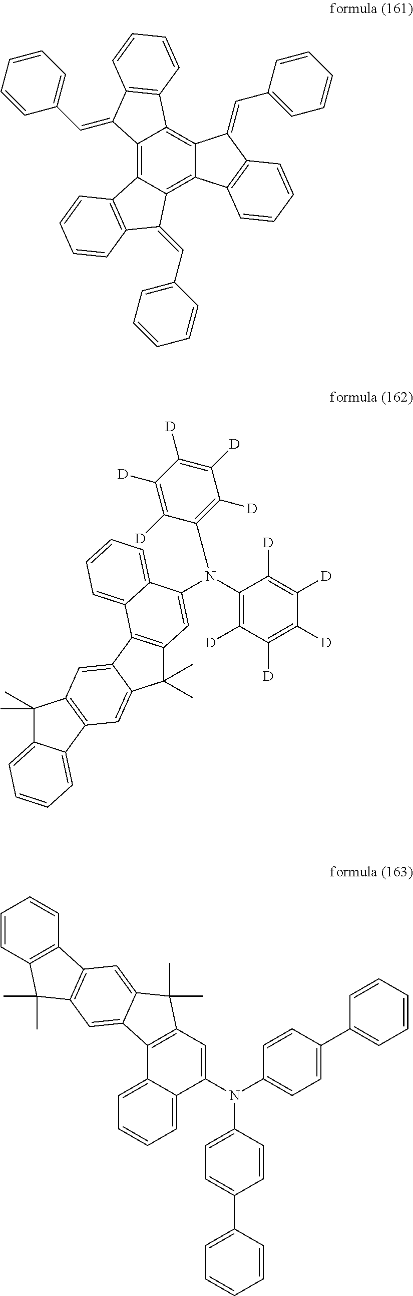

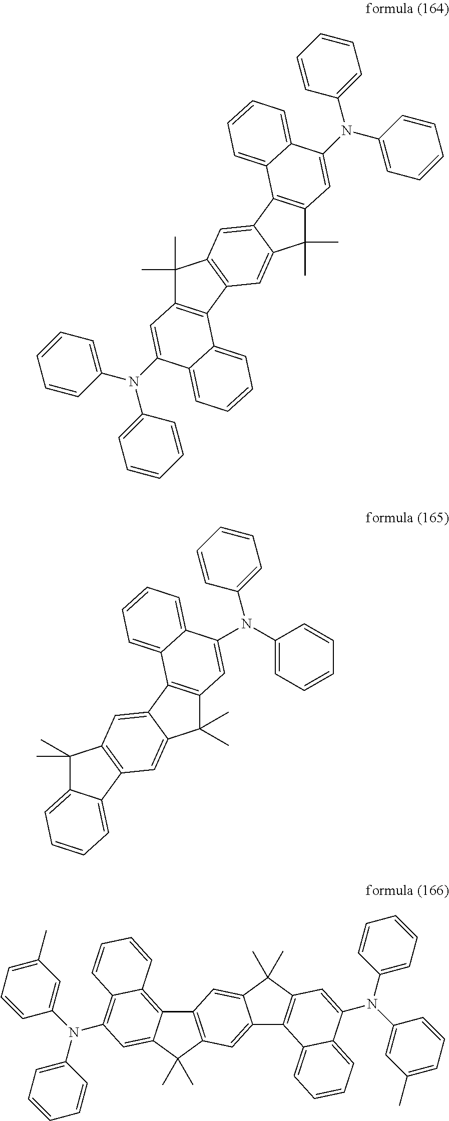 [SMILES: CC1(C)c2cc3c(cc2-c2c1cc(N(c1ccccc1)c1ccccc1)c1ccccc21)C(C)(C)c1cc(N(c2ccccc2)c2ccccc2)c2ccccc2c1-3 ; CC1(C)c2ccccc2-c2cc3c(cc21)-c1c(cc(N(c2ccccc2)c2ccccc2)c2ccccc12)C3(C)C ; Cc1cccc(N(c2ccccc2)c2cc3c(c4ccccc24)-c2cc4c(cc2C3(C)C)-c2c(cc(N(c3ccccc3)c3cccc(C)c3)c3ccccc23)C4(C)C)c1]

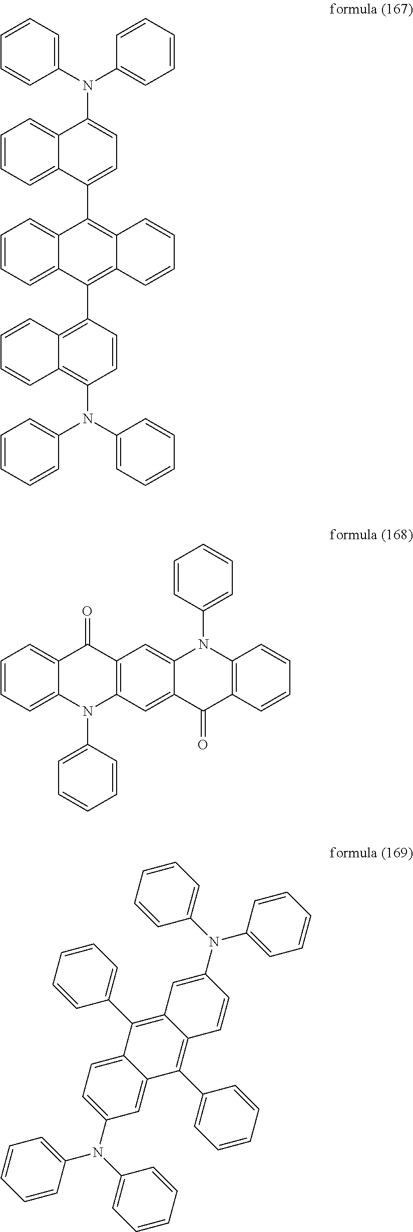 [SMILES: c1ccc(N(c2ccccc2)c2ccc(-c3c4ccccc4c(-c4ccc(N(c5ccccc5)c5ccccc5)c5ccccc45)c4ccccc34)c3ccccc23)cc1 ; O=c1c2ccccc2n(-c2ccccc2)c2cc3c(=O)c4ccccc4n(-c4ccccc4)c3cc12 ; c1ccc(-c2c3ccc(N(c4ccccc4)c4ccccc4)cc3c(-c3ccccc3)c3ccc(N(c4ccccc4)c4ccccc4)cc23)cc1]

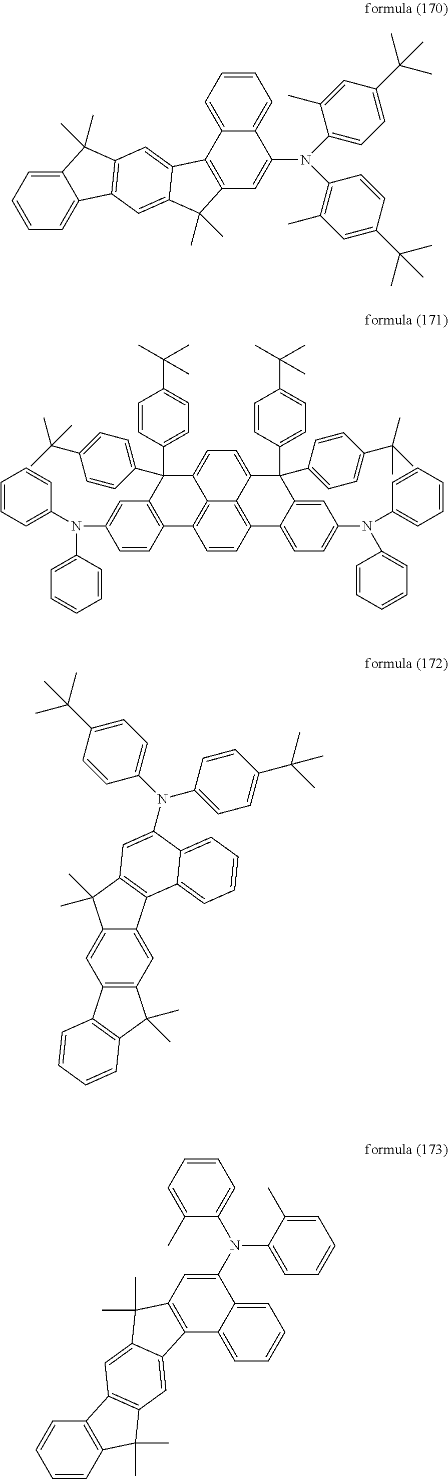

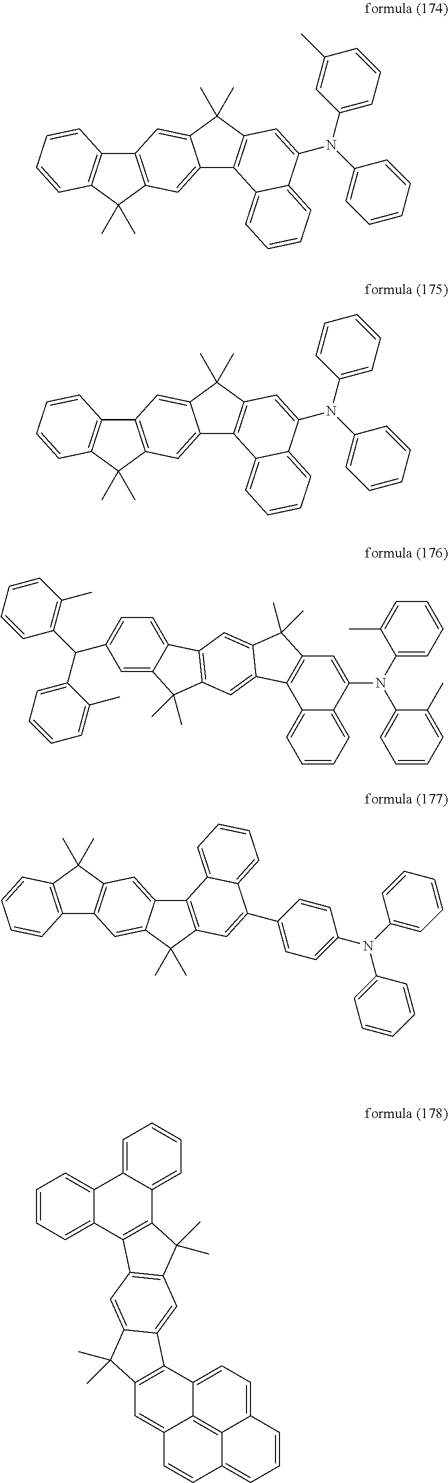

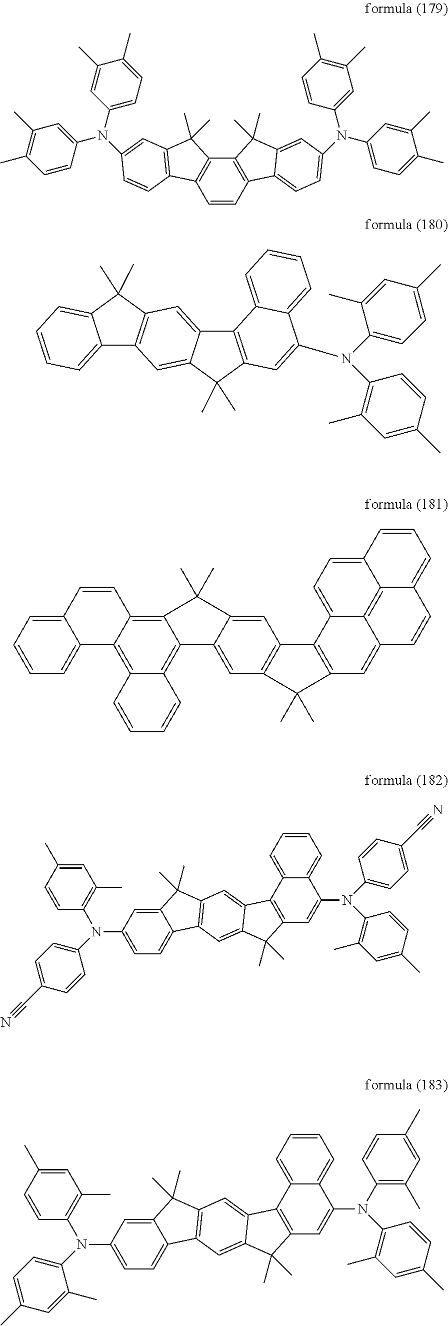

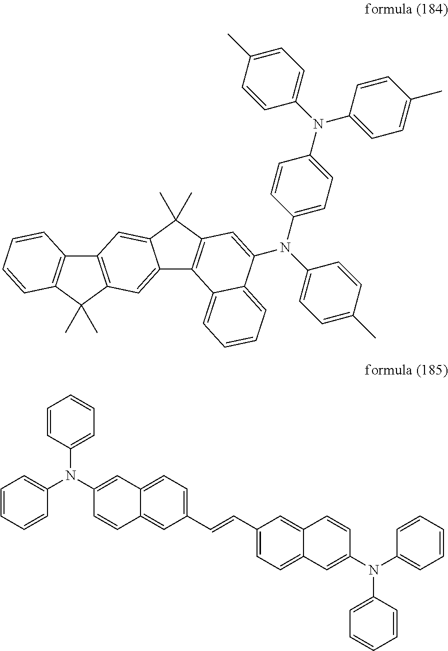 [SMILES: Cc1ccc(N(c2ccc(C)cc2)c2ccc(N(c3ccc(C)cc3)c3cc4c(c5ccccc35)-c3cc5c(cc3C4(C)C)-c3ccccc3C5(C)C)cc2)cc1 ; C(=C\c1ccc2cc(N(c3ccccc3)c3ccccc3)ccc2c1)/c1ccc2cc(N(c3ccccc3)c3ccccc3)ccc2c1]

In a further particularly preferred embodiment of the present invention, the emitter unit is a triplet emitter, in particular if highly efficient emission of red or green light is desired.

A triplet emitter, also known as phosphorescent compound, is taken to mean a compound which exhibits luminescence from an excited state having relatively high spin multiplicity, i.e. a spin state greater than 1, in particular from an excited triplet state or from an MLCT mixed state. Suitable phosphorescent compounds are, in particular, compounds which emit light, preferably in the visible region, on suitable excitation and in addition contain at least one atom having atomic numbers of greater than 38 and less than 84, particularly preferably greater than 56 and less than 80. Preferred phosphorescence emitters are compounds which contain copper, molybdenum, tungsten, rhenium, ruthenium, osmium, rhodium, iridium, palladium, platinum, silver, gold or europium, in particular compounds which contain iridium, platinum or copper. Examples of the emitters described above are revealed by the applications WO 00/7065, WO 01/41512, WO 02/02714, WO 02/15645, EP 1191613, EP 1191612, EP 1191614, WO 05/033244. In general, all phosphorescent complexes as are used in accordance with the prior art for phosphorescent OLEDs and as are known to the person skilled in the art in the area of organic electroluminescence are suitable.

In a further embodiment according to the invention, the phosphorescent emitter preferably contains an organometallic compound unit, or represents an organometallic compound unit. The organometallic compound unit is preferably an organometallic coordination compound. An organometallic coordination compound is taken to mean a compound containing a metal atom or ion in the centre of the compound surrounded by an organic compound as ligand. An organometallic coordination compound is in addition characterised in that a carbon atom of the ligand is bonded to the central metal via a coordination bond.

It is furthermore preferred for the organic ligand to be a chelate ligand. A chelate ligand is taken to mean a bi- or polydentate ligand, which can correspondingly bond to the central metal via two or more atoms.

The organic ligand preferably contains a unit (called ligand unit below) which is represented by the following formula (186):

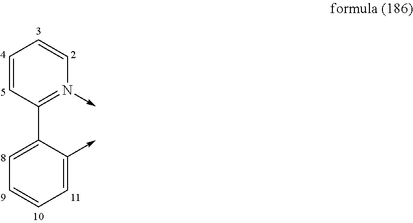

where the atoms from which the arrows point away are coordinated to the metal atom, and the numbers 2 to 5 and 8 to 11 merely represents a numbering in order to distinguish the C atoms. Instead of hydrogen at positions 2, 3, 4, 5, 8, 9, 10 and 11, independently of one another, the organic ligand unit of the formula (186) may contain a substituent selected from the group consisting of C₁₋₆-alkyl, C₆₋₂₀-aryl, 6- to 14-membered heteroaryl and further substituents.

Preferred examples of the ligands of the formula (186) are the following compounds (187) to (195):

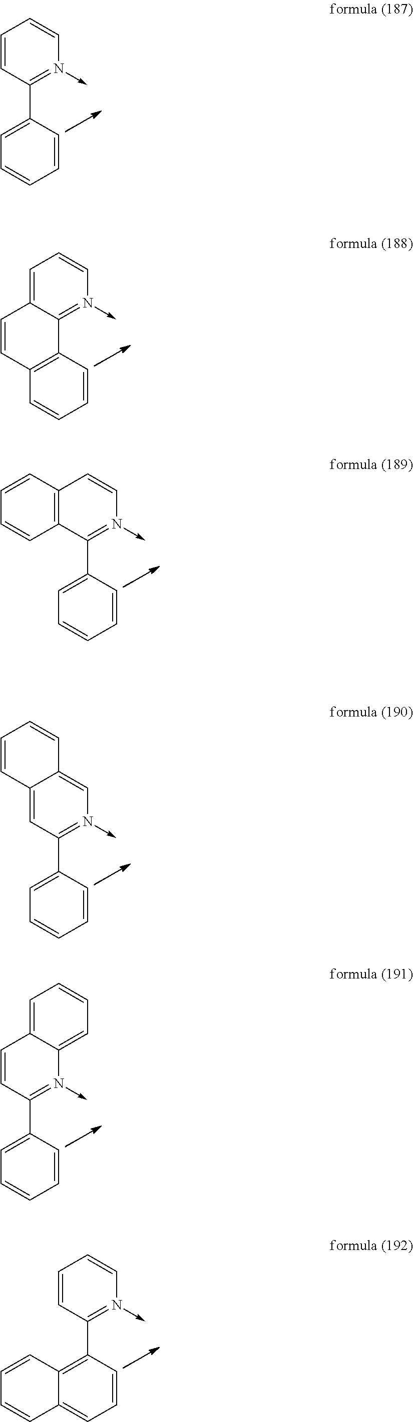

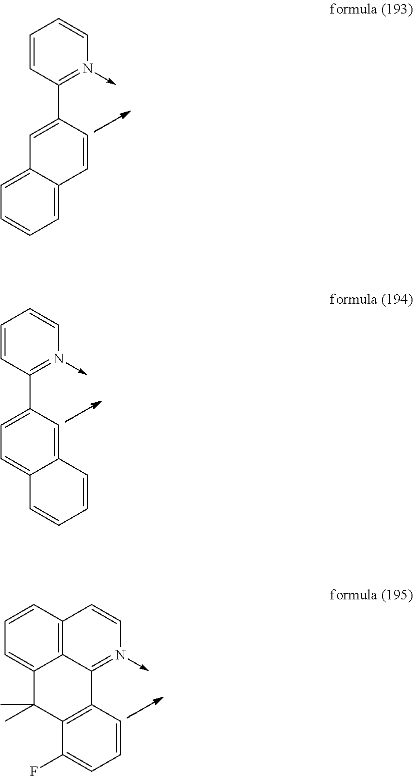

Greater preference is given in the sense of the present invention to compounds (187), (189) and (195).

The metal centre of the organic coordination compound is preferably a metal atom in oxidation state 0.

In a preferred embodiment, the metal centre is Pt or Ir. If the metal centre is Pt, it preferably has the coordination number 4. In the case of Ir as metal centre, the coordination number is preferably 6.

It is furthermore preferred for Pt to be coordinated by two ligand units of the formula (186) and for Ir to be coordinated by three ligand units of the formula (186) in the manner indicated above.

Examples of suitable phosphorescent compounds or group are shown below.

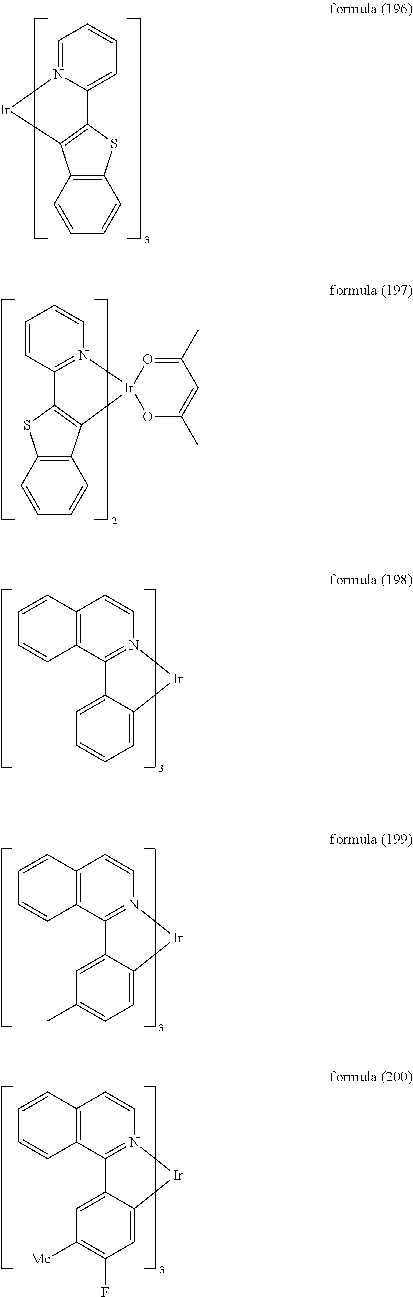

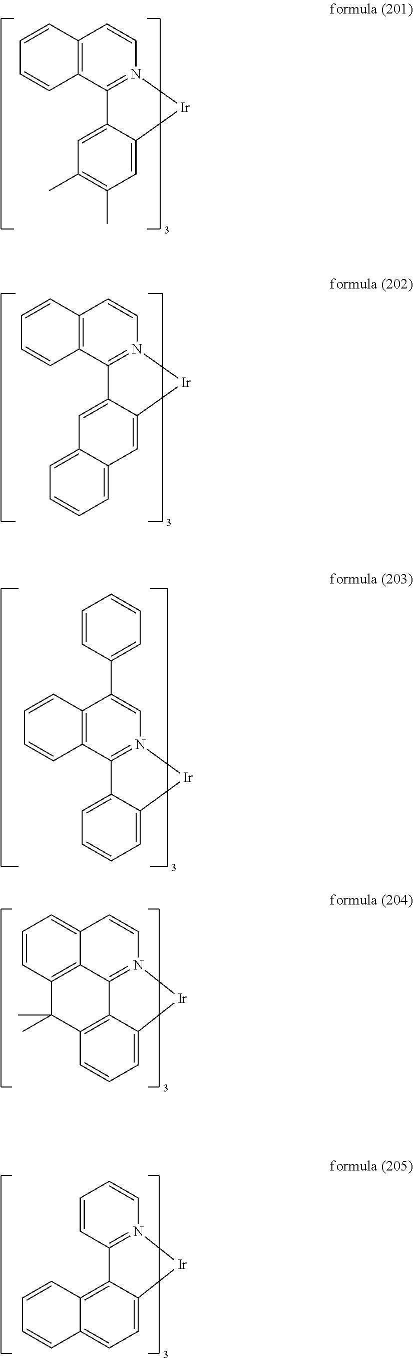

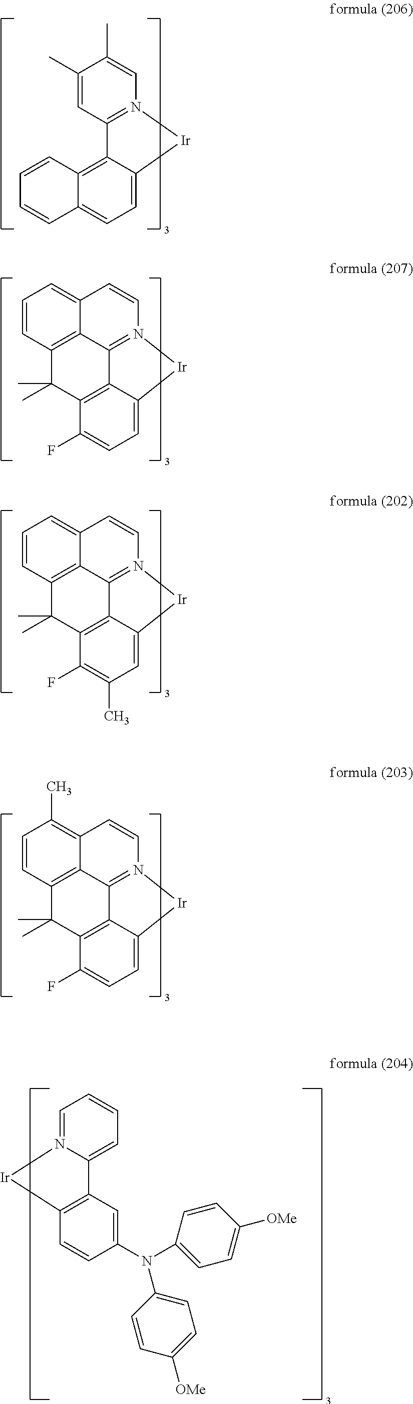

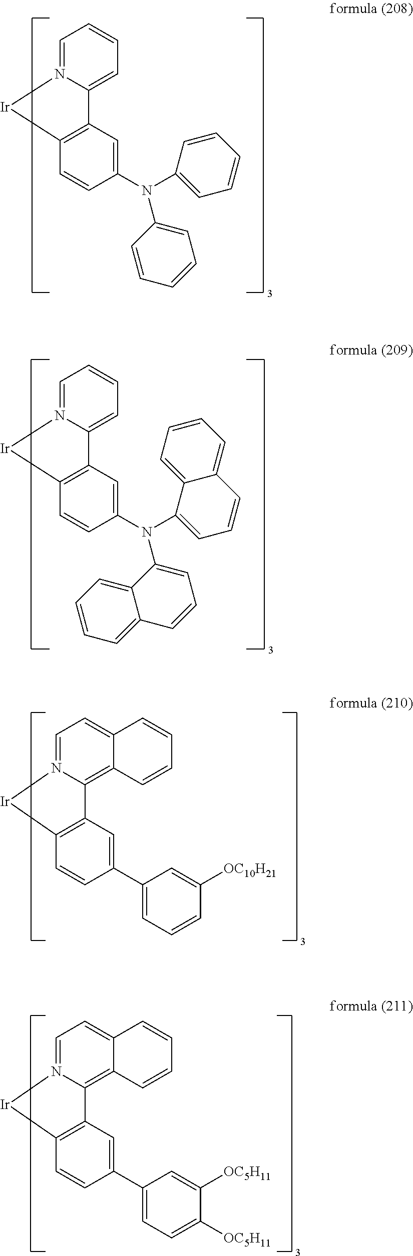

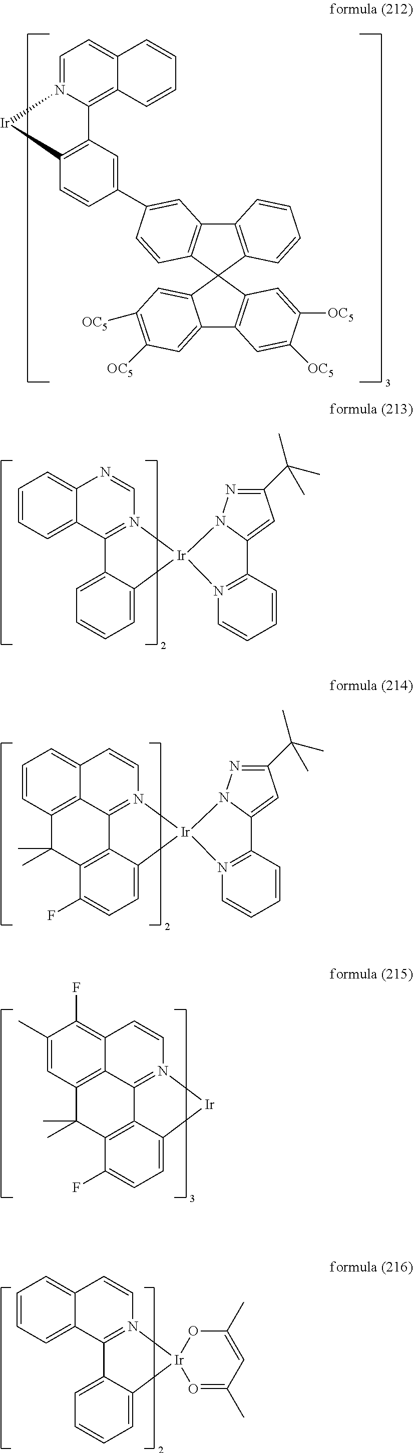

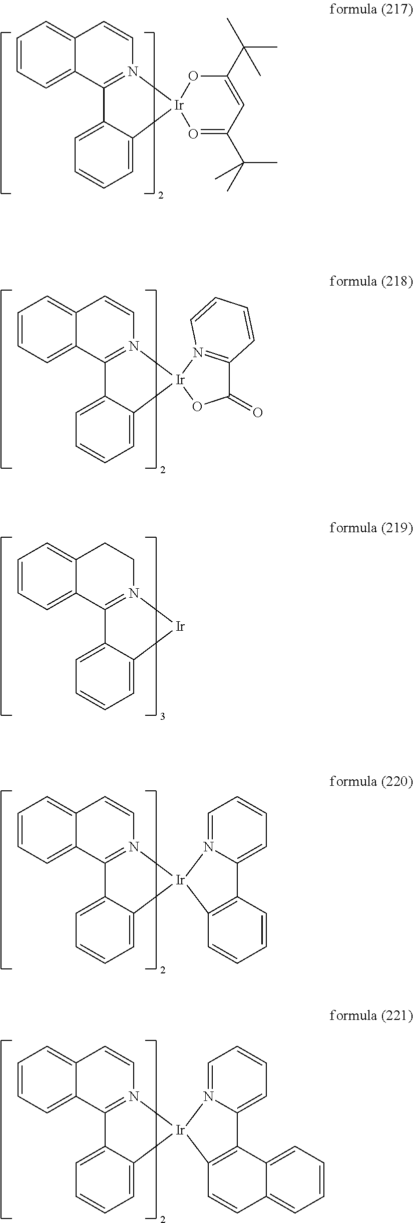

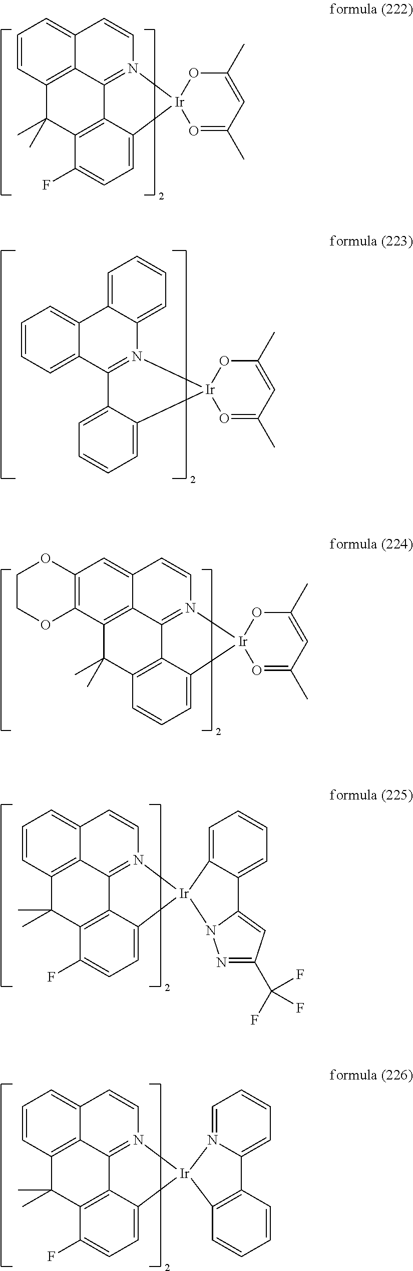

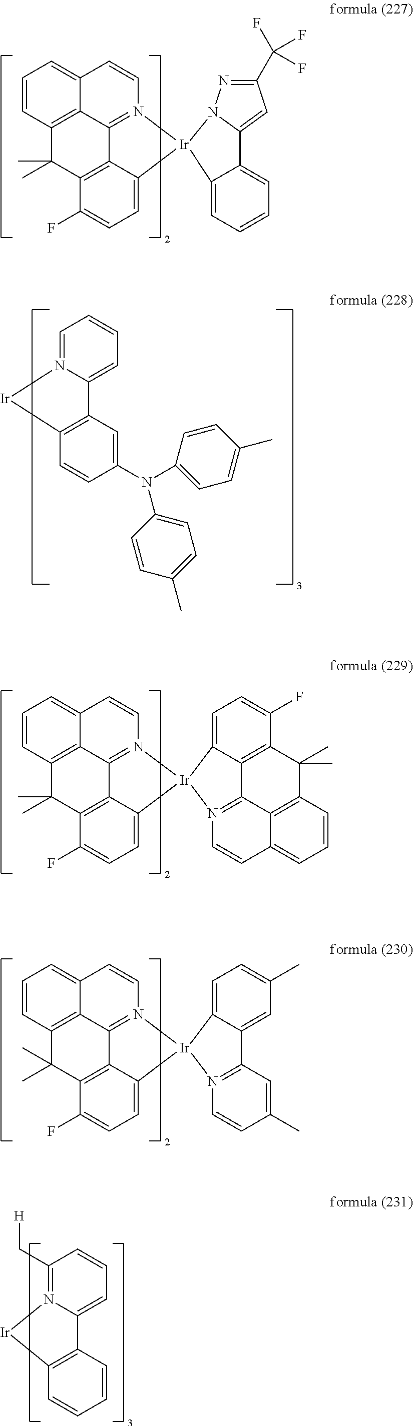

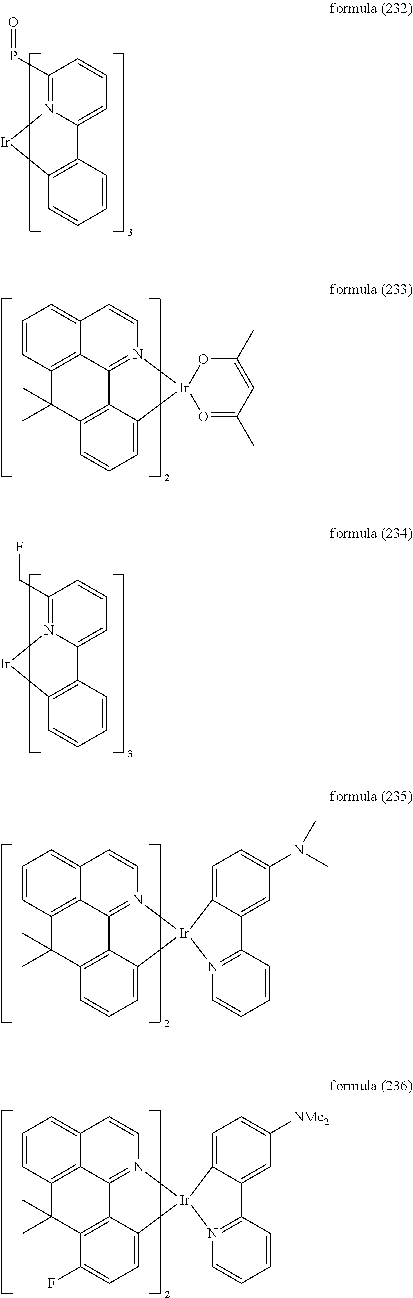

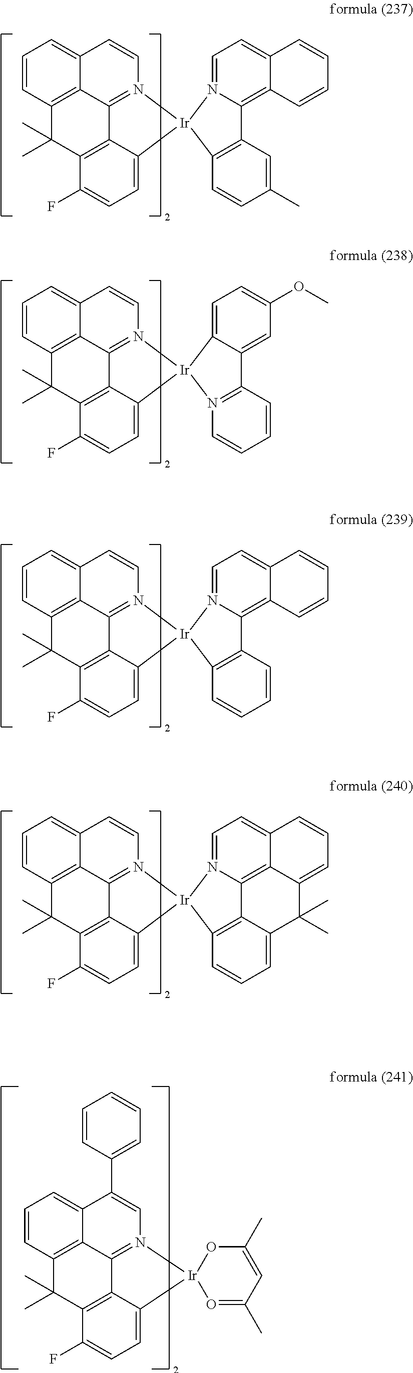

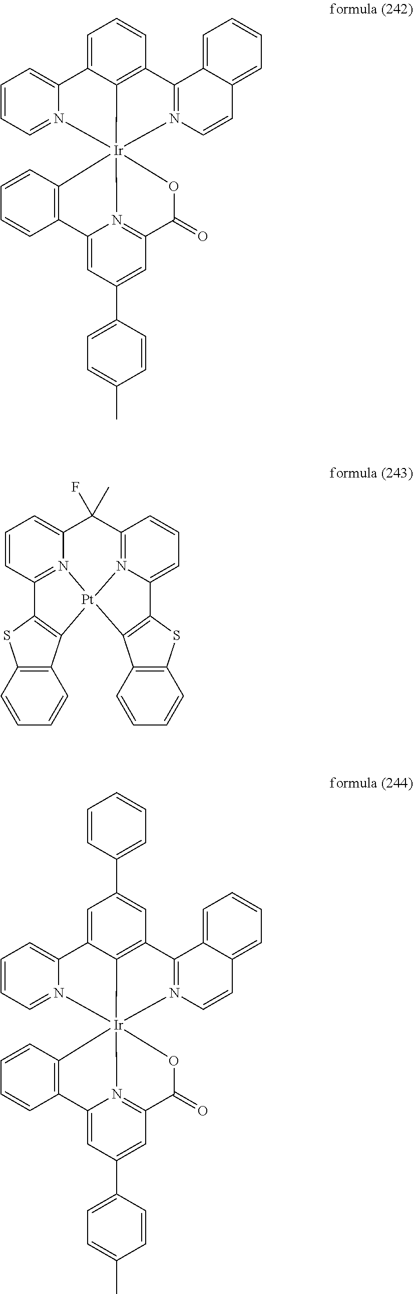

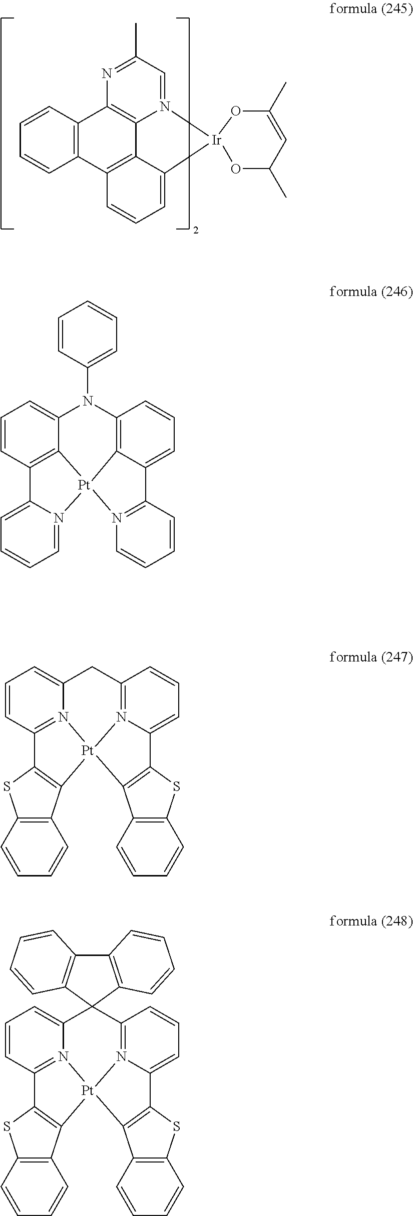

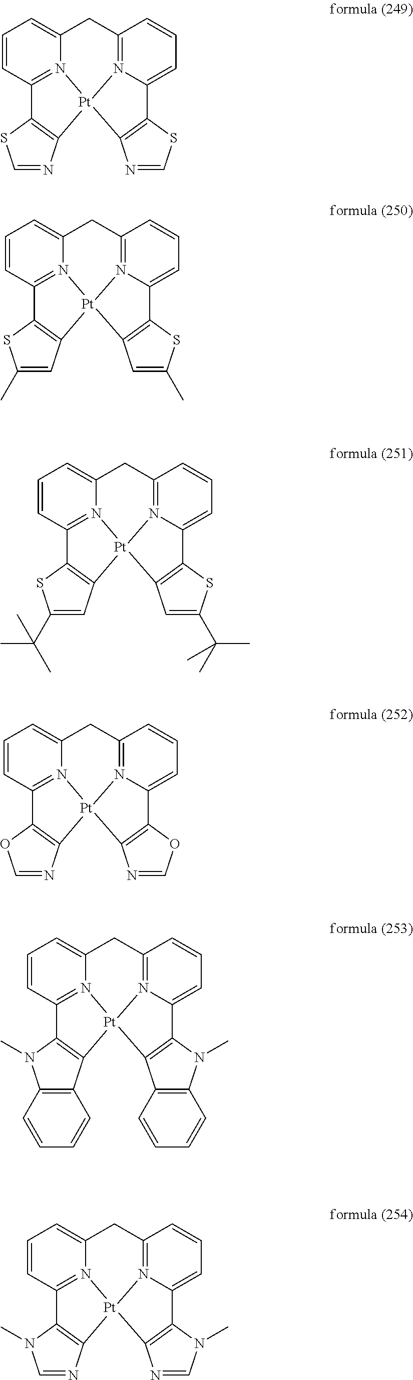

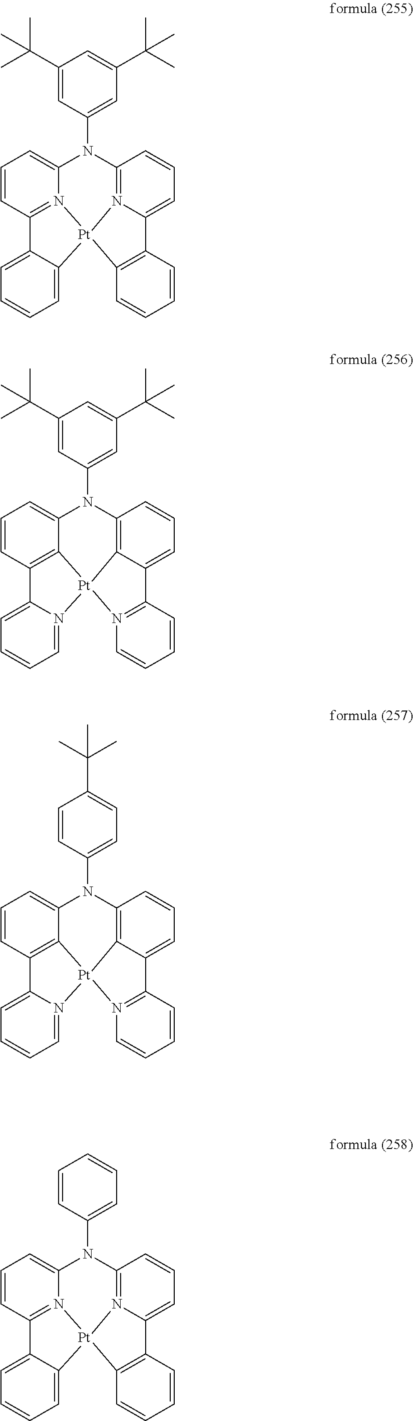

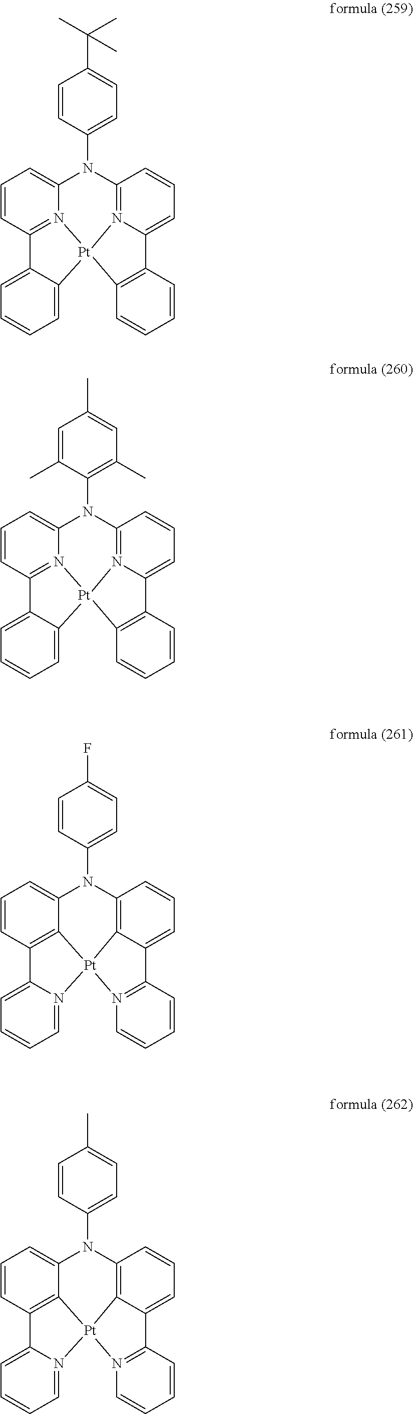

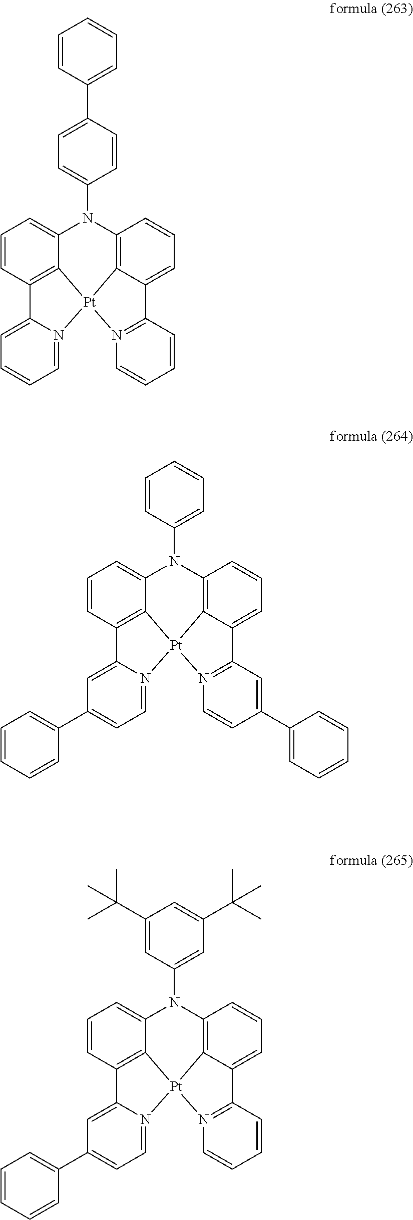

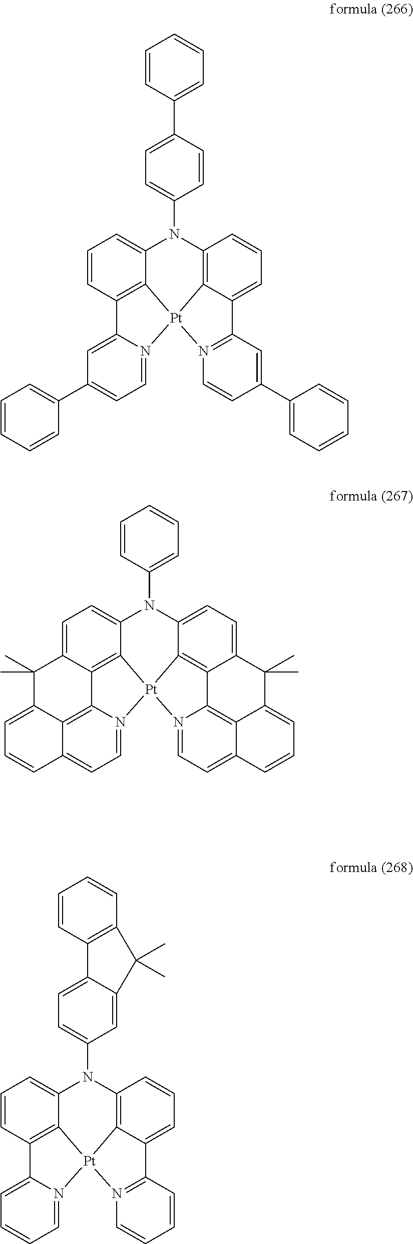

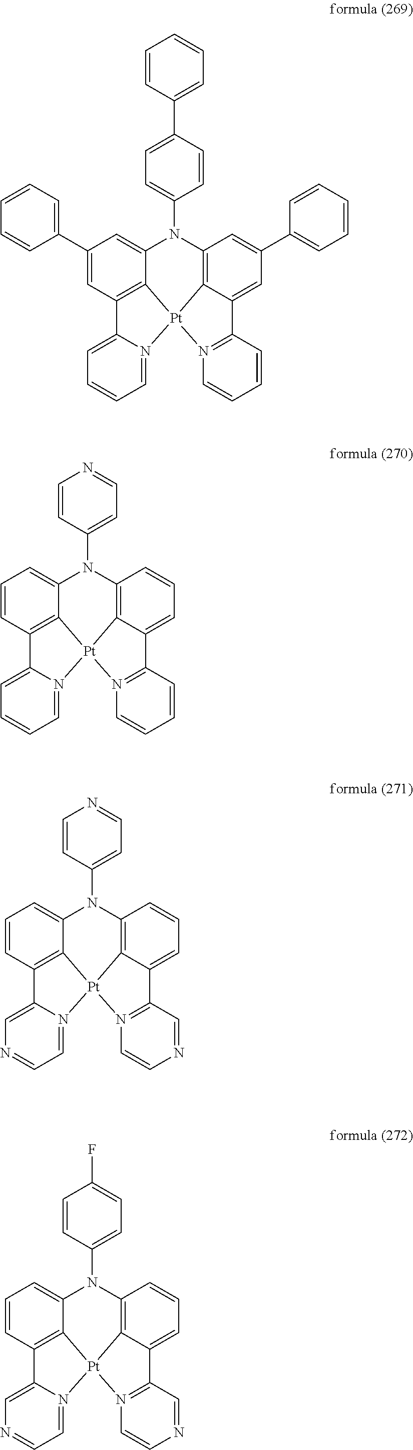

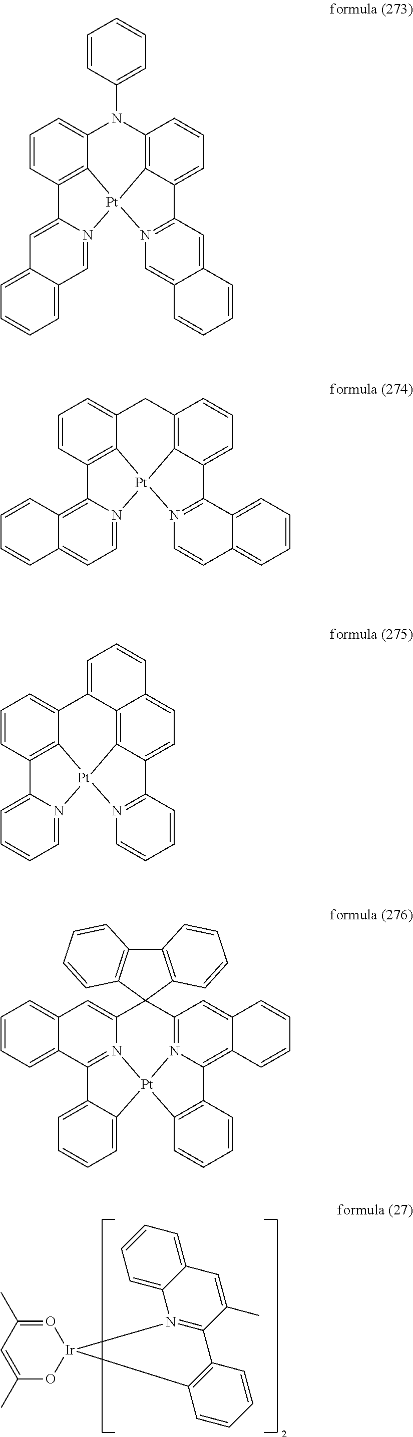

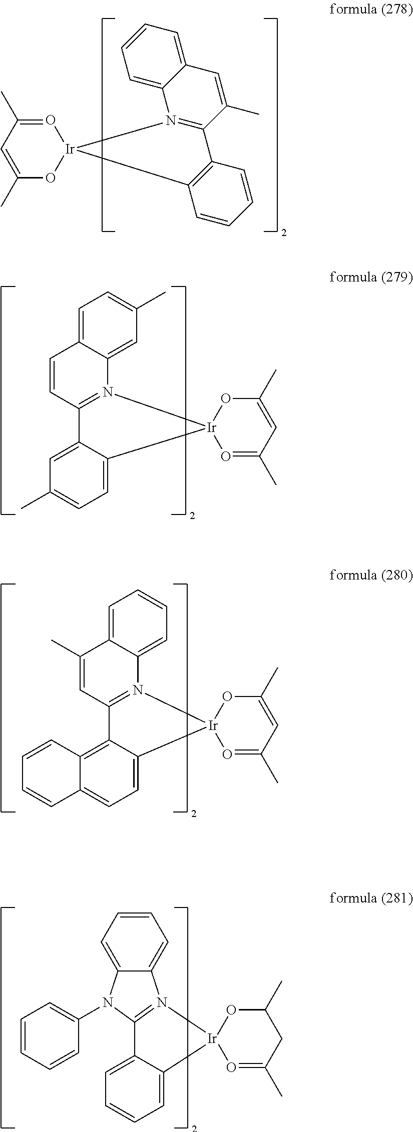

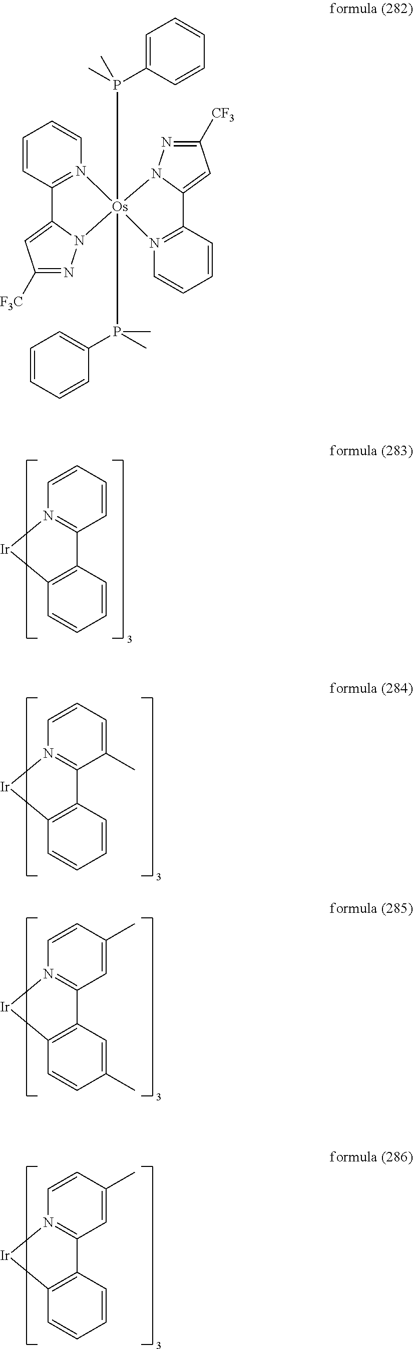

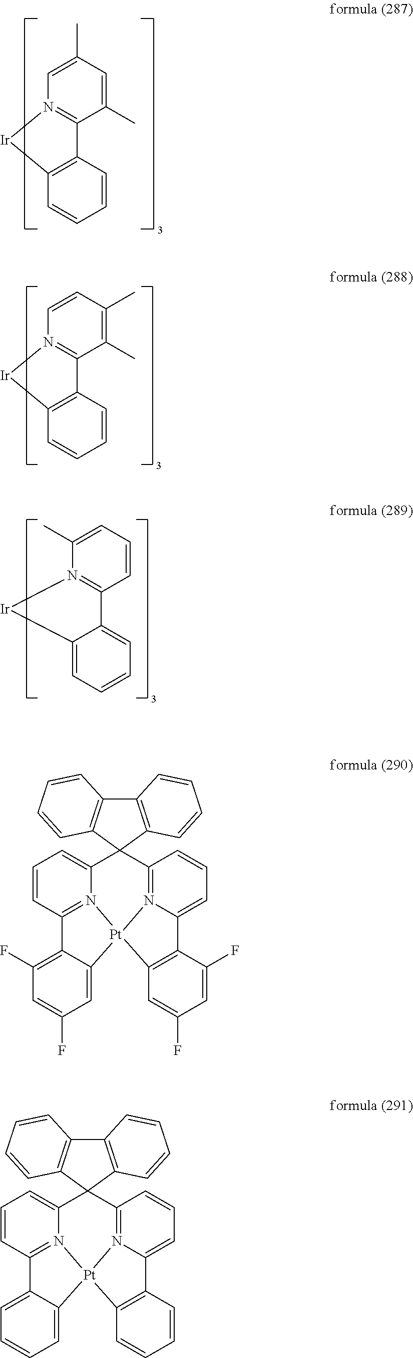

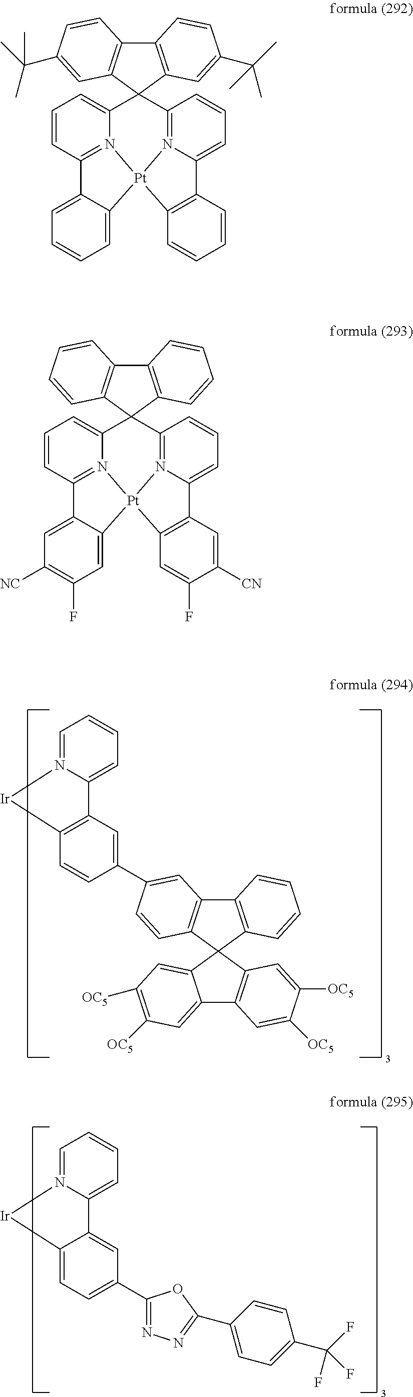

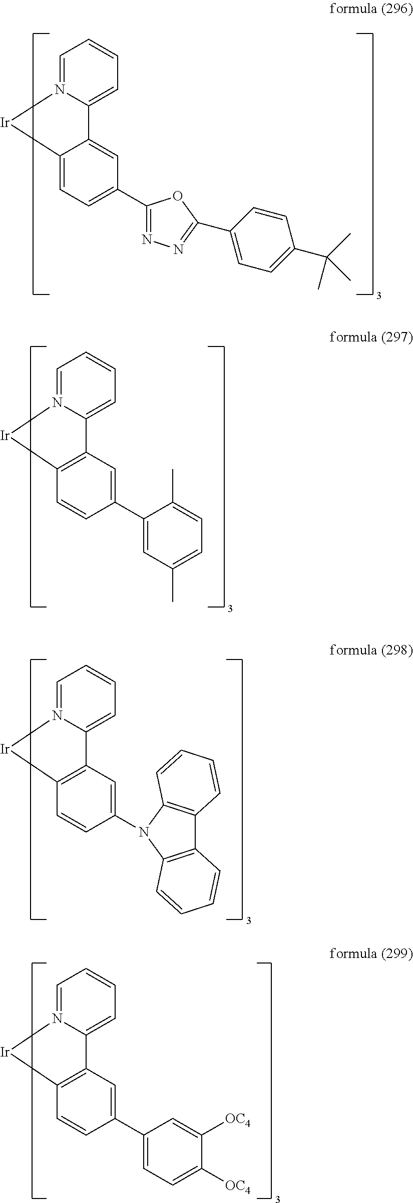

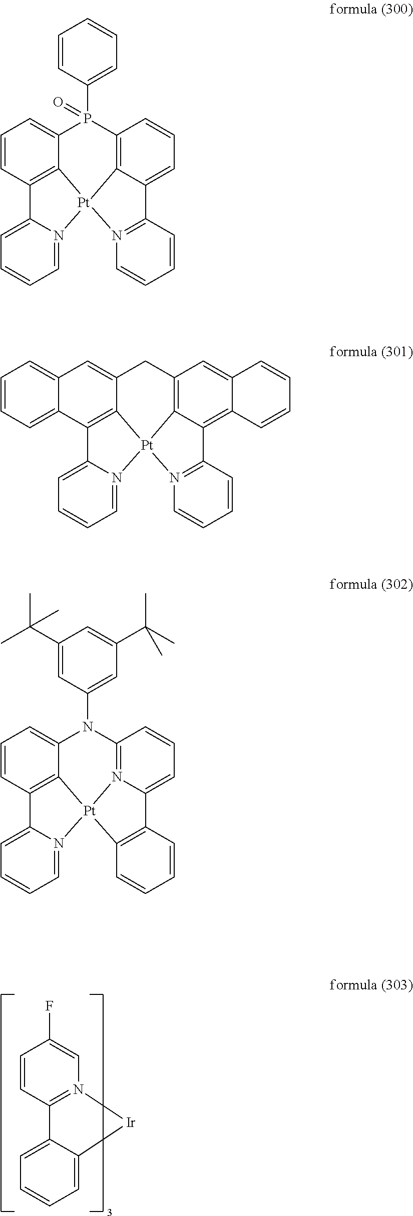

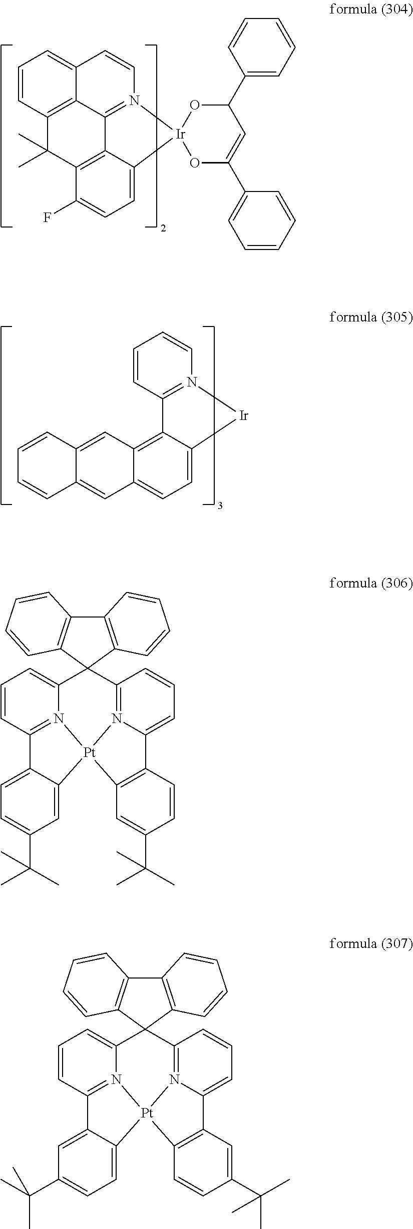

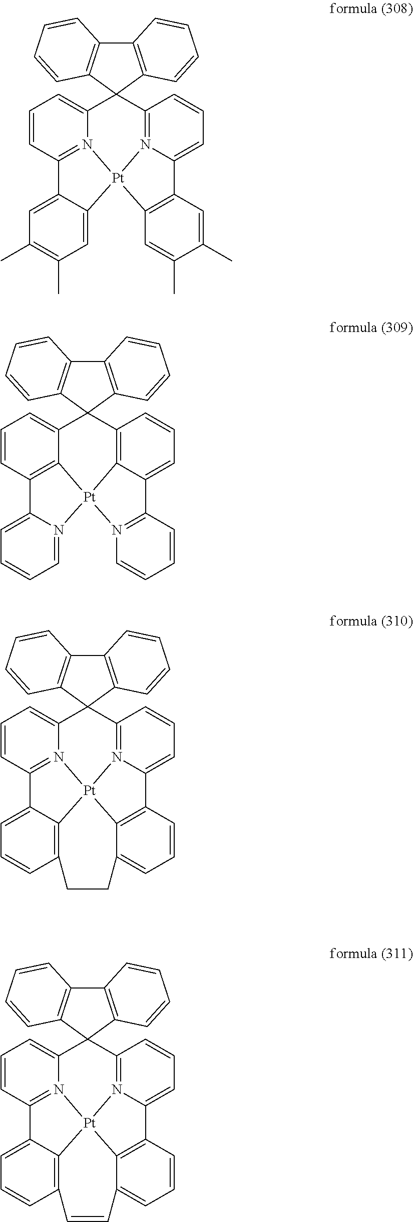

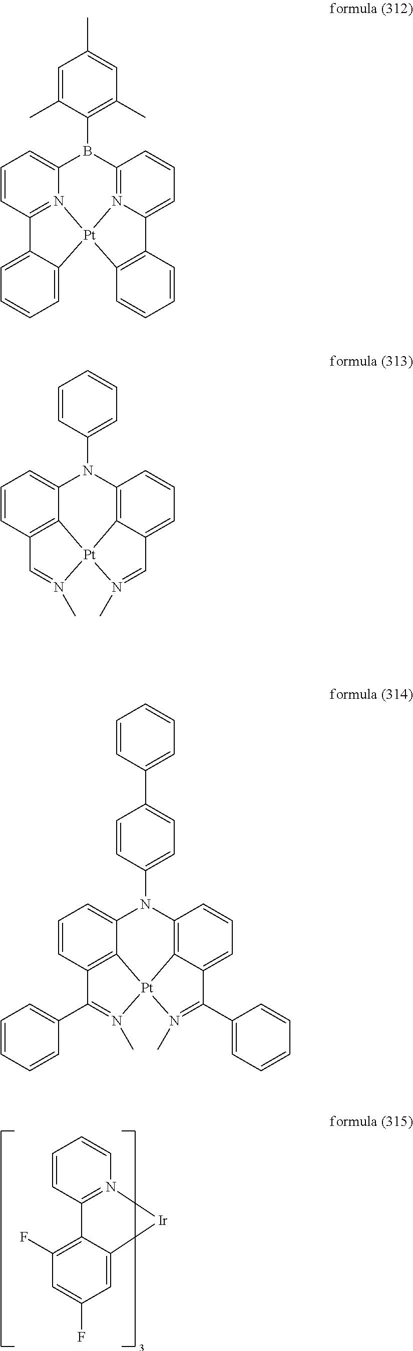

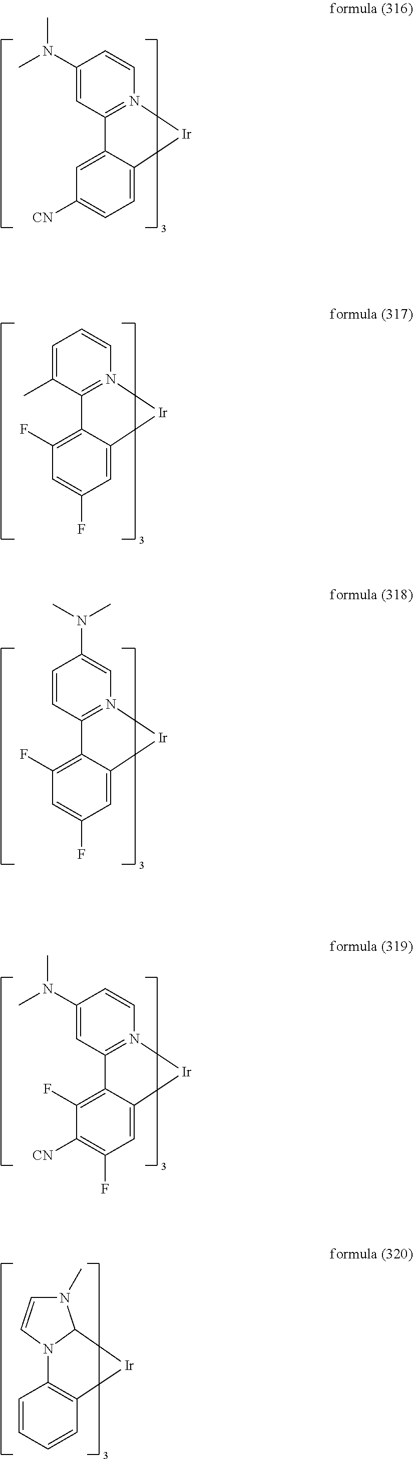

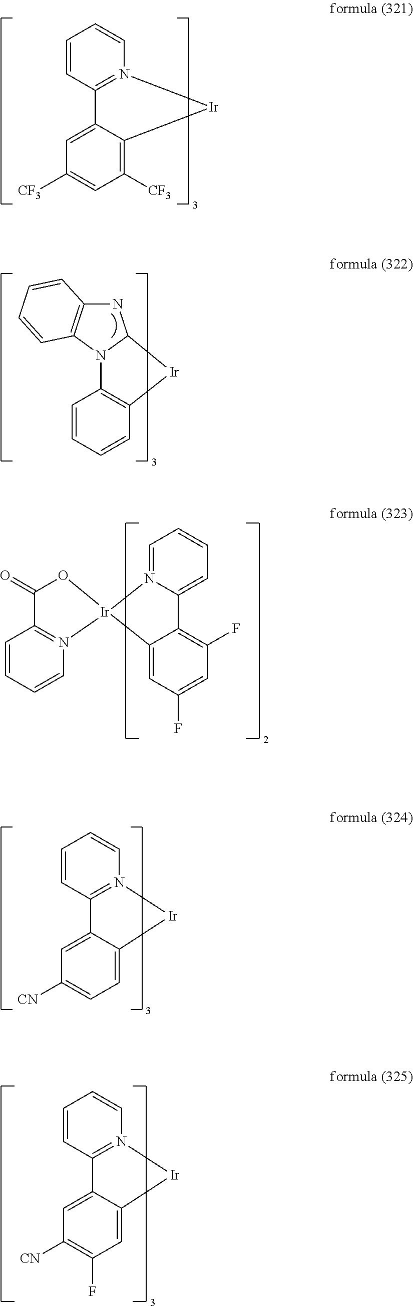

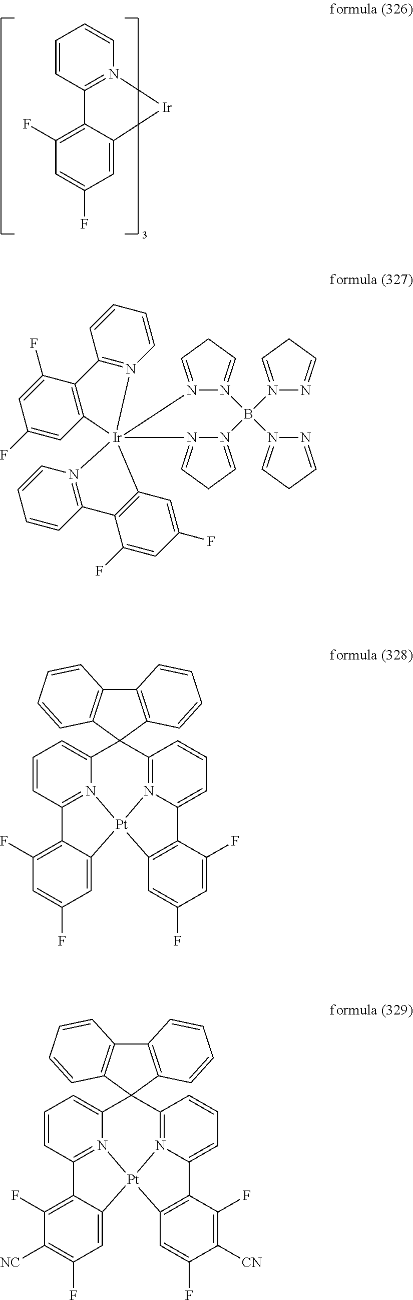

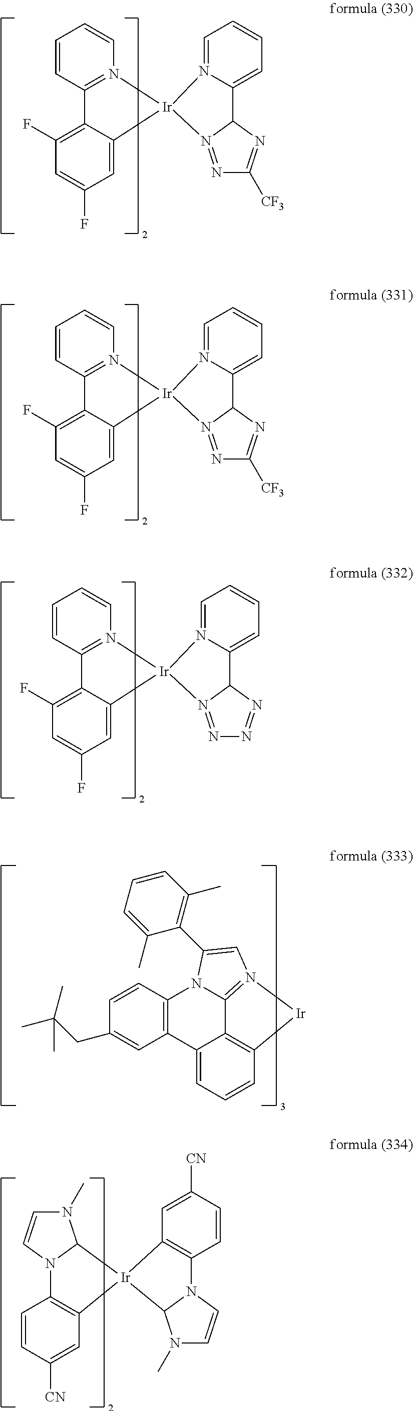

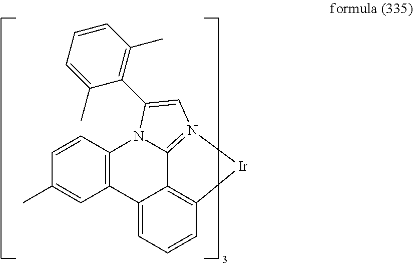

Structural units from group 5 are those which improve transfer from the singlet state to the triplet state and which, employed in support of the above-mentioned triplet emitter units, improve the phosphorescence properties of these structural elements. Suitable for this purpose are, in particular, carbazole and bridged carbazole dimer units, as described, for example, in WO 2004/070772 A2 and WO 2004/113468 A1. Also suitable for this purpose are ketones, phosphine oxides, sulfoxides, sulfones, silane derivatives and similar compounds, as described, for example, in WO 2005/040302 A1.

Structural units from group 6, besides those mentioned above, are those which contain at least one further aromatic structure or another conjugated structure which does not fall under the above-mentioned groups, i.e. which have only little influence on the charge-carrier mobilities, are not organometallic complexes or do not influence singlet-triplet transfer. Structural elements of this type can influence the emission colour of the resultant copolymers. Depending on the unit, they can therefore also be employed as emitters. Preference is given here to aromatic structures having 6 to 40 C atoms or also tolan, stilbene or bisstyrylarylene derivatives, each of which may be substituted by one or more radicals R. Particular preference is given here to the incorporation of 1,4 phenylene, 1,4-naphthylene, 1,4- or 9,10-anthrylene, 1,6-, 2,7- or 4,9-pyrenylene, 3,9- or 3,10-perylenylene, 4,4′-biphenylylene, 4,4″terphenylylene, 4,4′-bi-1,1′-naphthylylene, 4,4′-tolanylene, 4,4′-stilbenylene, 4,4″bisstyrylarylene, benzothiadiazole and corresponding oxygen derivatives, quinoxaline, phenothiazine, phenoxazine, dihydrophenazine, bis(thiophenyl)arylene, oligo(thiophenylene), phenazine, rubrene, pentacene or perylene derivatives, which are preferably substituted, or preferably conjugated push-pull systems (systems which are substituted by donor and acceptor substituents) or systems such as squarines or quinacridones, which are preferably substituted.

Structural units from group 7 are units which contain aromatic structures having 6 to 40 C atoms, which are typically used as polymer backbone. These are, for example, 4,5-dihydropyrene derivatives, 4,5,9,10-tetrahydropyrene derivatives, fluorene derivatives, 9,9′-spirobifluorene derivatives, phenanthrene derivatives, 9,10-dihydrophenanthrene derivatives, 5,7-dihydrodibenzoxepine derivatives and cis- and trans-indenofluorene derivatives, but in principle also all similar structures which, after polymerisation, would result in a conjugated, bridged or unbridged polyphenylene or polyphenylene-vinylene homopolymer. Here too, the said aromatic structure may contain heteroatoms, such as O, S or N, in the backbone or a side chain.

Structural units from group 8 are those which influence the film-morphological properties and/or the rheological properties of the copolymers, such as, for example, siloxanes, long alkyl chains or fluorinated groups, but also particularly rigid or flexible units, such as, for example, liquid crystal-forming units or crosslinkable groups.

The syntheses of the above-described units from groups 1 to 8 and of the further emitting units are known to the person skilled in the art and are described in the literature, for example in WO 2005/014689 A2, WO 2005/030827 A1 and WO 2005/030828 A1. These documents and the literature cited therein are incorporated into the present application by way of reference.

Preference is given to copolymers according to the invention which simultaneously, besides structural units of the formula (1), preferably where k=0, additionally contain one or more units selected from groups 1 to 8. It may furthermore be preferred for more than one structural unit from one group to be present simultaneously.

However, a smaller proportion of the emitting units, in particular green- and red-emitting units, may also be preferred, for example for the synthesis of white-emitting copolymers. The way in which white-emitting copolymers can be synthesised is described in detail, for example, in WO 2005/030827 A1 and WO 2005/030828 A1.

In a particularly preferred embodiment, the copolymer is a hole-transport material, or an interlayer material. It is furthermore preferred for the interlayer material to have an LUMO at least −2.5 eV (or higher) and triplet level at least of 2.6 eV (or higher). This can be achieved by means of the copolymers according to the invention, for example, in the following two ways:

(a) by polymers according to the invention which principally recurring units selected from a structural unit of the formula (1), preferably where k=1, and which have a preferred structure of structure (V), (VI), (X) and (XI). Preference is given to a copolymer which contains in total at least 50 mol % of the structural units of the formula (1), preferably where k=1, very preferably at least 70 mol %, very particularly preferably at least 80 mol % and especially preferably at least 90 mol %, based on all units of the copolymer;
(b) by polymers according to the invention which, besides at least one structural unit of the formula (1), preferably where k=1, also contain units from group 1 (HIM/HTM). The copolymer preferably contains a structure of structure (VII), (VIII) and/or structure (IX), where A is an HIM or HTM unit. The sum of structural units of the formula (1) and units from group 7 of the polymer particularly preferably makes up at least 50 mol %, based on all units of the copolymer. Very particular preference is given to a proportion of 0.5 to 30 mol % of the HIM or HTM; especial preference is given to a proportion of 5 to 20 mol % of the HIM or HTM.

In a further particularly preferred embodiment, the copolymer is a matrix material, very particularly a matrix material having a high triplet level for phosphorescent emitters. This can be achieved by different ways by means of the copolymers according to the invention, for example by

(a) polymers according to the invention, where most of the recurring units are selected from a structural unit of the formula (1), preferably where k=1, and which preferably have a structure of structure (V), (VI), (X) and/or structure (XI). The copolymer very preferably contains in total the structural units of the formula (1) in an amount of at least 50 mol %, particularly preferably at least 70 mol %, very particularly preferably at least 80 mol % and especially preferably at least 90 mol %, based on all units of the copolymer;
(b) polymers according to the invention which, besides at least one structural unit of the formula (1), preferably where k=1, also contain units from group 5. It is preferred here for the sum of structural units of the formula (1) of the polymer to be at least 40 mol %, based on all units of the copolymer. This proportion of group 5 units is very preferably 1 to 50 mol % of group 5, very particularly preferably 5 to 40 mol % and especially preferably 20 to 40 mol %.
(c) polymers according to the invention which, besides at least one structural unit of the formula (1), preferably where k=1, also contain (EIM/ETM) units from group 2. Preference is given here to a copolymer which contains in total the structural units of the formula (1) in an amount of at least 40 mol %, based on all units of the copolymer. This proportion of group 2 units is very preferably 0.5 to 30 mol %, very particularly preferably 1 to 30 mol %; especially preferably 10 to 20 mol %.

In each case, the structures the copolymer of structure (V), (VII) and/or structure (VIII) and of structure (X) and (XI) are preferred.

In still a further particularly preferred embodiment of the present invention, the copolymer is a phosphorescent material. This can be achieved by integrating at least one phosphorescent emitter unit in the copolymer. Besides at least one structural unit of the formula (1), preferably where k=1, the copolymer according to the invention preferably also contains units from group 4. Preference is given to a copolymer according to the invention which contains in total at least 50 mol % of the structural units of the formula (1), based on all units of the copolymer. The proportion of group 4 units is very preferably 0.5 to 10 mol %, very particularly preferably 1 to 8 mol % and especially preferably 1 to 5 mol %.

In a further preferred embodiment of the present invention, the copolymer according to the invention is an electron-transporting or hole-blocking copolymer (ETM copolymer).

This ETM copolymer preferably contains at least one of the structural unit of the formulae (4), (5), (6), (7), (8) or (9), particularly preferably (4), (5), (6), (8) or (9), where at least one of the groups Ar⁴ or Ar⁵ is an electron-transporting unit, preferably selected from the group consisting of pyridine, pyrimidine, pyridazine, pyrazine, oxadiazole, benzimidazole, triazine, ketone, phosphine oxide and phenazine derivatives, but also triarylboranes and further O-, S- or N-containing heterocycles having a low LUMO. Particularly preferably, at least one Ar⁴ or Ar⁵ is selected from:

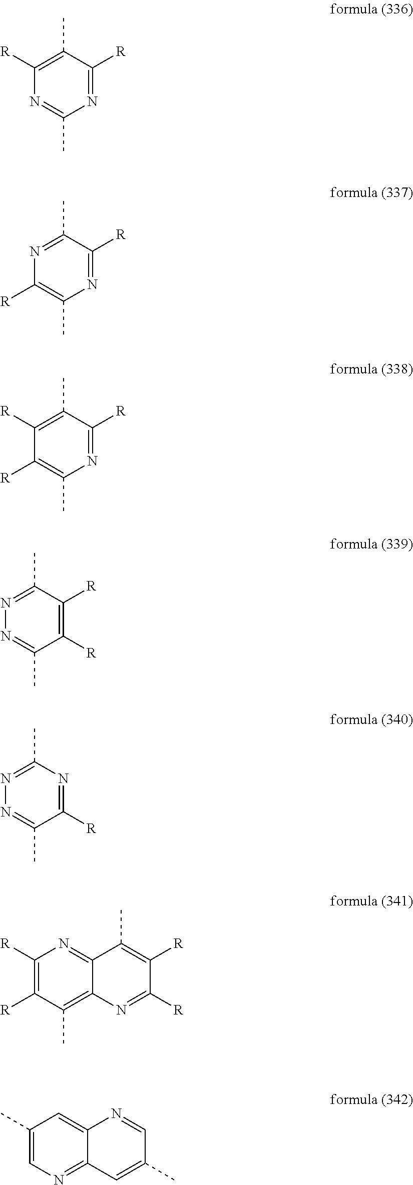

It is furthermore preferred for the ETM copolymer, besides at least one structural unit of the formula (1), preferably where k=1, also to contain (EIM/ETM) units from group 2. It is particularly preferred for this copolymer to contain in total at least 40 mol % of the structural units of the formula (1), based on all units of the copolymer. The proportion of group 2 units is very preferably 0.5 to 30 mol %, very particularly preferably 1 to 30 mol % and especially preferably 10 to 20 mol %.

The way in which the above-mentioned copolymers having block-like structures can be obtained and which further structural elements are particularly preferred for this purpose is described in detail, for example, in WO 2005/014688 A2. The latter is incorporated into the present application by way of reference. It should likewise again be emphasised at this point that the copolymer may also have dendritic structures.

The copolymers according to the invention containing structural units of the formula (1) are accessible readily and in high yields.

If triplet emitter units are employed in the copolymers according to the invention, they have advantageous properties, in particular long lifetimes, high efficiencies and good colour coordinates.

The copolymers according to the invention are generally prepared by polymerisation of more than one type of monomer, of which at least one monomer results in structural units of the formula (1) in the polymer. Suitable polymerisation reactions are known to the person skilled in the art and are described in the literature. Particularly suitable and preferred polymerisation reactions which result in C—C or C—N links are the following:

(A) SUZUKI polymerisation;
(B) YAMAMOTO polymerisation;
(C) STILLE polymerisation;
(D) HECK polymerisation;
(E) NEGISHI polymerisation;
(F) SONOGASHIRA polymerisation;
(G) HIYAMA polymerisation; and
(H) HARTWIG-BUCHWALD polymerisation.

The way in which the polymerisation can be carried out by these methods and the way in which the copolymers can then be separated off from the reaction medium and purified is known to the person skilled in the art and is described in detail in the literature, for example in WO 03/048225 A2, WO 2004/037887 A2 and WO 2004/037887 A2.

In order to be able to polymerise the structural units of the formula (1) and the further structural units, the structural units preferably contain leaving groups which are accessible to a coupling reaction, preferably a metal-catalysed cross-coupling reaction. The compounds functionalised with the leaving groups represent the basis for polymerisation. Thus, bromine derivatives can be reacted with arylboronic acids or arylboronic acid derivatives by Suzuki coupling or with organotin compounds by a Stille reaction to give the corresponding cooligomers, copolymers or dendrimers.

These processes are known from the prior art. Thus, the Suzuki coupling is, for example, a cross-coupling reaction, where arylboronic acids are preferably reacted with haloaromatic compounds with catalytic use of, preferably, palladium-phosphine complexes. The reactivity of the aromatic compounds increases from bromine via trifluoromethanesulfonic acid esters to iodine, where in the meantime even weakly reactive chloro-aromatic compounds can be reacted with palladium-phosphine catalysts. The Stille cross-coupling reaction proceeds analogously, using organotin compounds instead of organoboron compounds, although the former are not very preferred owing to their high toxicity.

For the purposes of the invention, particular preference is given to structural units of the formula (1), preferably where k=1, which are substituted by reactive leaving groups, preferably Cl, Br, I, O-tosylate, O-triflate, O-mesylate, O-nonaflate, NH, SiMe₃₋ₙFₙ (n=1 or 2), O—SO₂R¹, B(OR¹)₂, —CR¹═C(R¹)₂, —C≡CH and Sn(R¹)₃, where R¹ has the same meaning as described above and where two or more radicals R¹, together with the atoms to which they are bonded, may also form a ring system. The reactive leaving group is particularly preferably selected from Br, I and B(OR¹)₂. The polymerisation here preferably takes place via the halogen functionality or the boronic acid functionality.

The C—C linking reactions are preferably selected from the group of the SUZUKI coupling, the YAMAMOTO coupling and the STILLE coupling; the C—N linking reaction is preferably a HARTWIG-BUCHWALD coupling.

The present invention thus also relates to a process for the preparation of the polymers according to the invention, which is characterised in that they are prepared by SUZUKI polymerisation, YAMAMOTO polymerisation, STILLE polymerisation or HARTWIG-BUCHWALD polymerisation.

The dendrimers according to the invention can be prepared by processes known to the person skilled in the art or analogously thereto. Suitable processes are described in the literature, for example in Frechet, Jean M. J.; Hawker, Craig J., “Hyperbranched polyphenylene and hyperbranched polyesters: new soluble, three-dimensional, reactive polymers”, Reactive & Functional Polymers (1995), 26(1-3), 127-36; Janssen, H. M.; Meijer, E. W., “The synthesis and characterization of dendritic molecules”, Materials Science and Technology (1999), 20 (Synthesis of Polymers), 403-458; Tomalia, Donald A., “Dendrimer molecules”, Scientific American (1995), 272(5), 62-6, WO 02/067343 A1 and WO 2005/026144 A1.

For the synthesis of the copolymers according to the invention, the corresponding monomers are required. Monomers which result in structural units of the formula (1) in the polymers according to the invention are compounds which are correspondingly substituted and have, in two positions, suitable functionalities which allow this monomer unit to be incorporated into the polymer. The present invention therefore likewise relates to these monomers.

The present invention therefore also relates to compounds of the general formula (343)

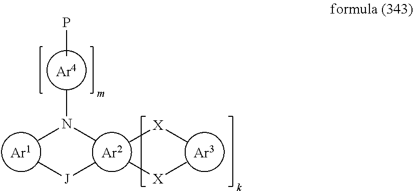

where Ar¹ to Ar⁵, J, J¹, R¹ and R² have the meaning indicated in Claim 1 and the following applies to the other symbols and indices:
P is in each case, independently of one another, a reactive leaving group;
k is either 0 or 1, preferably 1, where, for k=0, a further reactive leaving group P is bonded to Ar²;
m is either 0 or 1;
X is selected, independently of one another, from

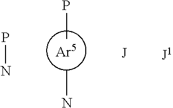

with the proviso that at least one X is not equal to J, where, in the case where k=1 and X is equal to J and J¹, a further reactive leaving group P is bonded to Ar³.

Very preferred monomers are the compounds of the general formulae (345) to (352), particularly preferably (345), (346), (347), (348), (349), (351) or (352

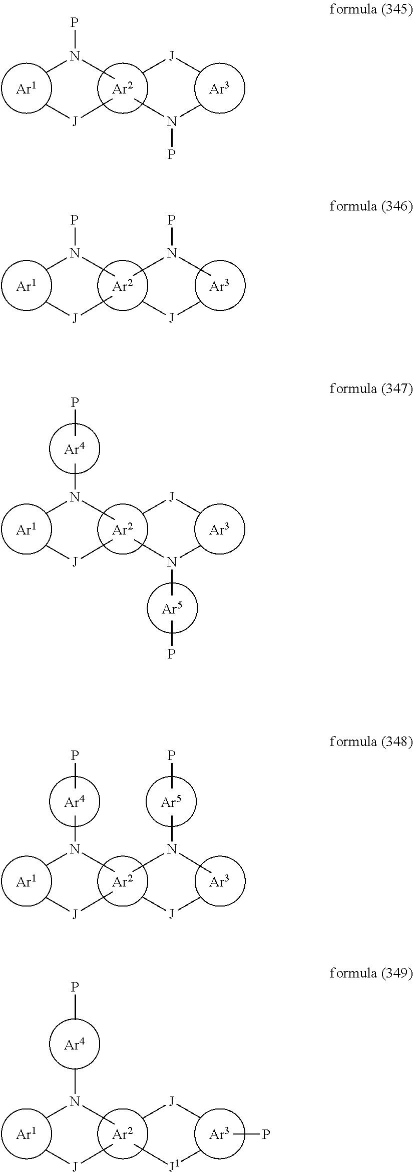

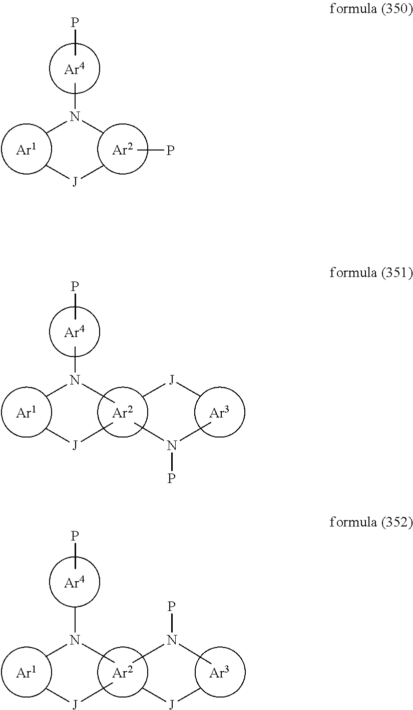

where the following applies to the symbols and indices:

P is preferably selected from Cl, Br, I, O-tosylate, O-triflate, O-mesylate, O-nonaflate, NH, SiMe₃₋ₙFₙ (n=1 or 2), O—SO₂R¹, B(OR¹)₂, —CR¹═C(R¹)₂, —C≡CH and Sn(R¹)₃, where R¹ has the same meaning as described above and where two or more radicals R¹, together with the atoms to which they are bonded, may also form a ring system. P is particularly preferably selected from Br, I and B(OR¹)₂.

In a preferred embodiment of the present invention, Ar¹ to Ar⁵ in the structural units of the formulae (343) to (352) are selected, identically or differently on each occurrence, from an unsubstituted or R¹-substituted aromatic ring system, where structural units where k=1 are preferred.

In a very preferred embodiment of the present invention, Ar¹ to Ar⁵ in the structural units of the formulae (343) to (352) are selected, identically or differently on each occurrence, from a monocyclic unsubstituted or R¹-substituted monocyclic aromatic or heteroaromatic rings, preferably monocyclic aromatic rings, where structural units where k=1 are preferred.

In a very particularly preferred embodiment of the present invention, Ar¹ to Ar⁵ in the structural units of the formulae (343) to (352) are selected, identically or differently on each occurrence, from a monocyclic unsubstituted aromatic or heteroaromatic ring, preferably from a monocyclic unsubstituted aromatic ring, very preferably Ar¹ to Ar⁵ are a monocyclic unsubstituted aromatic 6-membered ring, where structural units where k=1 are preferred.

According to an embodiment of the monomers according to the invention, the compounds of the formula (343) correspond to the following compounds of the formulae (353) to (371).

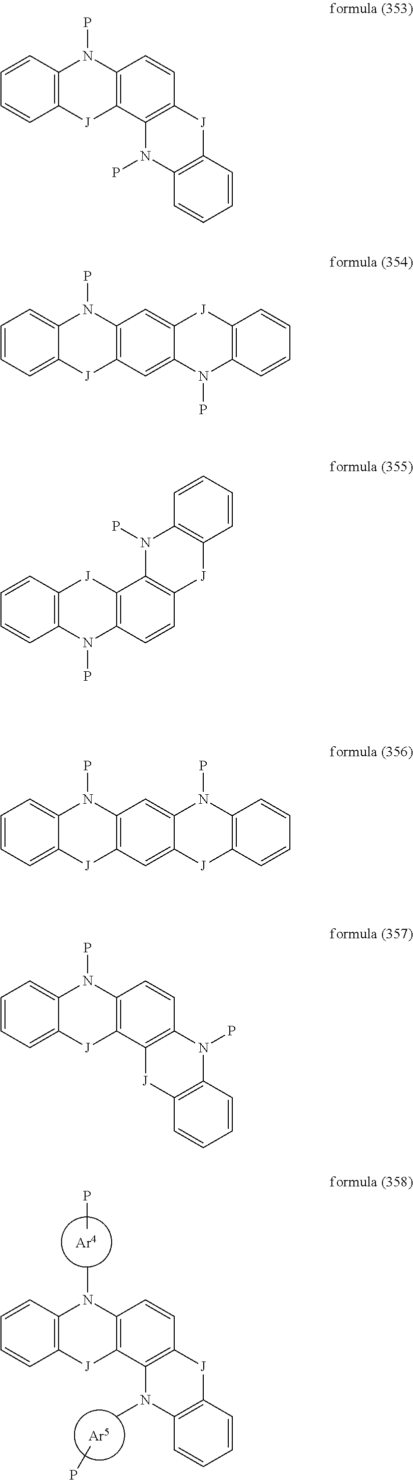

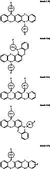

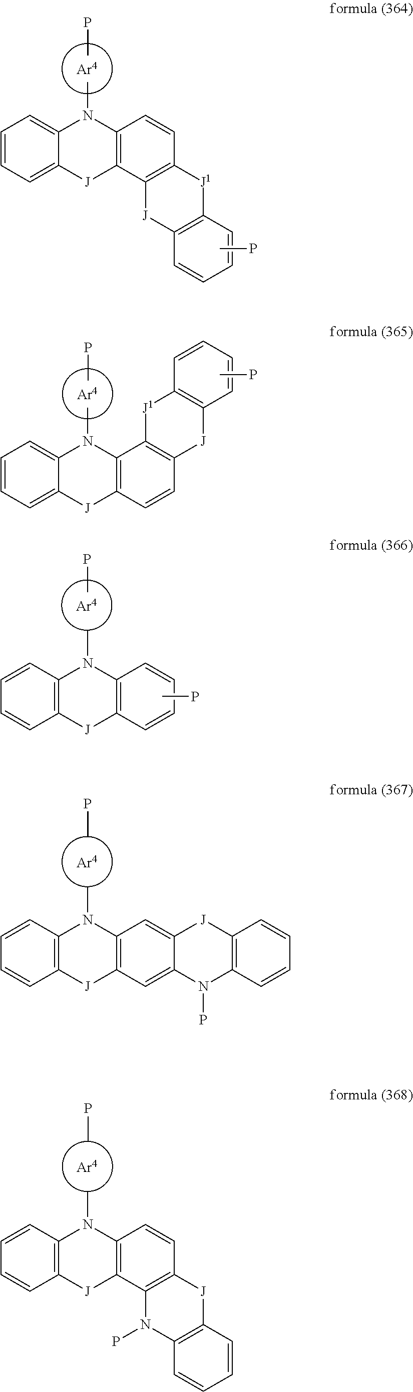

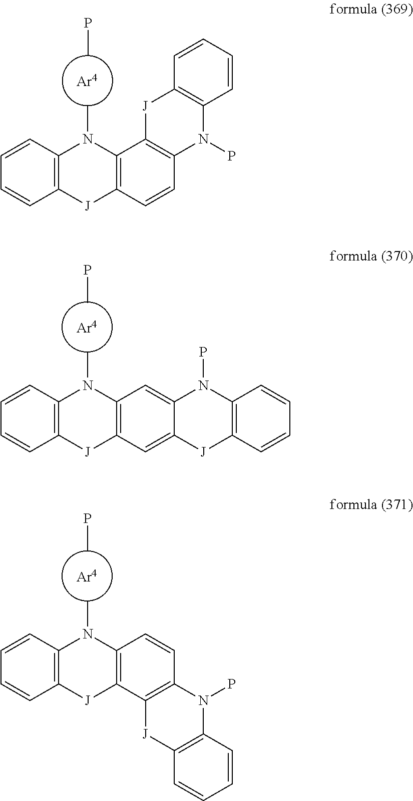

where the symbols and indices have the meaning indicated above.

Preference is given here to the compounds of the formulae (353) to (365) and (367) to (371).

For the purposes of the present invention, preference is furthermore given to compounds of the formulae (29) to (48), preferably (29) to (42) and (44) to (48), where the dotted bonds in the formulae of compounds (29) to (48) is to be replaced by the group —P defined above.

For the purposes of the present invention, very preference is given to compounds of the formulae (49) to (113), preferably (49) to (80) and (87) to (113), where the dotted bonds in the formulae of compounds (49) to (113) is to be replaced by the group —P defined above.

Examples of polymerisable compounds according to the invention are the compounds depicted below.

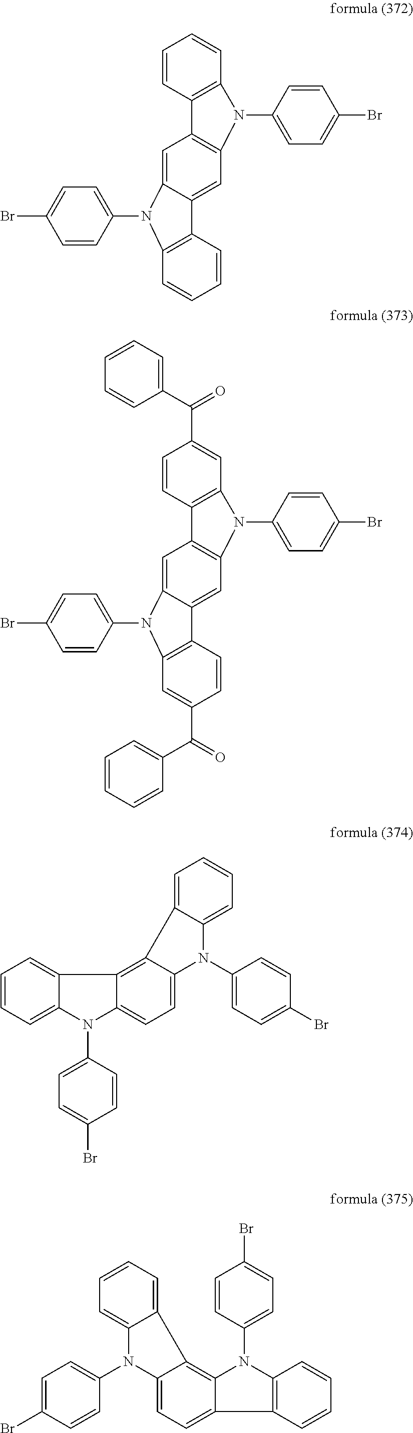 [SMILES: Brc1ccc(-n2c3ccccc3c3cc4c(cc32)c2ccccc2n4-c2ccc(Br)cc2)cc1 ; O=C(c1ccccc1)c1ccc2c3cc4c(cc3n(-c3ccc(Br)cc3)c2c1)c1ccc(C(=O)c2ccccc2)cc1n4-c1ccc(Br)cc1 ; Brc1ccc(-n2c3ccccc3c3c4c5ccccc5n(-c5ccc(Br)cc5)c4ccc32)cc1 ; Brc1ccc(-n2c3ccccc3c3c2ccc2c4ccccc4n(-c4ccc(Br)cc4)c23)cc1]

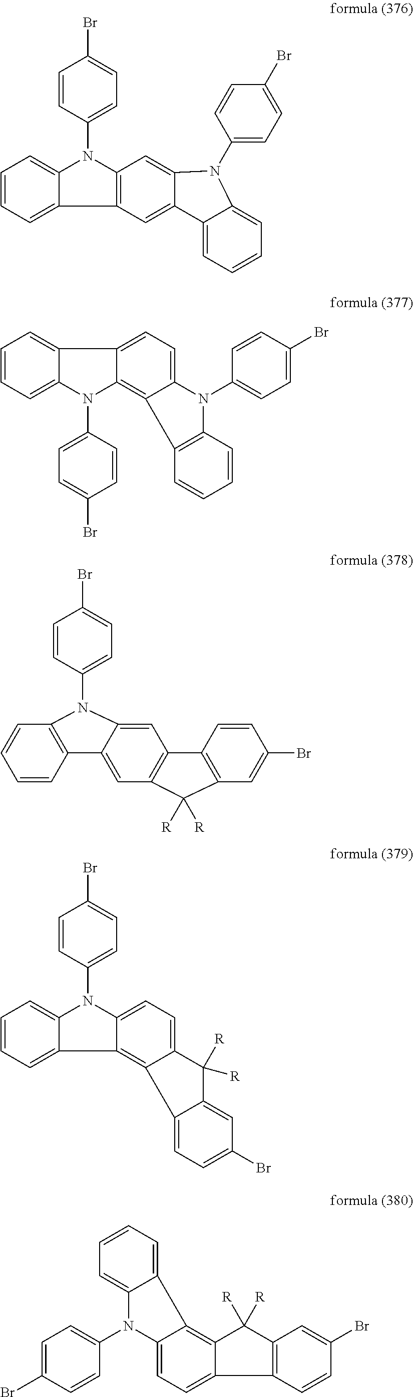

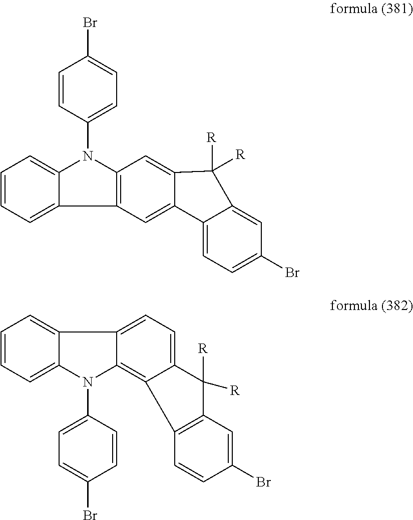

In addition, preferred compounds are those which contain leaving groups of different reactivity. This enables the build-up of the polymer chain to be controlled better. Examples thereof are the compounds depicted below.

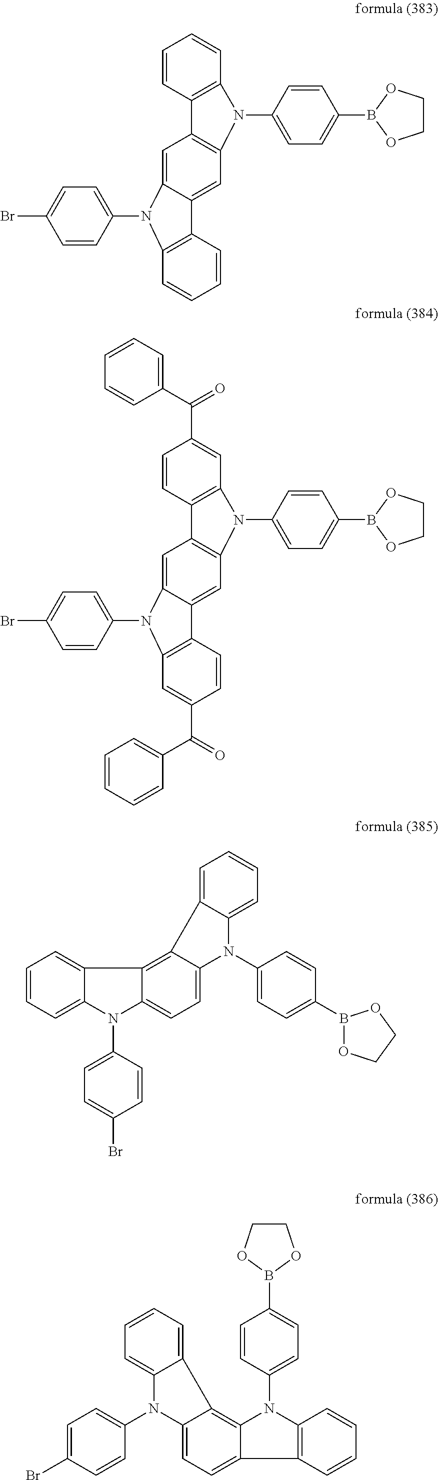 [SMILES: Brc1ccc(-n2c3ccccc3c3cc4c(cc32)c2ccccc2n4-c2ccc(B3OCCO3)cc2)cc1 ; O=C(c1ccccc1)c1ccc2c3cc4c(cc3n(-c3ccc(Br)cc3)c2c1)c1ccc(C(=O)c2ccccc2)cc1n4-c1ccc(B2OCCO2)cc1 ; Brc1ccc(-n2c3ccccc3c3c4c5ccccc5n(-c5ccc(B6OCCO6)cc5)c4ccc32)cc1 ; Brc1ccc(-n2c3ccccc3c3c2ccc2c4ccccc4n(-c4ccc(B5OCCO5)cc4)c23)cc1]

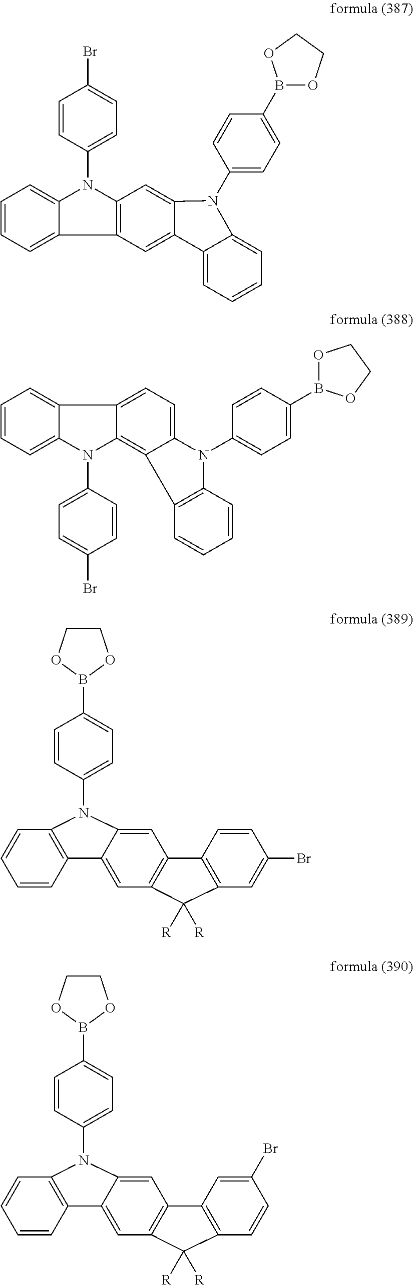

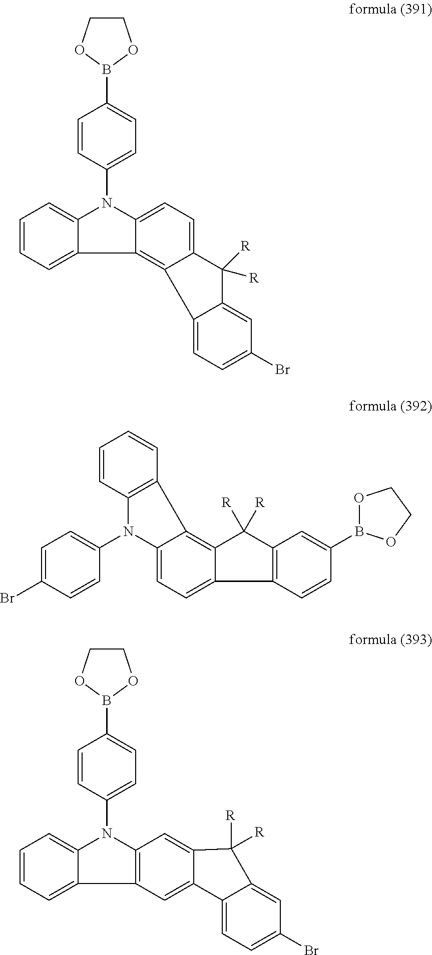

It may additionally be preferred to use the polymers according to the invention not as the pure substance, but instead as a mixture together with further polymeric, oligomeric, dendritic or low-molecular-weight substances of any desired type. These may, for example, improve the electronic properties or themselves emit. Above and below, a mixture is taken to mean a composition which comprises at least one polymeric component.

The present invention thus furthermore relates to a polymer mixture which comprises one or more copolymers according to the invention, and one or more further polymeric, oligomeric, dendritic or low-molecular-weight substances.

In a further embodiment of the present invention, it is preferred for a mixture to comprise a copolymer according to the invention and a low-molecular-weight substance. The low-molecular-weight substance is preferably a triplet emitter.

In a further embodiment, it is preferred for the copolymer which contains structural units of the formula (1), preferably where k=1, to be employed in an emitting layer together with an emitting compound. In this case, the polymer is preferably employed in combination with one or more phosphorescent materials (triplet emitters). For the purposes of the present invention, phosphorescence is taken to mean the luminescence from an excited state having relatively high spin multiplicity, i.e. a spin state greater than 1, in particular from an excited triplet state or from an MLCT mixed state. The mixture comprising the copolymer according to the invention or the preferred embodiment mentioned above and the emitting compound then comprises between 99 and 1% by weight, preferably between 98 and 60% by weight, particularly preferably between 97 and 70% by weight, in particular between 95 and 75% by weight, of the copolymer according to the invention or of the preferred embodiment mentioned above, based on the entire mixture comprising emitter and matrix material. Correspondingly, the mixture comprises up to 99% by weight, preferably up to 40% by weight, particularly preferably up to 30% by weight and in particular up to 25% by weight, of the emitter, based on the entire mixture comprising emitter and matrix material. In addition, the mixture comprises at least 1% by weight, preferably 2% by weight, particularly preferably at least 3% by weight and in particular at least 5% by weight, of the emitter, based on the entire mixture comprising emitter and matrix material.

In the above-mentioned embodiment in which the copolymer which contains structural units of the formula (1) is employed in an emitting layer together with an emitting compound, the proportion of the emitting compound may, however, also be significantly lower. In this case, the mixture preferably comprises at least 0.01% by weight of the emitter, based on the entire mixture, but preferably less than 5% by weight, particularly preferably less than 3% by weight and in particular less than 1.5% by weight, of the emitter, based on the entire mixture.

Suitable phosphorescent compounds are, in particular, compounds which emit light, preferably in the visible region, on suitable excitation and in addition contain at least one atom having an atomic number of greater than 36 and less than 84, particularly preferably greater than 56 and less than 80.

Examples of the emitters described above are revealed by the applications WO 00/70655, WO 01/41512, WO 02/02714, WO 02/15645, EP 1191613, EP 1191612, EP 1191614, WO 2005/033244 and DE 102008015526. In general, all phosphorescent complexes as are used in accordance with the prior art for phosphorescent OLEDs and as are known to the person skilled in the art in the area of organic electroluminescence are suitable, and the person skilled in the art will be able to use further phosphorescent complexes without an inventive step.

For the purposes of the present invention, the emitter compound in the composition according to the invention is preferably a green-emitting phosphorescence emitter. The phosphorescence emitter may likewise be a blue or red phosphorescence emitter.

In a further embodiment according to the invention, the phosphorescence emitter preferably contains an organometallic compound unit. The organometallic compound unit is preferably an organometallic coordination compound. In the present invention, an organometallic coordination compound is taken to mean a compound containing a metal atom or ion in the centre of the compound surrounded by an organic compound as ligand. An organometallic coordination compound is in addition characterised in that at least one carbon atom of the ligand is bonded to the central metal via a coordination bond. Electrically neutral phosphorescence emitters are furthermore preferred.

The phosphorescence emitters preferably contain only chelating ligands, i.e. ligands which coordinate to the metal via at least two bonding sites; the use of two or three bidentate ligands, which may be identical or different, is particularly preferred. The preference for chelating ligands is due to the higher stability of chelate complexes.

In a further embodiment of the invention, it is preferred for the copolymer according to the invention which contains structural units of the formula (1), preferably where k=1, to be employed in an interlayer. The copolymer here preferably has an exciton- and/or electron-blocking function.

In a further embodiment according to the invention, it is preferred for a mixture to comprise a copolymer according to the invention, a triplet emitter, which is either present in the copolymer according to the invention or, as in the above-mentioned embodiments, has been admixed as low-molecular-weight substance, and further low-molecular-weight substances. These low-molecular-weight substances may have the same functionalities as mentioned for possible monomer units in groups 1 to 8.

The present invention furthermore relates to a formulation, in particular a solution, dispersion or emulsion, comprising at least one copolymer according to the invention and at least one solvent. Solvents which can be employed are all conceivable ones which are capable of dissolving the copolymers according to the invention or of forming a suspension with them. The following organic solvents are preferred here in accordance with the invention—without having a restrictive effect on the invention: dichloromethane, trichloromethane, monochlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 1,1,1-trichloroethane, 1,1,2,2-tetrachloroethane, ethyl acetate, n-butyl acetate, dimethylformamide, dimethylacetamide, dimethyl sulfoxide, tetralin, decalin, indane and/or mixtures thereof.

The concentration of the copolymer according to the invention in the solution is preferably 0.1 to 10% by weight, more preferably 0.5 to 5% by weight, based on the total weight of the solution. The solution optionally also comprises one or more binders in order to adjust the rheological properties of the solution correspondingly, as described, for example, in WO 2005/055248 A1.

After appropriate mixing and ageing of the solutions, these are divided into one of the following categories: “full” solution, “borderline” solution or insoluble. The border line is drawn between these categories with reference to the solubility parameters. The corresponding values can be obtained from the literature, such as, for example, from “Crowley, J. D., Teague, G. S. Jr. and Lowe, J. W. Jr., Journal of Paint Technology, 38, No. 496, 296 (1966)”.

Solvent mixtures can also be used and are identified as described in “Solvents, W.H. Ellis, Federation of Societies for Coatings Technology, pp. 9 to 10, 1986”. Processes of this type can result in a mixture of so-called “non”-solvents which dissolve the composition, although it is desirable to have at least one true solvent in the mixture.

A further preferred form of the formulation is an emulsion, and more preferably a miniemulsion, which are prepared, in particular, as heterophase systems, in which stable nanodroplets of a first phase are dispersed in a second continuous phase. The present invention relates, in particular, to a miniemulsion in which the various components of the copolymer according to the invention are arranged either in the continuous phase or nanodroplets.

Both a miniemulsion, in which the continuous phase is a polar phase, and also an inverse miniemulsion, in which the continuous phase is a nonpolar phase, can be used in the present invention. The preferred form is a miniemulsion. In order to increase the kinetic stability of the emulsion, surfactants can also be admixed. The choice of the solvents for two-phase systems, the surfactants and the processing to give a stable miniemulsion should be known to a person skilled in the art in this area on the basis of his expert knowledge or through numerous publications, such as, for example, a comprehensive article by Landfester in Annu. Rev, Mater. Res. (06), 36, p. 231.

For use of so-called thin layers in electronic or opto-electronic devices, the copolymer according to the invention or a formulation thereof can be deposited by a correspondingly suitable process. Liquid coating of devices, such as, for example, of OLEDs, is more desirable than vacuum deposition techniques. Deposition methods from solution are particularly preferred. Preferred deposition techniques include, without correspondingly restricting the invention, dip coating, spin coating, ink-jet printing, letterpress printing, screen printing, doctor blade coating, roller printing, reverse roller printing, offset lithography, flexographic printing, web printing, spray coating, brush coating or pad printing and slot-die coating. Ink-jet printing is particularly preferred and enables the production of high-resolution displays.

The solutions according to the invention can be applied to prefabricated device substrates with the aid of ink-jet printing or by microdispensing. To this end, preference is given to the use of industrial piezoelectric print heads, such as from Aprion, Hitachie-Koki, Inkjet Technology, On Target Technology, Picojet, Spectra, Trident, Xaar, in order to apply the organic semiconductor layers to a substrate. In addition, semi-industrial print heads, such as those from Brother, Epson, Konika, Seiko Instruments, Toshiba TEC or single-nozzle microdispensing equipment, as manufactured, for example, by Mikrodrop and Mikrofab, can also be used.

In order that the copolymer according to the invention can be applied by ink-jet printing or microdispensing, it should first be dissolved in a suitable solvent. The solvents must meet the above-mentioned requirements and must not have any disadvantageous effects on the print head selected. In addition, the solvents should have a boiling point of above 100° C., preferably above 140° C. and more preferably above 150° C., in order to avoid processing problems caused by drying-out of the solution inside the print head. Besides the above-mentioned solvents, the following solvents are also suitable: substituted and unsubstituted xylene derivatives, di-C₁₋₂-alkylformamides, substituted and unsubstituted anisoles and other phenol ether derivatives, substituted heterocycles, such as substituted pyridines, pyrapsines, pyrimidines, pyrrolidinones, substituted and unsubstituted N, N-di-C₁₋₂-alkylanilines and other fluorinated or chlorinated aromatic compounds.

A preferred solvent for the deposition of the copolymers according to the invention by ink-jet printing comprises a benzene derivative which contains a benzene ring which is substituted by one or more substituents, in which the total number of carbon atoms of the one or more substituents is at least three. Thus, for example, the benzene derivative may be substituted by a propyl group or three methyl groups, where in each case the total number of carbon atoms must be at least three. A solvent of this type enables the formation of an ink-jet liquid which comprises the solvent with the compound according to the invention and reduces or prevents clogging of the nozzles and separation of the components during spraying. The solvent(s) can be selected from the following example list: dodecylbenzene, 1-methyl-4-tert-butylbenzene, terpineollimonene, isodurol, terpinolene, cymene and dethylbenzene. The solvent may also be a solvent mixture comprising two or more solvents, where each of the solvents preferably has a boiling point of greater than 100° C., more preferably greater than 140° C. Solvents of this type promote film formation of the deposited layer and reduce layer errors.

The ink-jet liquid, (i.e. a mixture, preferably comprising solvent(s), binder and the compound according to the invention) preferably has a viscosity at 20° C. of 1 to 100 mPa·s, more preferably 1 to 50 mPa·s and most preferably 1 to 30 mPa·s.

The compound or formulation according to the invention may additionally comprise one or more further components, such as, for example, surface-active substances, lubricants, wetting agents, dispersants, water-repellent agents, adhesives, flow improvers, antifoaming agents, air deposition agents, diluents, which may be reactive or unreactive substances, assistants, colorants, dyes or pigments, sensitisers, stabilisers or inhibitors.

Copolymers which contain structural units of the formula (1), preferably where k=1, which contain one or more polymerisable and thus crosslinkable groups are particularly suitable for the production of films or coatings, in particular for the production of structured coatings, for example by thermal or light-induced in-situ polymerisation and in-situ crosslinking, such as, for example, in-situ UV photopolymerisation or photopatterning. For applications of this type, particular preference is given to copolymers according to the invention containing one or more polymerisable groups, selected from acrylate, methacrylate, vinyl, epoxy and oxetane. It is possible here not only to use corresponding copolymers as the pure substance, but also to use formulations or blends of these copolymers as described above. These can be used with or without addition of solvents and/or binders. Suitable materials, processes and devices for the methods described above are described, for example, in WO 2005/083812 A2. Possible binders are, for example, polystyrene, polycarbonate, polyacrylates, polyvinylbutyral and similar, opto-electronically neutral polymers.

Suitable and preferred solvents are, for example, toluene, anisoles, xylenes, methyl benzoate, dimethylanisole, mesitylene, tetralin, veratrol and tetrahydrofuran or mixtures thereof.

The copolymers, mixtures and formulations according to the invention can be used in electronic or electro-optical devices or for the production thereof.

The present invention thus furthermore relates to the use of the copolymers, mixtures and formulations according to the invention in electronic devices, preferably electroluminescent devices (organic light-emitting diodes (OLEDs), polymer light-emitting diodes (PLEDs), organic light-emitting transistors (O-LETs), organically light-emitting electrochemical cells (OLECs) and organically light-emitting electrochemical transistors (OLEETs)), organic integrated circuits (O-ICs), organic field-effect transistors (O-FETs), organic thin-film transistors (O-TFTs), organic solar cells (O-SCs), organic dye-sensitised solar cells (ODSSCs), organic optical detectors, organic photoreceptors, organic field-quench devices (O-FQDs), organic laser diodes (O-lasers) and organic plasmon emitting devices” (D. M. Koller et al., Nature Photonics 2008, 1-4) organic solar concentrators.

As described above, the copolymers according to the invention are very particularly suitable as electroluminescent materials in organic electroluminescent devices, particularly preferably in OLEDs, PLEDs, OLECs, or displays.

The organic electroluminescent device preferably has a planar shape and/or is in the form of a fibre.

A fibre in the sense of the present invention is taken to mean any shape in which the ratio between length to diameter is greater than or equal to 10:1, preferably 100:1, where the shape of the cross section along the longitudinal axis is not important. The cross section along the longitudinal axis may accordingly be, for example, round, oval, triangular, rectangular or polygonal. Light-emitting fibres have preferred properties with respect to their use. Thus, they are suitable, inter alia, for use in the area of therapeutic and/or cosmetic phototherapy. Further details in this respect are described in the prior art (for example in U.S. Pat. No. 6,538,375, US 2003/0099858, Brenndan O'Connor et al. (Adv. Mater. 2007, 19, 3897-3900 and the unpublished patent application EP 10002558.4).

For the purposes of the present invention, electroluminescent materials are taken to mean materials which can be used as active layer. Active layer means that the layer is capable of emitting light on application of an electric field (light-emitting layer) and/or that it improves the injection and/or transport of positive and/or negative charges (charge-injection or charge-transport layer), or that it has an electron- and/or exciton-blocking function (interlayer).

The present invention therefore also preferably relates to the use of the copolymers or mixtures according to the invention in an OLED, or PLED or OLEC, in particular as electroluminescent material, particularly preferably as triplet/phosphorescence matrix material, or phosphorescent material or interlayer.

The present invention furthermore relates to electronic devices, preferably organic electroluminescent devices (organic light-emitting diodes (OLEDs), organic light-emitting transistors (O-LETs), polymer light-emitting diodes (PLEDs), organically light-emitting electrochemical cells (OLECs) and organically light-emitting electrochemical transistors (OLEET)), organic integrated circuits (O-ICs), organic field-effect transistors (O-FETs), organic thin-film transistors (O-TFTs), organic solar cells (O-SCs), organic dye-sensitised solar cells (ODSSCs), organic optical detectors, organic photoreceptors, organic field-quench devices (O-FQDs), organic laser diodes (O-lasers), organic plasmon emitting devices” (D. M. Koller et al., Nature Photonics 2008, 1-4) or organic solar concentrators. Particular preference is given to organic electroluminescent devices.

The structure of the above-mentioned electronic device is known to a person skilled in the art in the area of electronic devices. Nevertheless, some references which disclose a detailed device structure are indicated below.

An organic plasma-emitting device is preferably a device as described by Koller et al., in Nature Photonics (08), 2, pages 684 to 687. The so-called OPED is very similar to the OLED described above, apart from the fact that at least the anode or cathode should be capable of anchoring the surface plasma on the emitting layer. It is furthermore preferred for the OPED to comprise a copolymer according to the invention.

An organic light-emitting transistor (OLET) has a very similar structure to an organic field-effect transistor, but with a bipolar material as active layer between the source and the drain. A more recent development is revealed by a publication by Muccini et al., in Nature Materials 9, 496 to 503 (2010). Here too, it is preferred for the OLET to comprise at least one copolymer according to the invention.

Organic light-emitting electrochemical transistors (OLEET) have a structure which is very similar to that of organic field-effect transistors, but with a mixture of electrode and emitting species between the source and the drain. A more recent development is revealed by the publication by Sariciftci in Appl. Phys. Lett. 97, 033302 (2010). Here too, it is preferred for the OLEET to comprise at least one copolymer according to the invention.

Electrophotographic elements comprise a substrate, an electrode and a charge-transport layer above the electrode, and optionally a charge-generation layer between the electrode and the charge-transport layer. Regarding diverse details and variations of such devices and materials which can be used herein, reference is made to the book “Organic Photoreceptors for Xerography” by Marcel Dekker, Inc., Ed. by Paul M. Borsenberger & D. S. Weiss (1998). It is preferred for a device of this type to comprise at least one copolymer according to the invention, particularly preferably within a charge-transport layer.

A particularly preferred organic spintronic device is a spin-valve device, as reported by Z. H. Xiong et al., in Nature 2004 Vol. 727, page 821, which comprises two ferromagnetic electrodes and an organic layer between the two ferromagnetic electrodes, in which at least one of the organic layers, which comprises a copolymer according to the invention and the ferromagnetic electrode, is composed of cobalt, nickel, iron or an alloy thereof, or an ReMnO₃ or CrO₂, in which Re is a rare-earth element.

Organic light-emitting electrochemical cells (OLECs) comprise two electrodes and a mixture of electrode and fluorescent species in between, as first reported by Pei & Heeger in Science (95), 269, pages 1086 to 1088. It is desired that a copolymer according to the invention is used in a device of this type.

Dye-sensitised solar cells (DSSCs) comprise, in the following sequence, an electrode/a dye-sensitised TiO₂ porous thin film/an electrolyte/a counterelectrode, as first reported by O'Regan & Grätzel in Nature (91), 353, pages 737 to 740. The liquid electrode may be replaced by a solid hole-transport layer, as reported in Nature (98), 395, pages 583 to 585.

Organic solar concentrators (OSC) can be used as in the report by Baldo et al., in Science 321, 226 (2008). An OSC consists of a thin film of organic dyes deposited on a glass substrate having a high refractive index. The dye absorbs incident solar energy and re-emits it at low energy. The majority of the re-emitted photons are fully collected by a waveguide by total internal reflection. This takes place by means of a photovoltaic device, which is arranged at the edge of the substrate.

Particular preference is given in this invention to organic or polymeric organic electroluminescent devices, in particular polymeric organic electroluminescent devices, having one or more active layers, where at least one of these active layers comprises one or more copolymers according to the invention. The active layer can be, for example, an emission layer, an interlayer, a charge-transport layer and/or a charge-injection layer, preferably an emission layer or interlayer.

The way in which OLEDs or PLEDs can be produced is known to the person skilled in the art and is described in detail, for example, as a general process in WO 2004/070772 A2, which should be adapted correspondingly for the individual case.

In a further embodiment of the invention, the device comprises a plurality of layers. These can be layers which comprise the copolymer according to the invention or layers which comprise polymers, blends or low-molecular-weight compounds which are independent thereof. The copolymer or polymer according to the invention can be present here in the form of an interlayer, hole-transport, hole-injection, emitter, electron-transport, electron-injection, charge-blocking and/or charge-generation layer, preferably as emitter layer/emission layer or interlayer.

The organic electroluminescent device may preferably comprise one emitting layer, or it may comprise a plurality of emitting layers, where at least one emitting layer comprises at least one copolymer according to the invention, as defined above. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to three-layer systems, where the three layers exhibit blue, green and orange or red emission (for the basic structure see, for example, WO 2005/011013). White-emitting devices are suitable, for example, as lighting or backlighting of displays (LCD).

Apart from these layers, it may also comprise further layers, for example in each case one or more hole-injection layers, hole-transport layers, hole-blocking layers, electron-transport layers, electron-injection layers, exciton-blocking layers and/or charge-generation layers (IDMC 2003, Taiwan; Session 21 OLED (5), T. Matsumoto, T. Nakada, J. Endo, K. Mori, N. Kawamura, A. Yokoi, J. Kido, Multiphoton Organic EL Device Having Charge Generation Layer). It is likewise possible for interlayers, which have, for example, an exciton-blocking function, to be introduced between two emitting layers. However, it should be pointed out that each of these layers does not necessarily have to be present. These layers may likewise comprise the copolymers according to the invention, as defined above. It is also possible for a plurality of OLEDs to be arranged one above the other, which enables a further increase in efficiency with respect to the light yield to be achieved. In order to improve the coupling-out of light, the final organic layer on the light exit side in OLEDs can also be designed as a nanofoam, which reduces the proportion of total reflection.

The device may furthermore comprise layers which are built up from small molecules (SMOLED). These can be produced by evaporation of small molecules in a high vacuum.

Preference is thus furthermore given to an organic electroluminescent device in which one or more layers are coated by means of a sublimation process, in which the materials are vapour-deposited in vacuum sublimation units at a pressure of less than 10⁻⁵ mbar, preferably less than 10⁻⁶ mbar, particularly preferably less than 10⁻⁷ mbar.

Preference is likewise given to an organic electroluminescent device, characterised in that one or more layers are coated by means of the OVPD (organic vapour phase deposition) process or with the aid of carrier-gas sublimation, where the materials are applied at a pressure of between 10⁻⁵ mbar and 1 bar.

Preference is furthermore given to an organic electroluminescent device in which one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds, which are obtained, if necessary, by suitable substitution, are necessary for this purpose.

The device usually comprises a cathode and an anode (electrodes). For the purposes of this invention, the electrodes (cathode, anode) are selected in such a way that their potential matches as closely as possible the potential of the adjacent organic layer in order to ensure highly efficient electron or hole injection.

The cathode preferably comprises metal complexes, metals having a low work function, metal alloys or multilayered structures comprising various metals, such as, for example, alkaline-earth metals, alkali metals, main-group metals or lathanoids (for example Ca, Ba, Mg, Al, In, Mg, Yb, Sm, etc.). In the case of multilayered structures, further metals which have a relatively high work function, such as, for example, Ag, can also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides (for example LiF, Li₂O, BaF₂, MgO, NaF, etc.). The layer thickness of this layer is preferably between 1 and 10 nm, more preferably 2 to 8 nm.

The anode preferably comprises materials having a high work function. The anode preferably has a potential of greater than 4.5 eV vs. vacuum. Suitable for this purpose are on the one hand metals having a high redox potential, such as, for example, Ag, Pt or Au. On the other hand, metal/metal oxide electrons (for example Al/Ni/NiOₓ, AI/PtOₓ) may also be preferred. For some applications, at least one of the electrodes must be transparent in order to facilitate either irradiation of the organic material (O-SCs) or the coupling-out of light (OLEDs/PLEDs, O-LASERS). A preferred construction uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The device is correspondingly structured in a manner known per se, depending on the application, provided with contacts and finally hermetically sealed, since the lifetime of such devices is drastically shortened in the presence of water and/or air.

The compounds/copolymers according to the invention and the devices comprising same are furthermore suitable for use in the context of phototherapeutic measures.

The present invention therefore furthermore relates to the use of the compounds/copolymers according to the invention and devices comprising the compounds/copolymers for the treatment, prophylaxis and diagnosis of diseases. The present invention still furthermore relates to the use, of the compounds/copolymers according to the invention and devices comprising the compounds/copolymers for the treatment and prophylaxis of cosmetic conditions.

The present invention furthermore relates to the compounds/copolymers according to the invention for the production of devices for the therapy, prophylaxis and/or diagnosis of therapeutic diseases.

Many diseases are associated with cosmetic aspects. Thus, a patient with severe acne in the facial area suffers not only from the medical causes and consequences of the disease, but also from the cosmetic accompanying conditions.

Phototherapy or light therapy is used in many medical and/or cosmetic areas. The compounds according to the invention and the devices comprising these compounds can therefore be employed for the therapy and/or prophylaxis and/or diagnosis of all diseases and/or in cosmetic applications for which the person skilled in the art considers the use of phototherapy. Besides irradiation, the term phototherapy also includes photodynamic therapy (PDT) and disinfection and sterilisation in general. Phototherapy or light therapy can be used for the treatment of not only humans or animals, but also any other type of living or inorganic matter. These include, for example, fungi, bacteria, microbes, viruses, eukaryotes, prokaryotes, foods, drinks, water and drinking water.

The term phototherapy also includes any type of combination of light therapy and other types of therapy, such as, for example, treatment with active compounds. Many light therapies have the aim of irradiating or treating exterior parts of an object, such as the skin of humans and animals, wounds, mucous membranes, the eye, hair, nails, the nail bed, gums and the tongue. In addition, the treatment or irradiation according to the invention can also be carried out inside an object in order, for example, to treat internal organs (heart, lung, etc.) or blood vessels or the breast.

The therapeutic and/or cosmetic areas of application according to the invention are preferably selected from the group of skin diseases and skin-associated diseases or changes or conditions, such as, for example, psoriasis, skin ageing, skin wrinkling, skin rejuvenation, enlarged skin pores, cellulite, oily/greasy skin, folliculitis, actinic keratosis, precancerous actinic keratosis, skin lesions, sun-damaged and sun-stressed skin, crows' feet, skin ulcers, acne, acne rosacea, scars caused by acne, acne bacteria, photomodulation of greasy/oily sebaceous glands and their surrounding tissue, jaundice, jaundice of the newborn, vitiligo, skin cancer, skin tumours, Crigler-Najjar, dermatitis, atopic dermatitis, diabetic skin ulcers and desensitisation of the skin. Particular preference is given for the purposes of the invention to the treatment and/or prophylaxis of psoriasis, acne, cellulite, skin wrinkling, skin ageing, jaundice and vitiligo.

Further areas of application according to the invention for the compositions and/or devices comprising the compositions according to the invention are selected from the group of inflammatory diseases, rheumatoid arthritis, pain therapy, treatment of wounds, neurological diseases and conditions, oedemas, Paget's disease, primary and metastasising tumours, connective-tissue diseases or changes, changes in the collagen, fibroblasts and cell levels originating from fibroblasts in tissues of mammals, irradiation of the retina, neovascular and hypertrophic diseases, allergic reactions, irradiation of the respiratory tract, sweating, ocular neovascular diseases, viral infections, particularly infections caused by herpes simplex or HPV (human papillomaviruses) for the treatment of warts and genital warts.

Particular preference is given for the purposes of the invention to the treatment and/or prophylaxis of rheumatoid arthritis, viral infections, and pain.

Further areas of application according to the invention for the copolymers and/or devices comprising the copolymers according to the invention are selected from winter depression, sleeping sickness, irradiation for improving the mood, alleviation of pain, particularly muscular pain caused by, for example, tension or joint pain, elimination of joint stiffness and the whitening of the teeth (bleaching).

Further areas of application according to the invention for the copolymers and/or devices comprising the copolymers according to the invention are selected from the group of disinfections. The copolymers according to the invention and/or the devices according to the invention can be used for the treatment of any type of objects (inorganic matter) or subjects (living matter, such as, for example, humans and animals) for the purposes of disinfection. This includes, for example, the disinfection of wounds, the reduction in bacteria, the disinfection of surgical instruments or other articles, the disinfection of foods, of liquids, in particular water, drinking water and other drinks, the disinfection of mucous membranes and gums and teeth. Disinfection here is taken to mean the reduction in the living microbiological causative agents of undesired effects, such as bacteria and germs.

For the purposes of the above-mentioned phototherapy, devices comprising the copolymers according to the invention preferably emit light having a wavelength between 250 and 1250 nm, particularly preferably between 300 and 1000 nm and especially preferably between 400 and 850 nm.

In a particularly preferred embodiment of the present invention, the copolymers according to the invention are employed in an organic light-emitting diode (OLED) or an organic light-emitting electrochemical cell (OLEC) for the purposes of phototherapy. Both the OLED and the OLEC can have a planar or fibre-like structure having any desired cross section (for example round, oval, polygonal, square) with a single- or multilayered structure. These OLECs and/or OLEDs can be installed in other devices which comprise further mechanical, adhesive and/or electronic elements (for example battery and/or control unit for adjustment of the irradiation times, intensities and wavelengths). These devices comprising the OLECs and/or OLEDs according to the invention are preferably selected from the group comprising plasters, pads, tapes, bandages, cuffs, blankets, caps, sleeping bags, textiles and stents.

The use of the said devices for the said therapeutic and/or cosmetic purpose is particularly advantageous compared with the prior art, since homogeneous irradiation of lower irradiation intensity is possible at virtually any site and at any time of day with the aid of the devices according to the invention using the OLEDs and/or OLECs. The irradiation can be carried out as an inpatient, as an outpatient and/or by the patient themself, i.e. without initiation by medical or cosmetic specialists. Thus, for example, plasters can be worn under clothing, so that irradiation is also possible during working hours, in leisure time or during sleep. Complex inpatient/outpatient treatments can in many cases be avoided or their frequency reduced. The devices according to the invention may be intended for reuse or be disposable articles, which can be disposed of after use once, twice or three times.

Further advantages over the prior art are, for example, lower evolution of heat and emotional aspects. Thus, newborn being treated owing to jaundice typically have to be irradiated blindfolded in an incubator without physical contact with the parents, which represents an emotional stress situation for parents and newborn. With the aid of a blanket according to the invention comprising the OLEDs and/or OLECs according to the invention, the emotional stress can be reduced significantly. In addition, better temperature control of the child is possible due to reduced heat production of the devices according to the invention compared with conventional irradiation equipment.

The present invention furthermore relates to a method for the therapy, prophylaxis and/or diagnosis of diseases in which the copolymers and devices according to the invention are used for this purpose.

The present invention furthermore relates to a method for the therapy, prophylaxis and/or diagnosis of cosmetic conditions in which the copolymers and devices according to the invention are used for this purpose.

The present application text and also the examples below are principally directed to the use of the copolymers according to the invention in relation to PLEDs and corresponding displays. In spite of this restriction of the description, it is possible for the person skilled in the art, without a further inventive step, also to use the copolymers according to the invention as semiconductors for the further uses described above in other electronic devices.

It should be pointed out that variations of the embodiments described in the present invention fall within the scope of this invention. Each feature disclosed in the present invention can, unless explicitly excluded, be replaced by alternative features which serve the same, an equivalent or a similar purpose. Thus, each feature disclosed in the present invention should, unless stated otherwise, be regarded as an example of a generic series or as an equivalent or similar feature.

All features of the present invention can be combined with one another in any way, unless certain features and/or steps are mutually exclusive. This applies, in particular, to preferred features of the present invention. Equally, features of non-essential combinations can be used separately (and not in combination).

It should furthermore be pointed out that many of the features, and in particular those of the preferred embodiments of the present invention, should be regarded as inventive themselves and not merely as part of the embodiments of the present invention. Independent protection may be granted for these features in addition or as an alternative to each invention claimed at present.

The teaching regarding technical action disclosed with the present invention can be abstracted and combined with other examples.

The invention is explained in greater detail by the following examples without wishing it to be restricted thereby.

The person skilled in the art will be able, without being inventive, to prepare further copolymers and/or compounds according to the invention and use them in organic electronic devices.

### WORKING EXAMPLES

### Examples 1

### Synthesis of Monomer M1

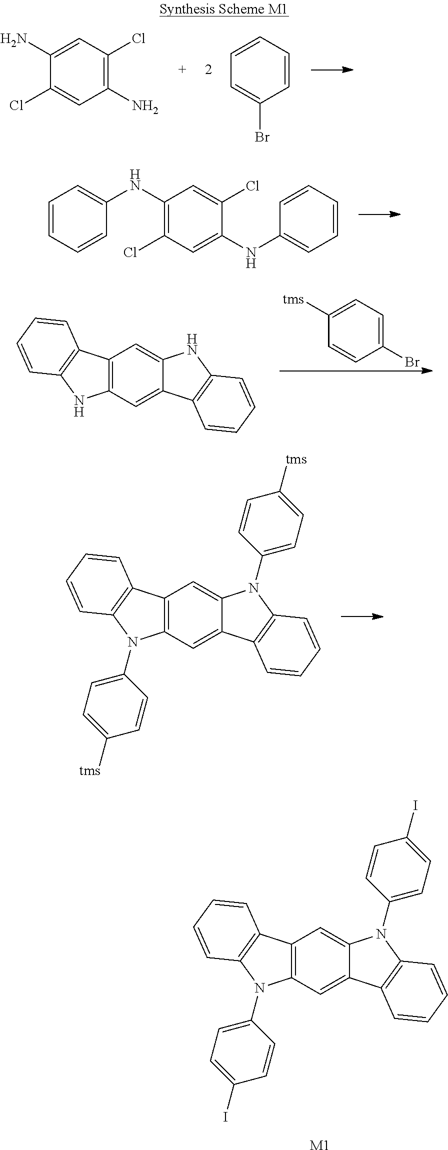

### a) Synthesis of N,N-diphenyl-1,4-diamino-2,5-dichlorobenzene

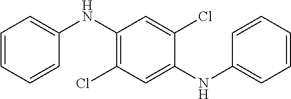 [SMILES: Clc1cc(Nc2ccccc2)c(Cl)cc1Nc1ccccc1]

100 g (565 mmol) of 1,4-diamino-2,5-dichlorobenzene, 177 g (1.2 mol) of bromobenzene and 163 g (1.7 mol) of Na tert-butoxide are dissolved in 2000 ml of toluene. The reaction solution is carefully degassed, warmed to 80° C., and 367 mg (0.4 mmol) of Pd₂(dba)₃ and 750 mg (1.2 mmol) of rac-BINAP as catalyst are added. The progress of the reaction is monitored by means of TLC. The solution is cooled to room temperature 1000 ml of H₂O are added, and the phases are separated. The aqueous phase is extracted three times with toluene, the combined organic phases are subsequently washed twice with water, dried over magnesium sulfate, filtered, and the solvent is stripped off in vacuo. The residue is recrystallised from ethanol, giving 132 g (400 mmol) (71%) of a white solid in a of purity 99.2%.

### b) Synthesis of indolocarbazole

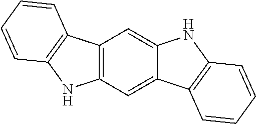 [SMILES: c1ccc2c(c1)[nH]c1cc3c(cc12)[nH]c1ccccc13]

120 g (365 mmol) of diamine, 247 g (1.82 mol) of potassium carbonate and 24.8 g (244 mmol) of pivalic acid are dissolved in 2000 ml of DMA. The reaction solution is carefully degassed, and 20.2 g (36.5 mmol) of tritert-butylphosphine are added. 8.2 g (36.5 mmol) of palladium acetate are subsequently added, and the reaction mixture is warmed to 130° C. The progress of the reaction is monitored by means of TLC. The solution is cooled to room temperature 1000 ml of dichloromethane and 1000 ml of H₂O are added, and the phases are separated. The aqueous phase is extracted three times with dichloromethane, the combined organic phases are subsequently washed twice with water, dried over magnesium sulfate, filtered, and the solvent is stripped off in vacuo. The residue is chromatographed with heptane/ethyl acetate, giving 58 g (226 mmol) (62%) of a white solid in a of purity 99.3%.

### c) Synthesis of N,N-bistrimethylsilylphenylindolocarbazole

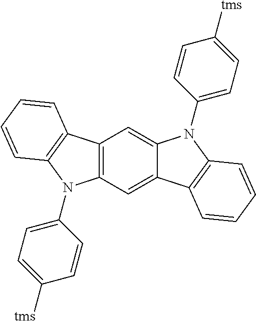

50 g (195 mmol) of indolocarbazole, 92 g (400 mmol) of 1-bromo-4-trimethylsilylbenzene and 58 g (600 mmol) of Na tert-butoxide are dissolved in 800 ml of toluene. The reaction solution is carefully degassed, warmed to 80° C., and 150 mg (0.67 mmol) of Pd(OAc)₂ and 1.1 g (2 mmol) of P(t-Bu)₃ as catalyst are added. The progress of the reaction is monitored by means of TLC. The solution is cooled to room temperature 400 ml of H₂O are added, and the phases are separated. The aqueous phase is extracted three times with toluene, the combined organic phases are subsequently washed twice with water, dried over magnesium sulfate, filtered, and the solvent is stripped off in vacuo. The residue is recrystallised from acetone, giving 79.7 g (144 mmol) (74%) of a white solid in a of purity 99.2%.

### d) Synthesis of N,N-bisiodophenylindolocarbazole M1

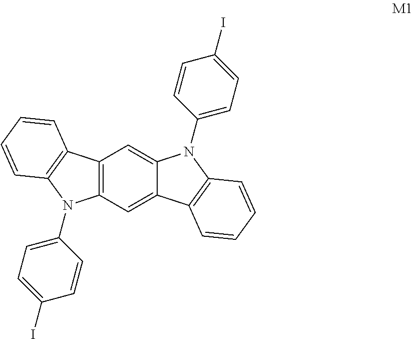 [SMILES: Ic1ccc(-n2c3ccccc3c3cc4c(cc32)c2ccccc2n4-c2ccc(I)cc2)cc1]

70 g (127 mmol) of indolocarbazole is dissolved in dichloromethane. The solution is cooled to 0° C., and a 260 ml of a 1 M solution of iodine chloride in dichloromethane are slowly added dropwise. The reaction solution is stirred at 0° C. for 2 h, and the progress of the reaction is monitored by means of TLC. The solution is warmed to room temperature saturated sodium thiosulfate solution is added until the colour disappears, and the phases are subsequently separated. The aqueous phase is extracted three times with dichloromethane, the combined organic phases are subsequently washed twice with water, dried over magnesium sulfate, filtered, and the solvent is stripped off in vacuo. The residue is recrystallised from acetone, giving 79.6 g (120 mmol) (95%) of a white solid in a of purity 99.2%.

### Examples 2

### Synthesis of N,N-bisborolanephenylindolocarbazole M2

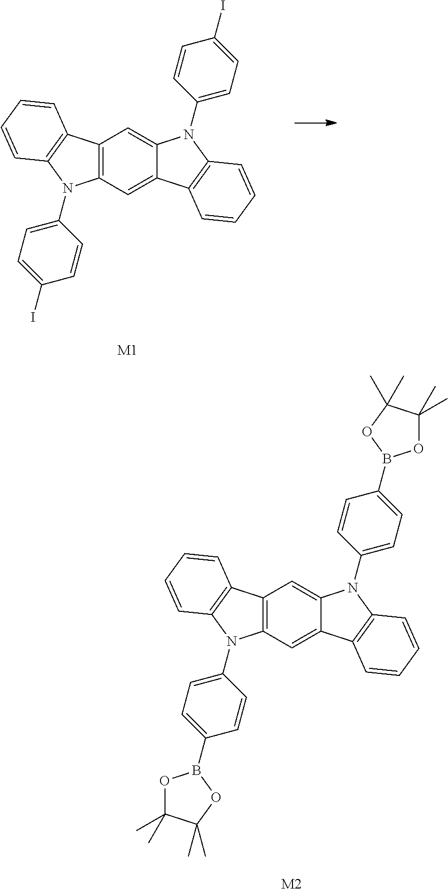

30 g (45 mmol) of diiodo is dissolved in 250 ml of dioxane, and 22.8 g (90 mmol) of bis(pinacolato)diborane and 13.2 g (135 mmol) of potassium acetate are added. 800 mg of 1,1-bis(diphenylphosphino)ferrocenepalladium(II) chloride (complex with dichloromethane (1:1), Pd 13%) are subsequently added, and the batch is warmed to 110° C. After a TLC check, the batch is cooled to room temperature, and 200 ml of water are added, the phases are separated. The organic phase is washed water, and the aqueous phase is extracted with ethyl acetate, the combined organic phases are then dried over magnesium sulfate, filtered, and the solvent is stripped off in vacuo. The residue is recrystallised from ethanol, giving 15.7 g (24 mmol) (53%) of a white solid of purity 99.9%.

### Examples 3

### Synthesis of M7

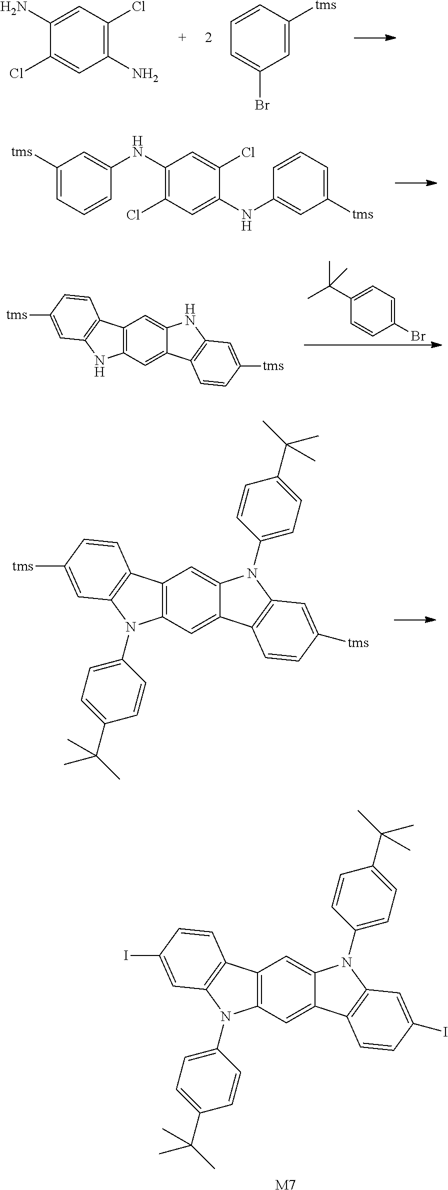

### a) Synthesis of N,N-bis-4-trimethylsilylphenyl-1,4-diamino-2,5-dichlorobenzene

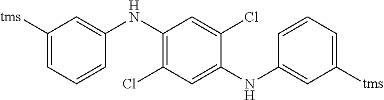

100 g (565 mmol) of 1,4-diamino-2,5-dichlorobenzene, 285 g (1.25 mol) of 1-bromo-3-trimethylsilylbenzene and 163 g (1.7 mmol) of Na tert-butoxide are dissolved in 2000 ml of toluene. The reaction solution is carefully degassed, warmed to 80° C., and 367 mg (0.4 mmol) of Pd₂(dba)₃ and 750 mg (1.2 mmol) of rac-BINAP as catalyst are added. The progress of the reaction is monitored by means of TLC. The solution is cooled to room temperature 1000 ml of H₂O are added, and the phases are separated. The aqueous phase is extracted three times with toluene, the combined organic phases are subsequently washed twice with water, dried over magnesium sulfate, filtered, and the solvent is stripped off in vacuo. The residue is recrystallised from ethanol, giving 171 g (362 mmol) (64%) of a white solid in a of purity 99.2%.

### b) Synthesis of 2.7 ditrimethylsilylindolocarbazole

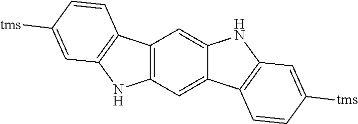

150 g (317 mmol) of diamine, 220 g (1.58 mol) of potassium carbonate and 21.6 g (211 mmol) of pivalic acid are dissolved in 2000 ml of DMA. The reaction solution is carefully degassed, and 17.2 g (31.7 mmol) of tritert-butylphosphine are added. 6.96 g (31.7 mmol) of palladium acetate are subsequently added, and the reaction mixture is warmed to 130° C. The progress of the reaction is monitored by means of TLC. The solution is cooled to room temperature 1000 ml of dichloromethane and 1000 ml of H₂O are added, and the phases are separated. The aqueous phase is extracted three times with dichloromethane, the combined organic phases are subsequently washed twice with water, dried over magnesium sulfate, filtered, and the solvent is stripped off in vacuo. The residue is chromatographed with heptane/ethyl acetate, giving 73.7 g (184 mmol) (58%) of a white solid in a of purity 99.3%.

### c) Synthesis of N,N-tert-butylphenyl-2,7-bistrimethylsilylindolocarbazole

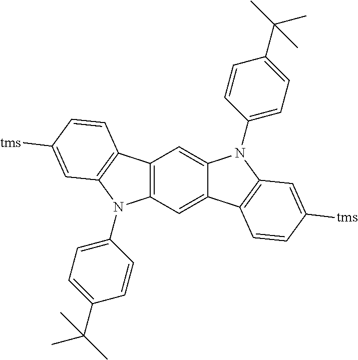

50 g (125 mmol) of indolocarbazole, 58 g (275 mmol) of 1-bromo-4-tert-butylbenzene and 38 g (400 mmol) of Na tert-butoxide are dissolved in 500 ml of toluene. The reaction solution is carefully degassed, warmed to 80° C., and 120 mg (0.55 mmol) of Pd(OAc)₂ and 500 mg (0.165 mmol) of P(t-Bu)₃ as catalyst are added. The progress of the reaction is monitored by means of TLC. The solution is cooled to room temperature 200 ml of H₂O are added, and the phases are separated. The aqueous phase is extracted three times with toluene, the combined organic phases are subsequently washed twice with water, dried over magnesium sulfate, filtered, and the solvent is stripped off in vacuo. The residue is recrystallised from acetone, giving 75 g (112 mmol) (90%) of a white solid in a of purity 99.2%.

### d) Synthesis of dibromo-N,N-tertbutylphenylindolocarbazole M7

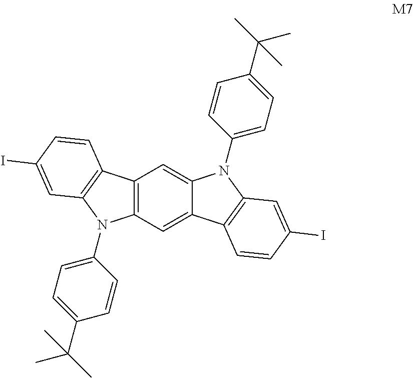 [SMILES: CC(C)(C)c1ccc(-n2c3cc(I)ccc3c3cc4c(cc32)c2ccc(I)cc2n4-c2ccc(C(C)(C)C)cc2)cc1]

50 g (75 mmol) of indolocarbazole is dissolved in dichloromethane. The solution is cooled to 0° C., and 155 ml of a 1 M solution of ICl in dichloromethane are slowly added. The reaction solution is stirred at 0° C. for 2 h, and the progress of the reaction is monitored by means of TLC. The solution is warmed to room temperature saturated sodium thiosulfate solution is added until the colour disappears, and the phases are subsequently separated. The aqueous phase is extracted three times with dichloromethane, the combined organic phases are subsequently washed twice with water, dried over magnesium sulfate, filtered, and the solvent is stripped off in vacuo. The residue is recrystallised a number of times from toluene/acetonitrile 1:1, giving 38 g (50 mmol) (66%) of a white solid in a of purity 99.2%.

### Example 4

### Synthesis of N,N-tertbutylphenylindolocarbazole-2,7-bisborolane M8

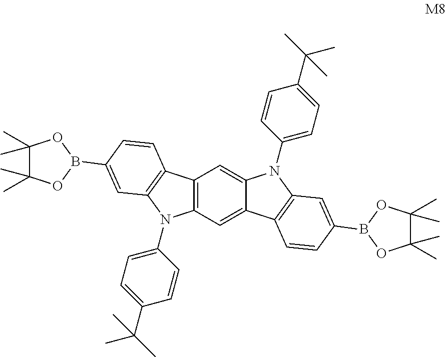

20 g (26 mmol) of diiodide is dissolved in 200 ml of dioxane, and bis(pinacolato)diborane 14.5 g (57 mmol) and 7.6 g (78 mmol) of potassium acetate are added. 408 mg of 1,1-bis(diphenylphosphino)ferrocenepalladium(II) chloride (complex with dichloromethane (1:1), Pd 13%) are subsequently added, and the batch is warmed to 110° C. After a TLC check, the batch is cooled to room temperature, and 200 ml of water are added, the phases are separated. The organic phase is washed water, and the aqueous phase is extracted with ethyl acetate, the combined organic phases are then dried over magnesium sulfate, filtered, and the solvent is stripped off in vacuo. The residue is recrystallised from ethanol, giving 14.5 g (19 mmol) (72%) of a white solid of purity 99.9%.

### Examples 5

### Further Monomers for the Suzuki Polymerisation

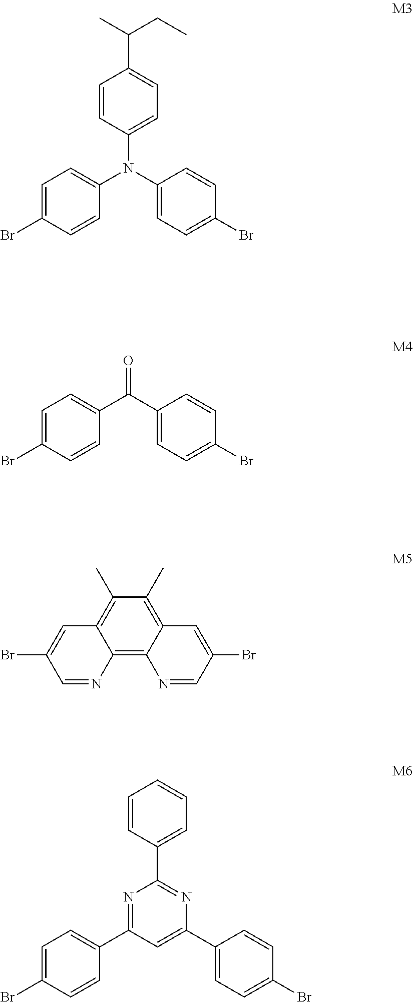 [SMILES: CCC(C)c1ccc(N(c2ccc(Br)cc2)c2ccc(Br)cc2)cc1 ; O=C(c1ccc(Br)cc1)c1ccc(Br)cc1 ; Cc1c(C)c2cc(Br)cnc2c2ncc(Br)cc12 ; Brc1ccc(-c2cc(-c3ccc(Br)cc3)nc(-c3ccccc3)n2)cc1]

### Examples 6

### Synthesis of polymers P1 to P5 and V1 to V5

### General Polymerisation Procedure for the Suzuki Polymerisation of Monomers M1-M8 as Polymerisable Group.

Polymers P1 to P5 according to the invention and comparative polymers V1 to V5 are synthesised by SUZUKI coupling in accordance with WO 03/048225 A2 using the following monomers (percent data=mol %).

TABLE 1
Composition of the polymers in mol %

| Polymer | M1 | M2 | M3 | M4 | M5 | M6 | M7 | M8 | Mw |
|---|---|---|---|---|---|---|---|---|---|
| P1 | 50 | 50 | 0 | 0 | 0 | 0 | 0 | 0 | 213.000 |
| P2 | 0 | 50 | 50 | 0 | 0 | 0 | 0 | 0 | 307.000 |
| P3 | 0 | 50 | 0 | 50 | 0 | 0 | 0 | 0 | 278.000 |
| P4 | 0 | 50 | 0 | 0 | 50 | 0 | 0 | 0 | 251.000 |
| P5 | 0 | 50 | 0 | 0 | 0 | 50 | 0 | 0 | 389.000 |
| V1 | 0 | 0 | 0 | 0 | 0 | 0 | 50 | 50 | 321.000 |
| V2 | 0 | 0 | 50 | 0 | 0 | 0 | 0 | 50 | 257.000 |
| V3 | 0 | 0 | 0 | 50 | 0 | 0 | 0 | 50 | 281.000 |
| V4 | 0 | 0 | 0 | 0 | 50 | 0 | 0 | 50 | 238.000 |
| V5 | 0 | 0 | 0 | 0 | 0 | 50 | 0 | 50 | 277.000 |

### Examples 7

### Quantum-Chemical Simulations

Firstly, the organic compounds are analysed by means of quantum-chemical calculations, where P1 to P5 represent the polymers according to the invention and V1 to V5 represent the comparative polymers.

The HOMO (highest occupied molecular orbital) and LUMO positions (lowest unoccupied molecular orbital) and the triplet/singlet level of the organic compounds are determined via quantum-chemical calculations. To this end, the “Gaussian03W” software (Gaussian Inc.) is used. In order to calculate organic substances without metals, firstly a geometry optimisation is carried out using a “Ground State/Semi-empirical/Default Spin/AM1” semi-empirical method (Charge 0/Spin Singlet). This is followed by an energy calculation on the basis of the optimised geometry. The “TD-SCF/DFT/Default Spin/B3PW91” method (TD-SCF/DFT—time dependent-self consistent field/density functional theory) with the “6-31G(d)” base set is used here (charge 0/spin singlet). For organometallic compounds, the geometry is optimised via the “Ground State/Hartree-Fock/Default Spin/LanL2MB” method (Charge 0/Spin Singlet). The energy calculation is carried out analogously to the organic substances as described above, with the difference that the “LanL2DZ” base set (pseudo=LanL2) is used for the metal atom and the “6-31G(d)” base set is used for the ligands. The most important results from these calculations are the HOMO and LUMO energy levels and energies for the triplet and singlet excited states. The first excited singlet and triplet state is in each case of particular interest here. These are typically denoted by S1 (first excited singlet state) and T1 (first excited triplet state). The energy calculation gives the HOMO HEh or LUMO LEh in hartree units. The HOMO and LUMO values in electron-volts are determined therefrom as follows, where these relationships arise from the calibration with reference to cyclic voltammetry measurements (CV):

HOMO(eV)=((HEh*27.212)−0.9899)/1.1206

LUMO(eV)=((LEh*27.212)−2.0041)/1.385

For polymers, in particular conjugated polymers, the calculations were restricted to trimers, i.e. a polymer containing monomers M1 and M2 trimers M2-M1-M2 and/or M1-M2-M1 are calculated, where polymerisable groups are removed. Furthermore, long alkyl chains are reduced to a methyl unit. An example of polymer P1 is depicted below. The agreement between CV measurements and simulations of polymers is disclosed in WO 2008/011953 A1.

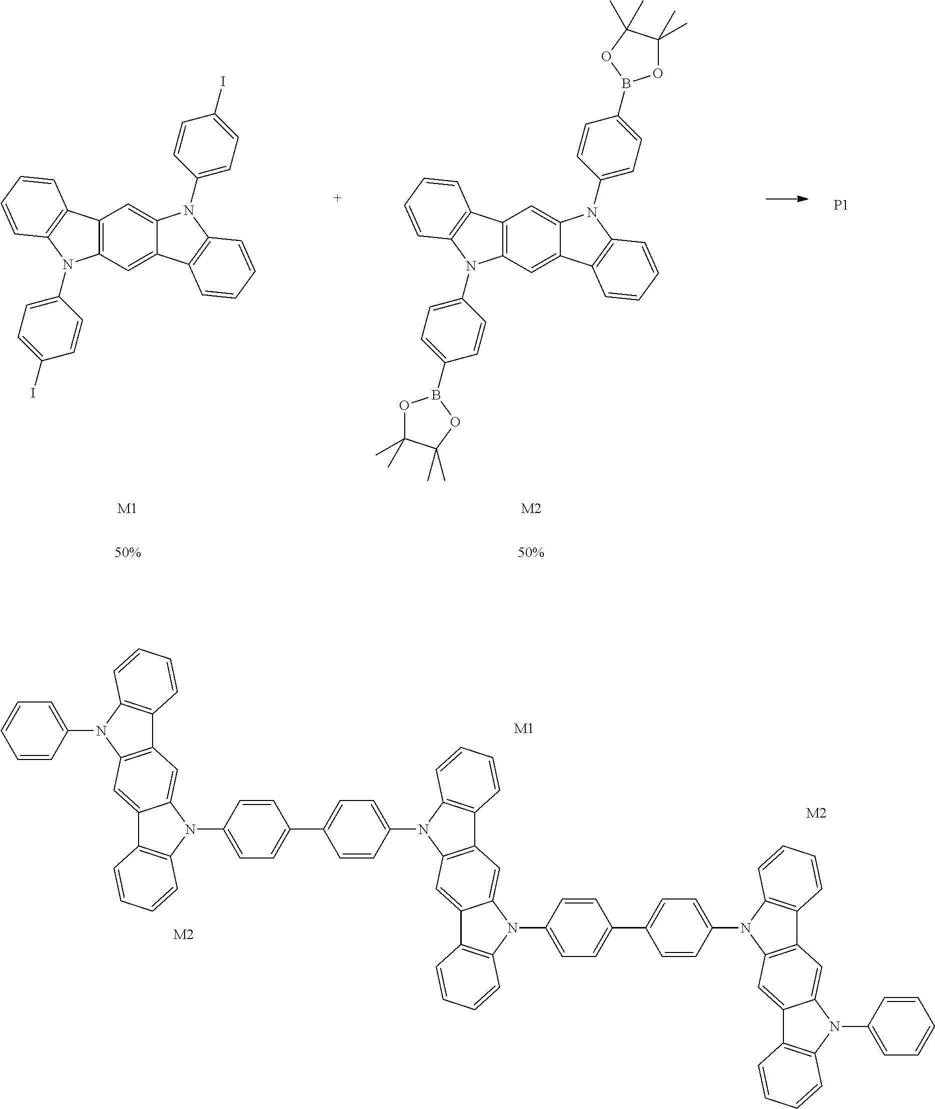

For the purposes of this application, these values are to be regarded as the energetic position of the HOMO level or of the LUMO level of the materials. As an example, an HOMO of −0.18392 hartrees and an LUMO of −0.04771 hartrees, which corresponds to a calibrated HOMO of −5.35 eV, a calibrated LUMO of −2.38 eV, are obtained for polymer P1 (M2-M1-M2 in Table 2) by means of simulation.

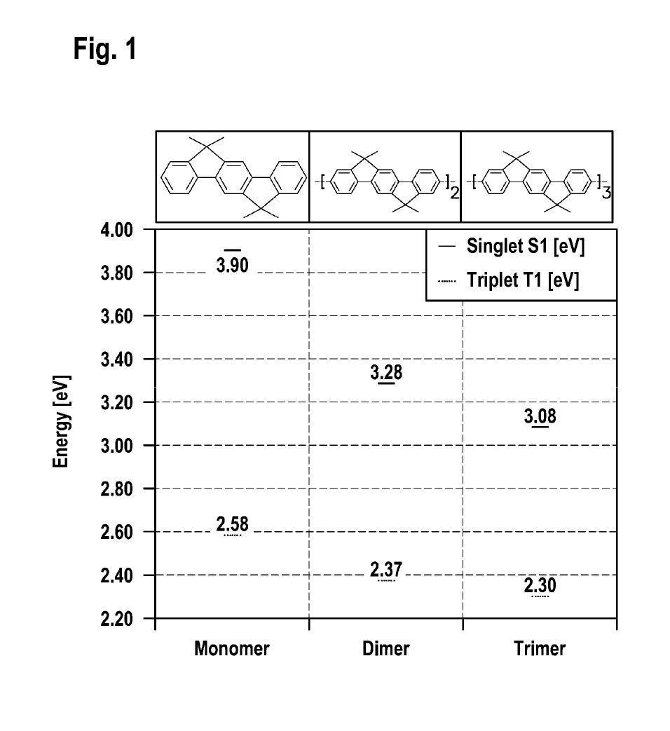

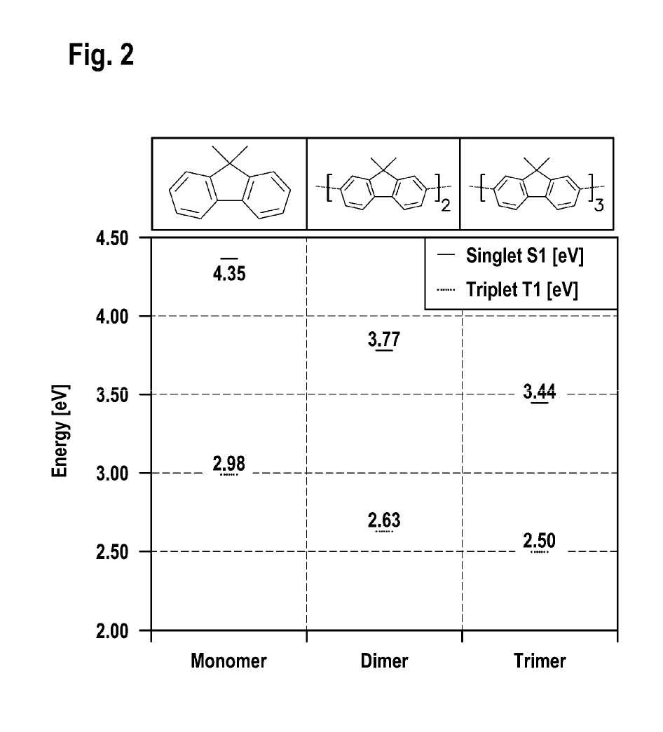

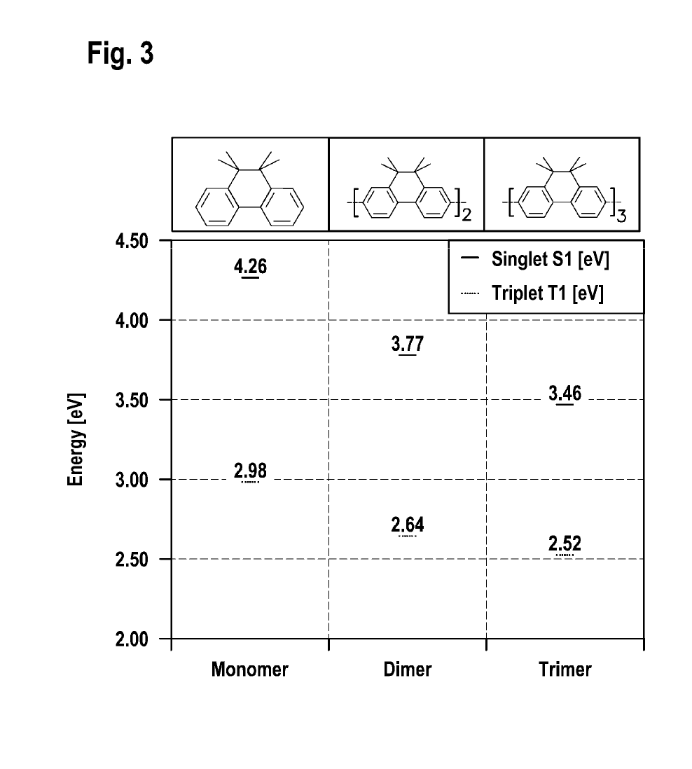

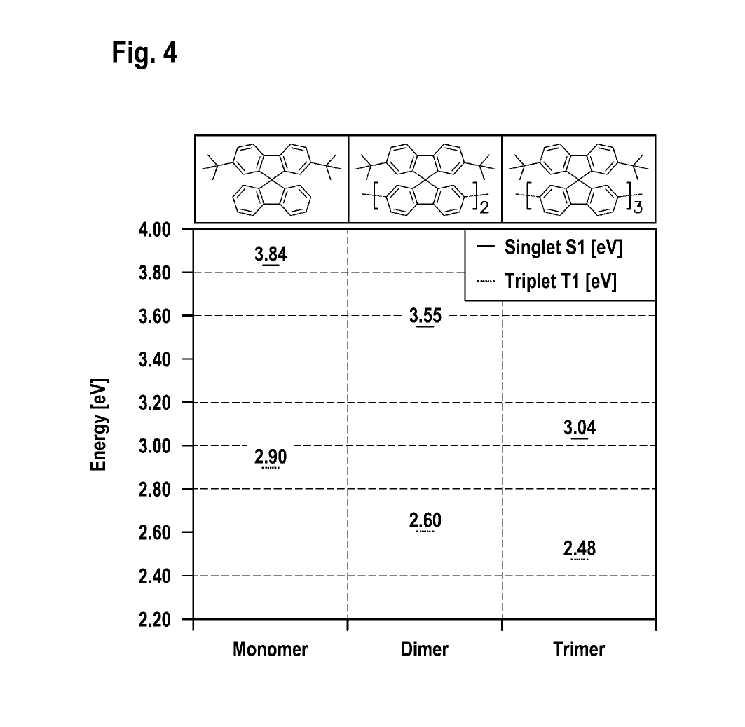

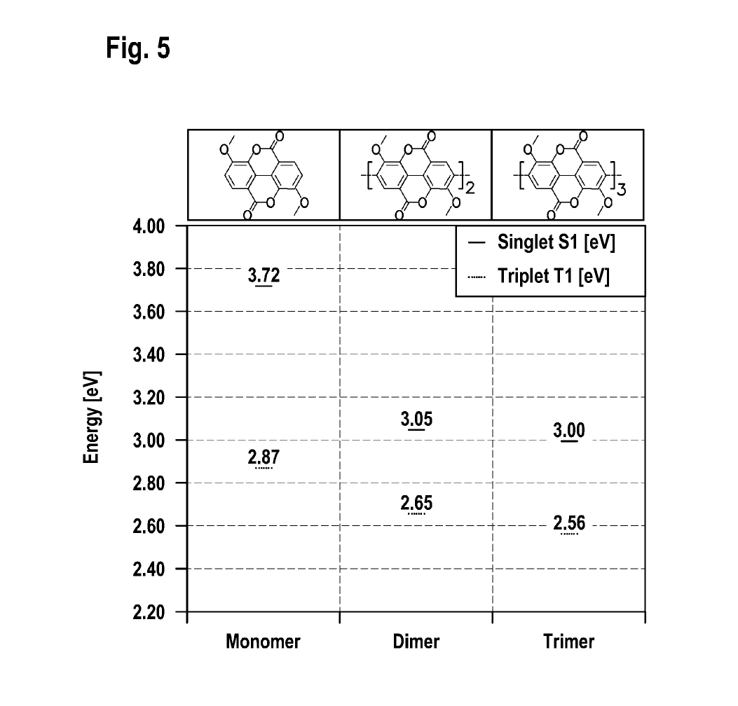

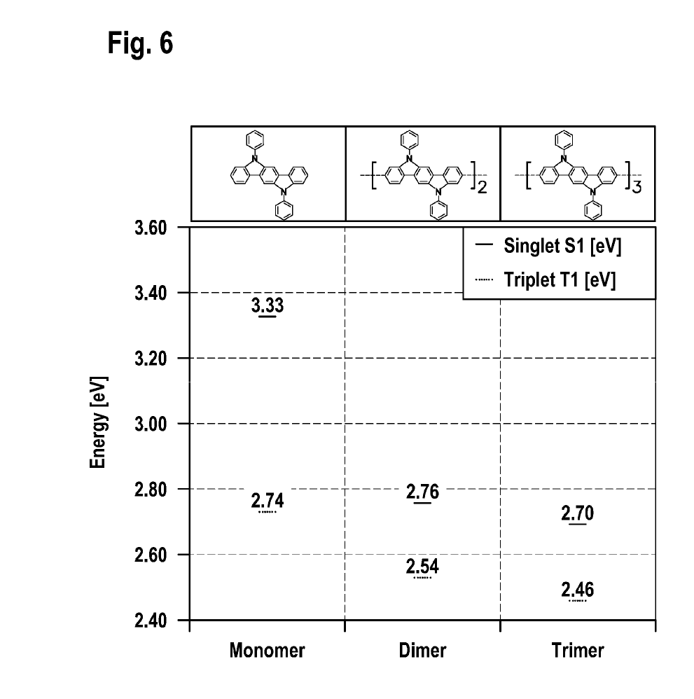

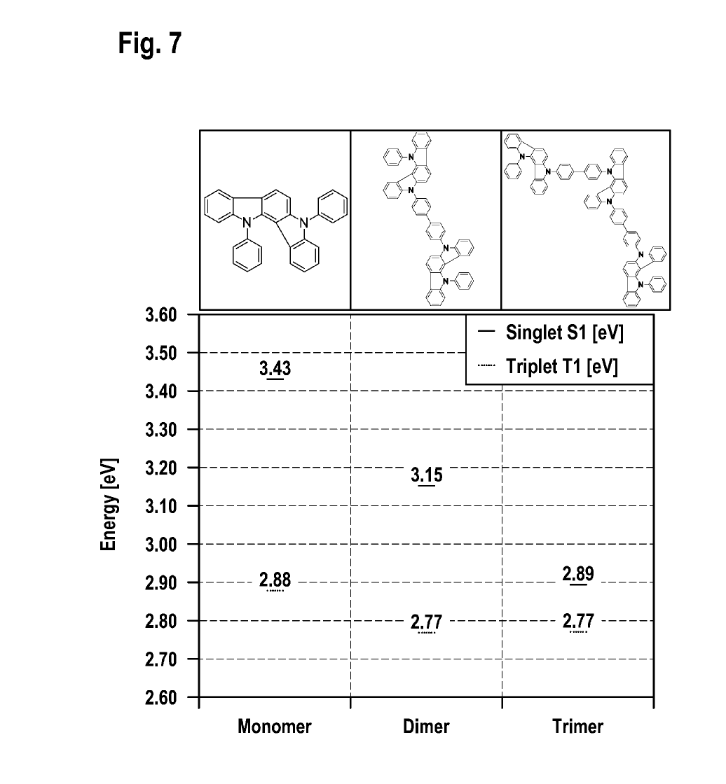

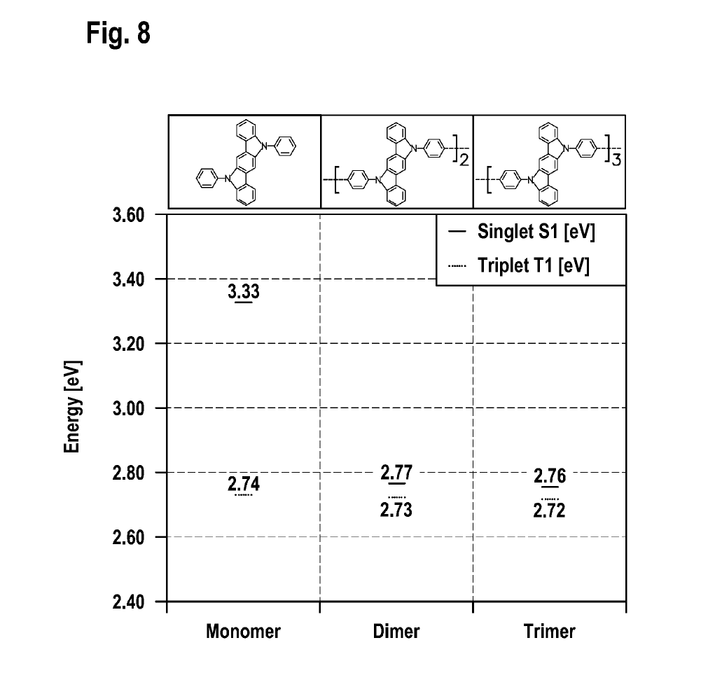

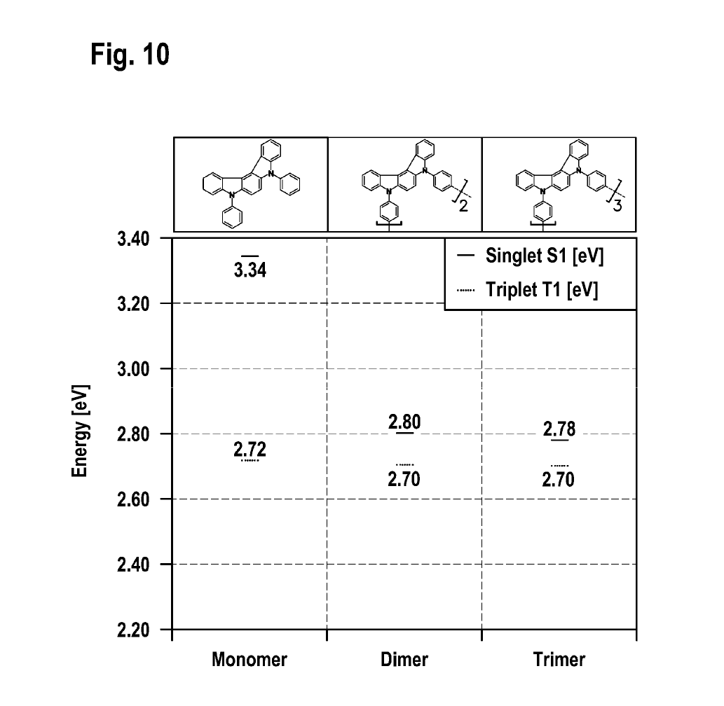

Firstly, the conventional conjugated polymers and the polymers according to the invention are investigated by the method described above. To this end, the S1 and T1 level of monomer, dimer and trimer of various polymer backbones is simulated and compared. FIGS. 1 to 6 show the results. As can be seen, the T1 level drop rapidly with conjugation length. For the trimers, the T1 level is already so low that they are no longer suitable for green emitters. FIGS. 7 to 13 show the results for 7 polymers according to the invention (see Table 2). In contrast to the conventional polymers, the polymers according to the invention have a number of advantages:
1. The T1 level of the polymers according to the invention tends to drop significantly more slowly;
2. in particular between the dimer and trimer, there are only small differences between the T1 levels.
3. In some cases (see FIGS. 8 and 10), the T1 level hardly changes between monomer, dimer and trimer;
4. in virtually all cases, the high T1 levels show that the compounds are suitable for green triplet emitters;

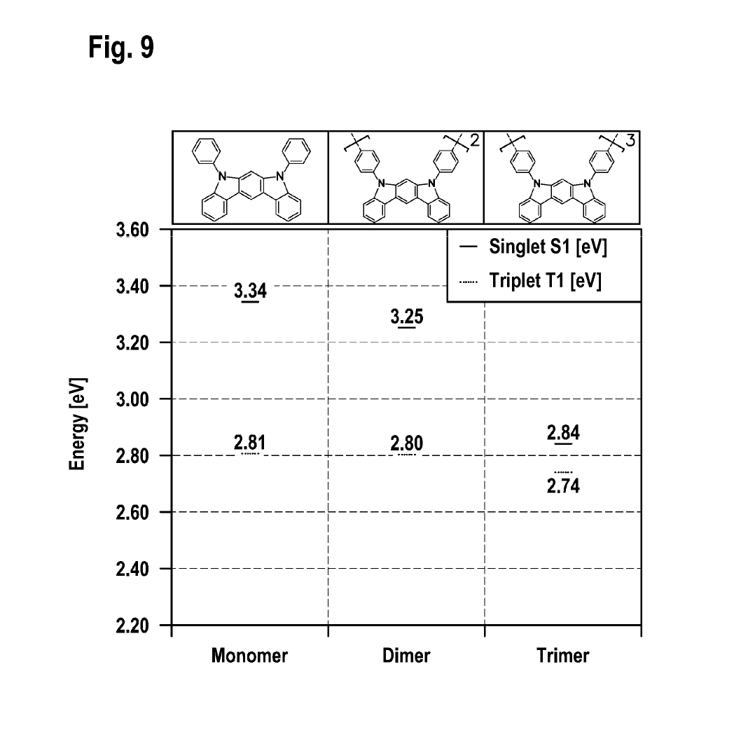

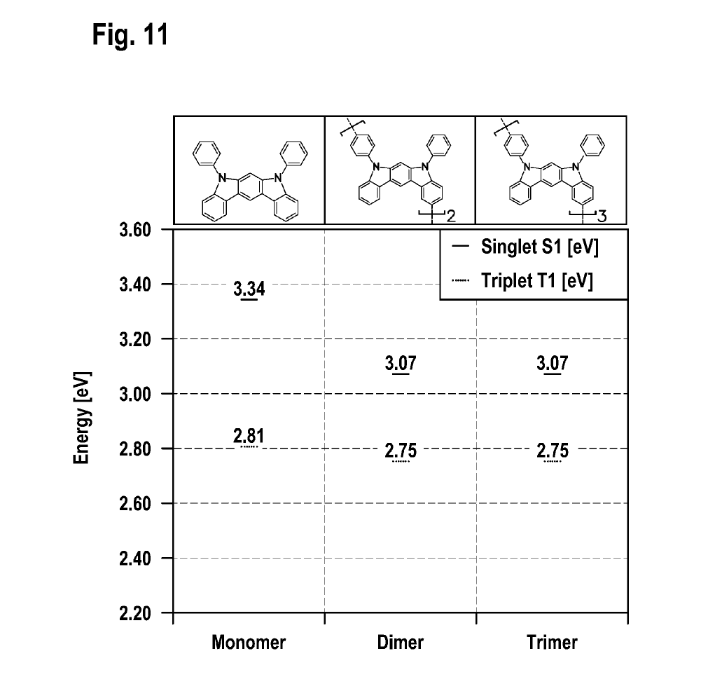

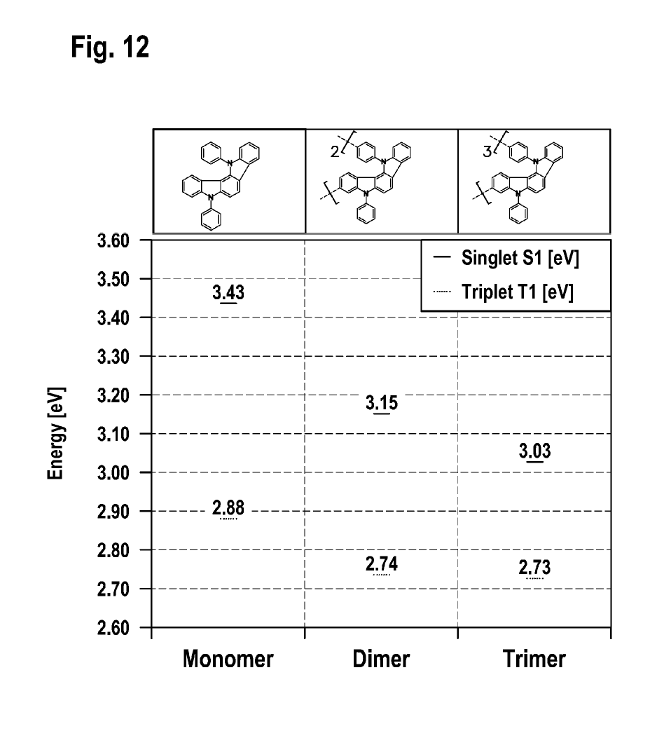

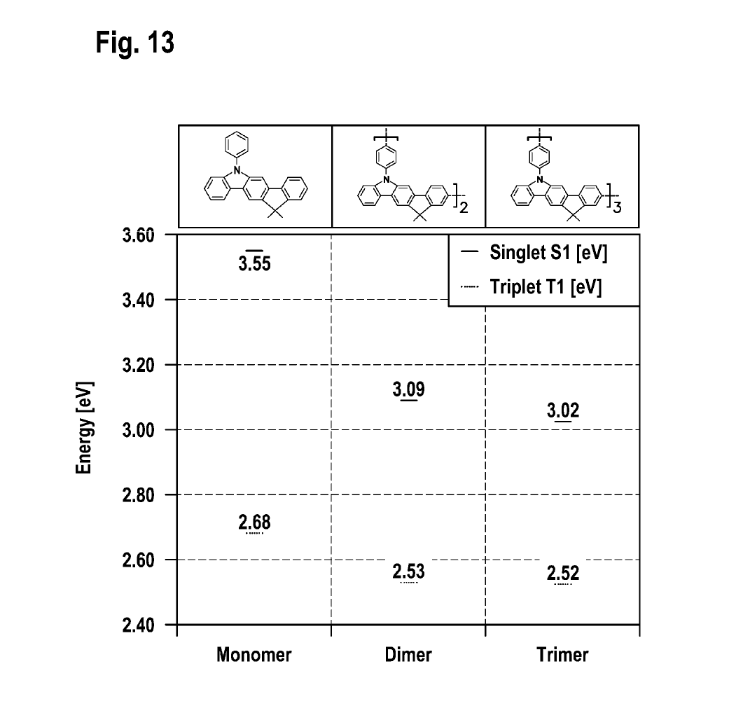

TABLE 2
Simulated preferred embodiment

| FIG. | Corresponding embodiment |
|---|---|
| FIG. 7 | Formula (34) |
| FIG. 8 | Formula (35) |
| FIG. 9 | Formula (37) |
| FIG. 10 | Formula (38) |
| FIG. 11 | Formula (39) |
| FIG. 12 | Formula (41) |
| FIG. 13 | Formula (42) |

Table 3 shows a comparison of the results for polymers P1 to P5 according to the invention and those for comparative polymers V1 to V5. The following is evident here:
1. All polymers P1 to P5 have higher T1 levels than those of polymers V1 to V5. They are consequently more suitable as matrix materials for phosphorescent green emitters;
2. P1 and P2 have an HOMO around −5.2 to −5.3 eV and are therefore particularly highly suitable as HTL and/or host. If the polymers are employed as HTL, they will then have improved electron-blocking properties owing to the high LUMO and better triplet exciton-blocking properties owing to the high T1 level. They therefore have technical advantages over V1 and V2.
3. P3, P4 and P5 have a higher T1 level and lower LUMO than polymers V3, V4 and V5. They are therefore highly suitable as ETL.

TABLE 3
Summary of the energy levels of P1-5 and V1-5

| | | TD-DFT | | | |
|---|---|---|---|---|---|
| | | | | | S1 |
| | | Homo corr. [eV] | Lumo corr. [eV] | T1 [eV] | [eV] |
| P1 | M2-M1-M2 | −5.35 | −2.38 | 2.72 | 2.76 |
| V1 | M8-M7-M8 | −5.39 | −2.56 | 2.46 | 2.70 |
| P2 | M2-M3-M2 | −5.21 | −2.32 | 2.57 | 2.75 |
| V2 | M8-M3-M8 | −5.12 | −2.43 | 2.46 | 2.72 |
| P3 | M2-M4-M2 | −5.45 | −2.91 | 2.59 | 2.74 |
| V3 | M8-M4-M8 | −5.47 | −2.81 | 2.54 | 2.62 |
| P4 | M2-M5-M2 | −5.41 | −2.77 | 2.48 | 2.77 |
| V4 | M8-M5-M8 | −5.45 | −2.70 | 2.46 | 2.65 |
| P5 | M2-M6-M2 | −5.42 | −2.79 | 2.70 | 2.75 |
| V5 | M8-M6-M8 | −5.45 | −2.72 | 2.60 | 3.04 |

The T1 level of TEG1 is 2.52 eV, which is determined by the onset of the PL spectrum in toluene solution.

### Example 8

### Solutions and Compositions Comprising TMM1, P1 to P5, V1 to V5 and TEG1

Solutions corresponding to the composition from Table 4 can be prepared as follows: firstly, the compositions are dissolved in 10 ml of chlorobenzene and stirred until the solution is clear. The solution is filtered using a Millipore Millex LS, hydrophobic PTFE 5.0 μm filter.

TABLE 4
Composition of the solutions

| | | Ratio (based | | |
|---|---|---|---|---|
| Solution | Composition | on weight) | Solvent | Concentration |
| 1 | P1 + TEG1 | 80:20 | Chlorobenzene | 10 mg/ml |
| 2 | P2 | 100 | Chlorobenzene | 5 mg/ml |
| 3 | P3 + TEG1 | 80:20 | Chlorobenzene | 10 mg/ml |
| 4 | P4 + TEG1 | 80:20 | Chlorobenzene | 10 mg/ml |
| 5 | P5 + TEG1 | 80:20 | Chlorobenzene | 10 mg/ml |
| 6 | V1 + TEG1 | 80:20 | Chlorobenzene | 10 mg/ml |
| 7 | V2 | 100 | Chlorobenzene | 5 mg/ml |
| 8 | V3 + TEG1 | 80:20 | Chlorobenzene | 10 mg/ml |
| 9 | V4 + TEG1 | 80:20 | Chlorobenzene | 10 mg/ml |
| 10 | V5 + TEG1 | 80:20 | Chlorobenzene | 10 mg/ml |

Solutions 2 and 7 are used in order to coat the interlayer of OLEDs. Other solutions are used in order to coat the emitting layer of OLEDs. The corresponding solid composition can be obtained by evaporating the solvent of the solutions. This composition can be used for the preparation of further formulations.

In addition, HIL-012 (interlayer polymer from Merck KGaA) is used as standard interlayer. For this purpose, a solution of HIL-012 in toluene in concentration of 5 mg/ml is prepared.

### Example 9

### Production of OLEDs

OLED1 to OLED10 (see Table 5) having a typical structure in accordance with the prior art (anode/PEDOT/interlayer/EML/cathode) are produced using the corresponding solutions 1 to 10 (Table 4) in accordance with the following procedure:
1. Application of 80 nm of PEDOT (Baytron P AI 4083) to an ITO-coated glass substrate by spin coating.
2. Application of a 20 nm interlayer by spin coating a solution: solution 2 (Table 4) for OLED2, solution 7 (Table 4) for OLED7, and HIL-012 solution in toluene (concentration 0.5% by weight) for others, in a glovebox.
3. Heating of the interlayer at 180° C. for 1 h in a glovebox.
4. Application of an 80 nm emitting layer (EML) by spin coating a solution in accordance with Table 4.
5. Heating of the device at 120° C. for 20 min.
6. Application of a Ba/Al cathode by vapour deposition (3 nm+150 nm).
7. Encapsulation of the device.

TABLE 5
Materials in layer structure

| OLED | Interlayer | EML |
|---|---|---|
| OLED1 | HIL-012 | P1 + TEG1 |
| OLED2 | P2 | P1 + TEG1 |
| OLED3 | HIL-012 | P3 + TEG1 |
| OLED4 | HIL-012 | P4 + TEG1 |
| OLED5 | HIL-012 | P5 + TEG1 |
| OLED6 | HIL-012 | V1 + TEG1 |
| OLED7 | V2 | P1 + TEG1 |
| OLED8 | HIL-012 | V3 + TEG1 |
| OLED9 | HIL-012 | V4 + TEG1 |
| OLED10 | HIL-012 | V5 + TEG1 |

### Example 9

### Characterisation of the OLEDs

The OLEDs obtained in this way are characterised by means of standard methods which are well known to the person skilled in the art. The following properties are measured here: UIL characteristics, electroluminescence spectrum, colour coordinates, efficiency, operating voltage and lifetime. The results are summarised in Table 6, where OLED6 to OLED10 serve as comparison in accordance with the prior art. In Table 5, Uₒₙ stands for the turn-on voltage, U(100) stands for the voltage at 100 cd/m² and U(1000) stands for the voltage at 1000 cd/m².

TABLE 6
Measurement results with OLED1 to OLED6

| | Max. eff. | Uₒₙ | U(100) | U(1000) | CIE @ |
|---|---|---|---|---|---|
| | [cd/A] | [V] | [V] | [V] | 100 cd/m² |
| OLED1 | 26.2 | 2.81 | 3.80 | 6.10 | 0.35/0.62 |
| OLED2 | 32.3 | 2.78 | 3.90 | 5.38 | 0.35/0.61 |
| OLED3 | 25.3 | 2.84 | 4.10 | 5.97 | 0.35/0.62 |
| OLED4 | 21.1 | 2.74 | 3.90 | 6.65 | 0.34/0.62 |
| OLED5 | 27.3 | 2.92 | 4.00 | 5.60 | 0.35/0.62 |
| OLED6 | 18.2 | 2.80 | 3.91 | 7.10 | 0.34/0.62 |
| OLED7 | 28.3 | 2.78 | 3.88 | 5.61 | 0.35/0.61 |
| OLED8 | 17.3 | 2.84 | 4.20 | 7.05 | 0.35/0.62 |
| OLED9 | 20.5 | 2.73 | 4.61 | 7.65 | 0.35/0.62 |
| OLED10 | 18.3 | 3.06 | 5.20 | 7.41 | 0.35/0.61 |

As can be seen from Table 6, the use of the polymers according to the invention as matrix or interlayer is advantageous.
1. OLED1, 3, 4 and 5 exhibit significantly better efficiency and operating voltages than OLED6, 8, 9 and 10;
2. OLED2 exhibits better efficiency than OLED1 and OLED7.

The improvements reflect the quantum-chemical simulations above. All OLEDs exhibit comparable colour coordinates.

On the basis of the present technical teaching according to the invention, further optimisations can be achieved by means of various possibilities without being inventive in the process. Thus, a further optimisation can be achieved, for example, by the use of another co-matrix or other emitters in the same or a different concentration.

1-19. (canceled)

20. A copolymer containing, as structural unit, a compound of the general formula (1) 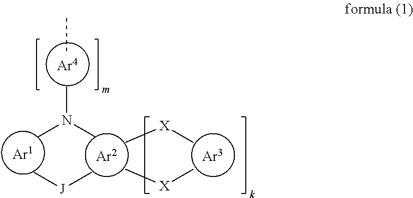
where the following applies to the symbols and indices:
J is on each occurrence, identically or differently, a single covalent bond or a divalent bridge selected from the group consisting of N(R¹), B(R¹), C(R¹)₂, O, Si(R¹)₂, C═C(R¹)₂, S, S═O, SO₂, P(R¹) and P(═O)R¹;
R¹ is, identically or differently on each occurrence, —H, —F, —Cl, Br, I, —CN, —NO₂, —CF₃, B(OR²)₂, Si(R²)₃, a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², O, S, —COO— or CONR² and where one or more H atoms is optionally replaced by D, F, Cl, Br, I, CN or NO₂, or arylamines, or substituted or unsubstituted carbazoles, each of which is optionally substituted by one or more radicals R², or an aryl or heteroaryl group having 5 to 40 ring atoms, which by one or more aromatic;
R² is on each occurrence, identically or differently, H, D or an aliphatic or aromatic hydrocarbon radical having 1 to 20 C atoms or a substituted or unsubstituted aromatic or heteroaromatic ring system having 5 to 40 ring atoms;
k is either 0 or 1, where, for k=0, the bonding to an adjacent monomer unit in the polymer takes place via Ar²;
m is either 0 or 1;
X is selected, independently of one another, from 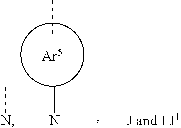
with the proviso that at least one X is not equal to J, where, in the case where k=1 and X is equal to J and J¹, the bonding to an adjacent monomer unit in the polymer takes place via Ar³;
Ar¹-Ar⁵ are selected, identically or differently on each occurrence, from an unsubstituted or R¹-substituted aromatic or heteroaromatic ring system;
J¹ is on each occurrence, identically or differently, a divalent bridge selected from the group consisting of N(R¹), B(R¹), C(R¹)₂, O, Si(R¹)₂, C═C(R¹)₂, S, S═O, SO₂, P(R¹) and P(═O)R¹;
and where the dashed line represents a bond to an adjacent monomer unit in the polymer.

21. The copolymer according to claim 20 containing, as structural unit, a compound of the general formula (2), (3), (4), (5), (6), (7), (8) or (9). 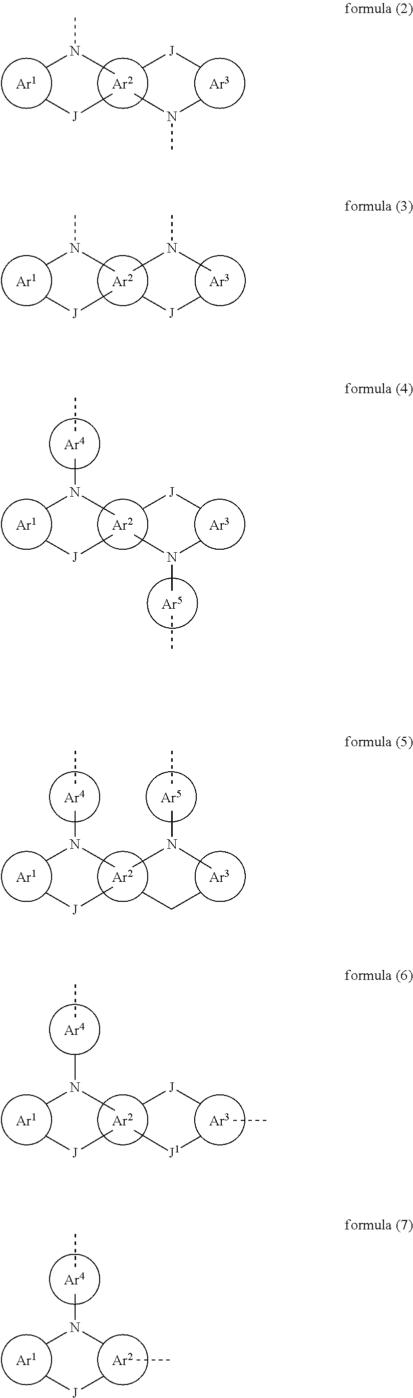 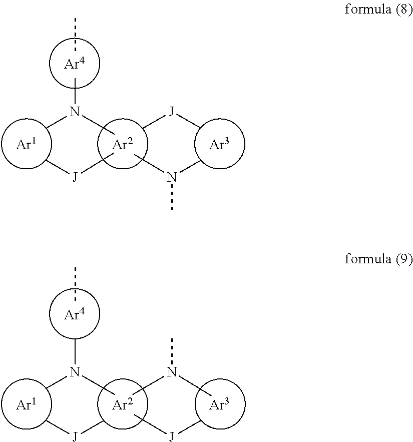
where for the symbols and indices have the meaning indicated in claim 20.

22. The copolymer according to claim 20, wherein Ar¹ to Ar³ are selected, identically or differently on each occurrence, from an unsubstituted or R¹-substituted aromatic ring.

23. The copolymer according to claim 20, wherein the compounds of the formula (1) is selected from the following compounds of the formulae (10) to (28), 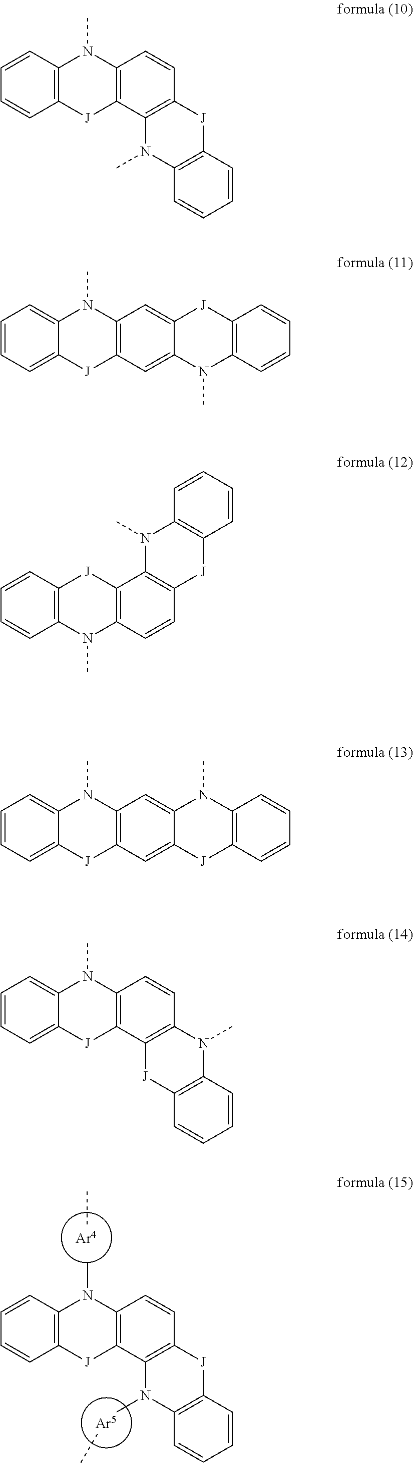 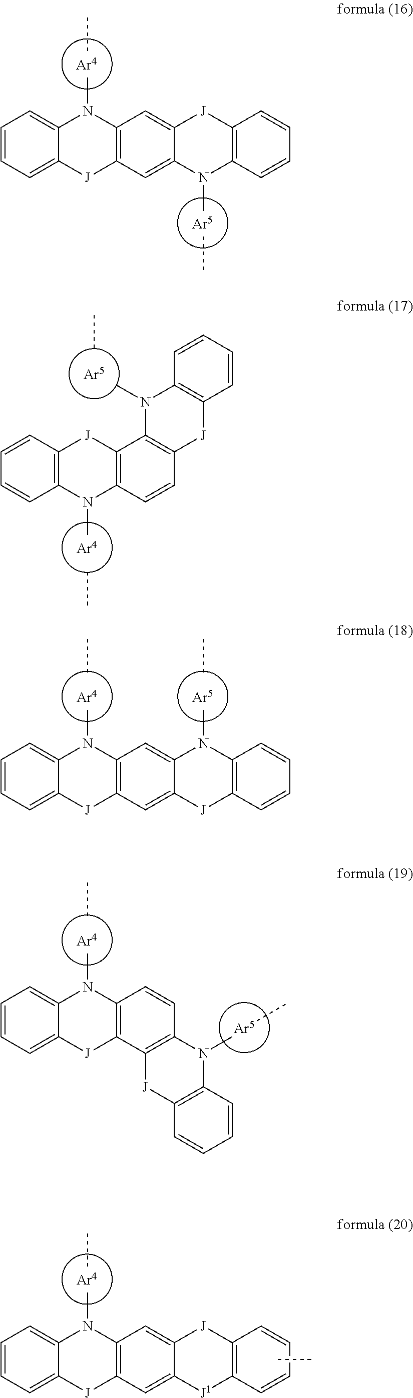 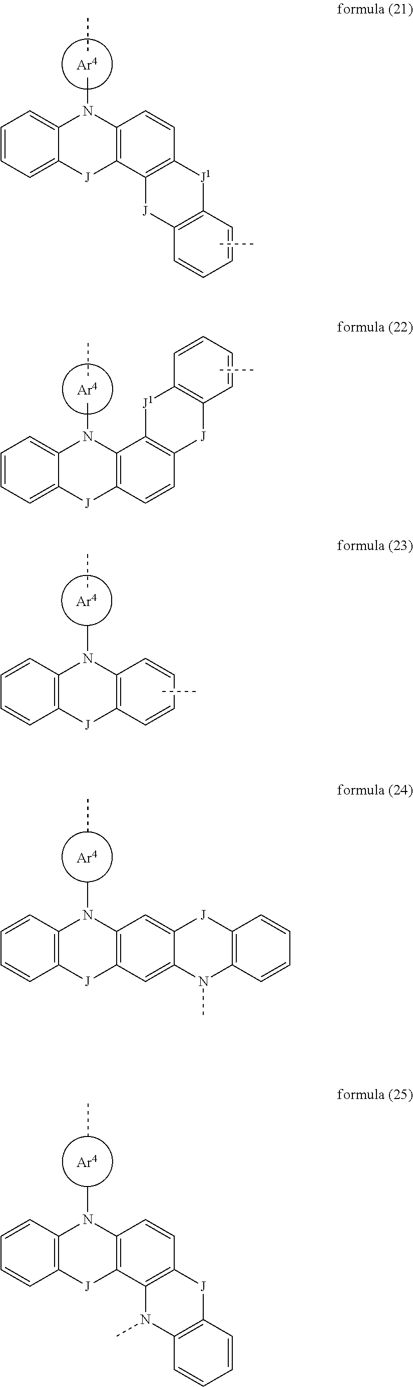 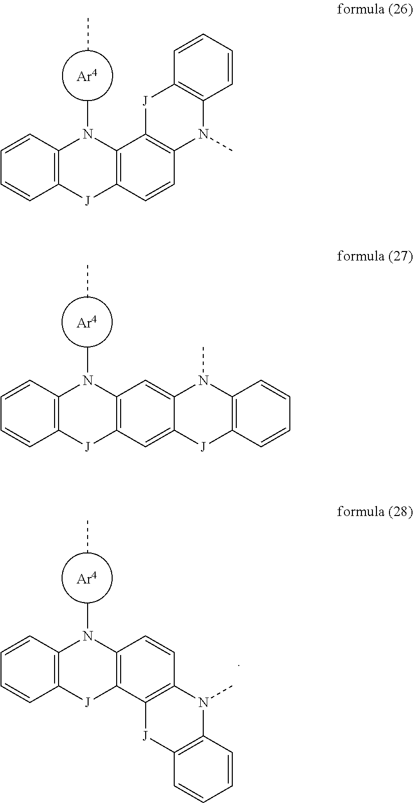
where the symbols and indices have the meaning indicated in claim 20.

24. The copolymer according to claim 20, wherein the compounds of the formula (1) is selected from the compounds of the formulae (29) to (48), 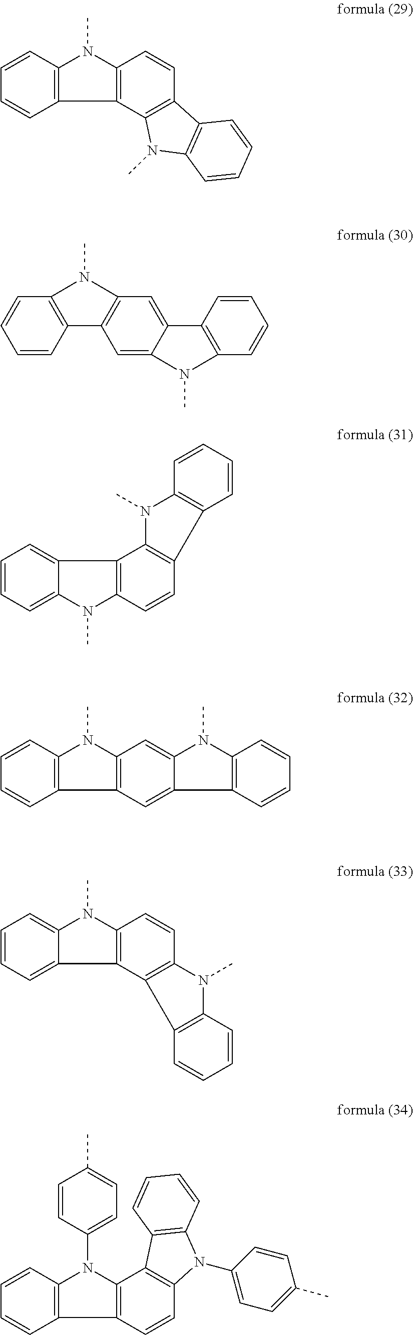 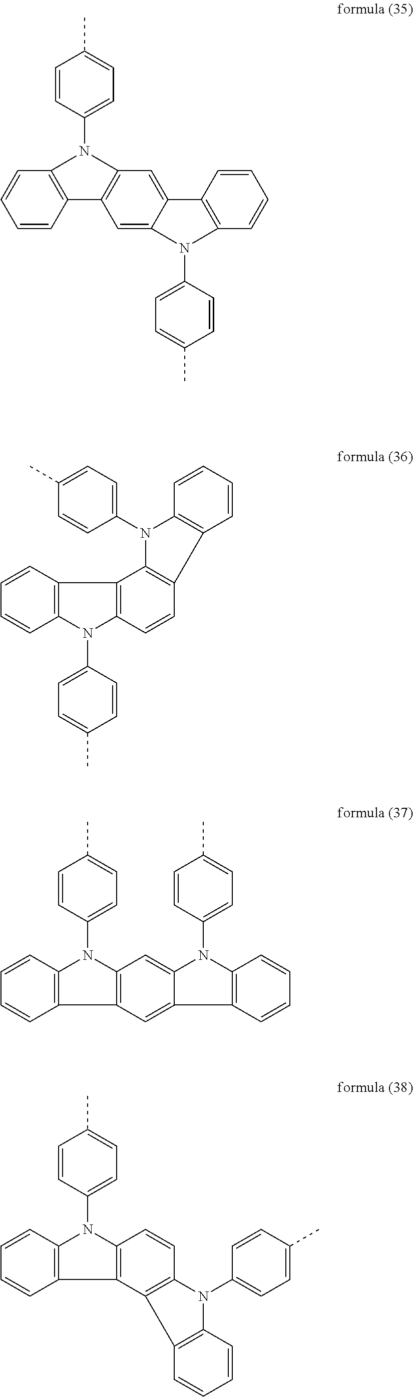 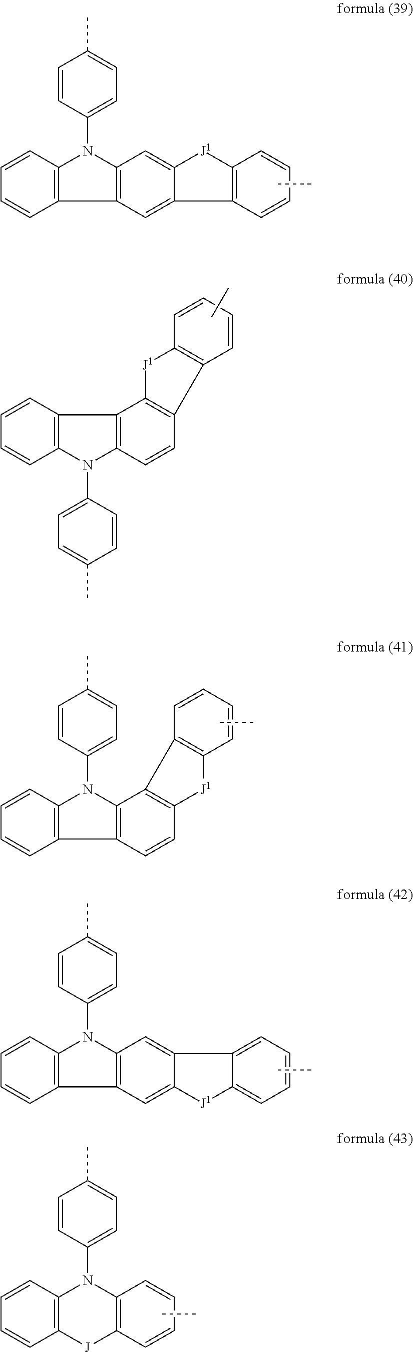 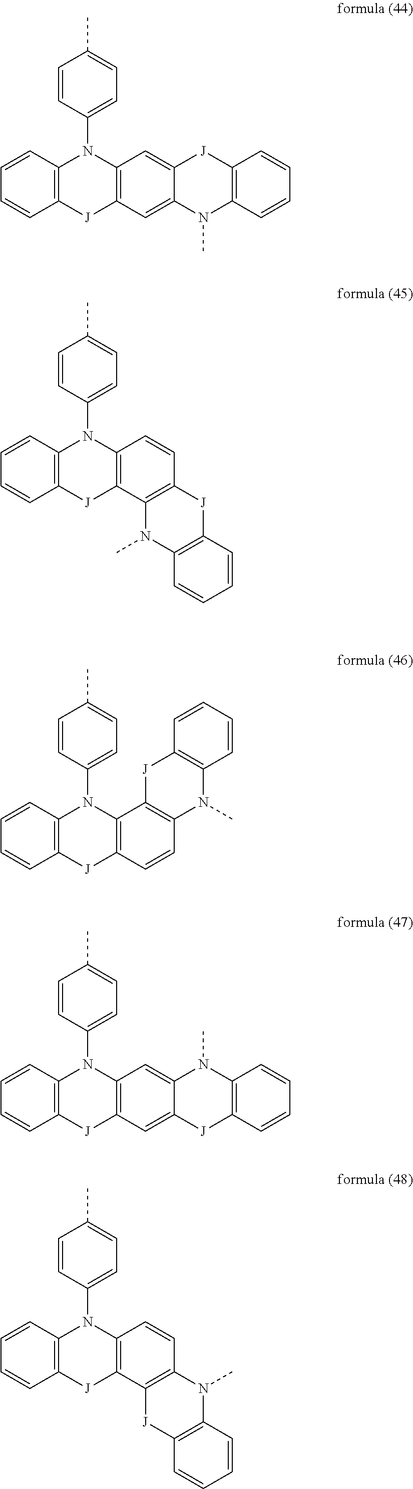
where the symbols and indices have the meaning indicated in claim 20.

25. The copolymer according to claim 20, wherein J is on each occurrence, independently of one another, a single covalent bond or is equal to C(R¹)₂ and J¹ is on each occurrence, identically or differently, C(R¹)₂ and otherwise the symbols and indices have the meaning indicated in claim 20.

26. The copolymer according to claim 20, wherein the copolymer contains at least one structural unit which is different from the formula (1), where the at least one further structural unit is an emitter unit or a hole-transport unit.

27. A compound of the general formula (343) 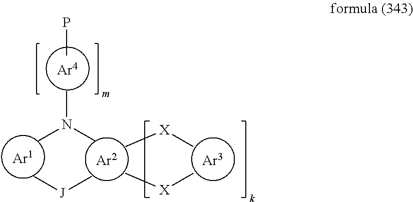
and the following applies to the other symbols and indices:
J is on each occurrence, identically or differently, a single covalent bond or a divalent bridge selected from the group consisting of N(R¹), B(R¹), C(R¹)₂, O, Si(R¹)₂, C═C(R¹)₂, S, S═O, SO₂, P(R¹) and P(═O)R¹;
R¹ is, identically or differently on each occurrence, —H, —F, —Cl, Br, I, —CN, —NO₂, —CF₃, B(OR²)₂, Si(R²)₃, a straight-chain alkyl, alkoxy or thioalkoxy group having 1 to 40 C atoms or a branched or cyclic alkyl, alkoxy or thioalkoxy group having 3 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², O, S, —COO— or CONR² and where one or more H atoms is optionally replaced by D, F, Cl, Br, I, CN or NO₂, or arylamines, or substituted or unsubstituted carbazoles, each of which is optionally substituted by one or more radicals R², or an aryl or heteroaryl group having 5 to 40 ring atoms, which by one or more aromatic;
R² is on each occurrence, identically or differently, H, D or an aliphatic or aromatic hydrocarbon radical having 1 to 20 C atoms or a substituted or unsubstituted aromatic or heteroaromatic ring system having 5 to 40 ring atoms;
X is selected, independently of one another, from 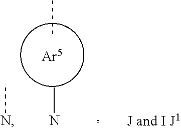
with the proviso that at least one X is not equal to J, where, in the case where k=1 and X is equal to J and J¹, the bonding to an adjacent monomer unit in the polymer takes place via Ar³;
Ar¹-Ar⁵ are selected, identically or differently on each occurrence, from an unsubstituted or R¹-substituted aromatic or heteroaromatic ring system;
J¹ is on each occurrence, identically or differently, a divalent bridge selected from the group consisting of N(R¹), B(R¹), C(R¹)₂, O, Si(R¹)₂, C═C(R¹)₂, S, S═O, SO₂, P(R¹) and P(═O)R¹;
and where the dashed line represents a bond to an adjacent monomer unit in the polymer.
P is in each case, independently of one another, a reactive leaving group;
k is either 0 or 1, where, for k=0, a further reactive leaving group P is bonded to Ar²;
m is either 0 or 1;
X is defined above.

28. The compound according to claim 27 selected from the compounds of the formulae (345) to (352), 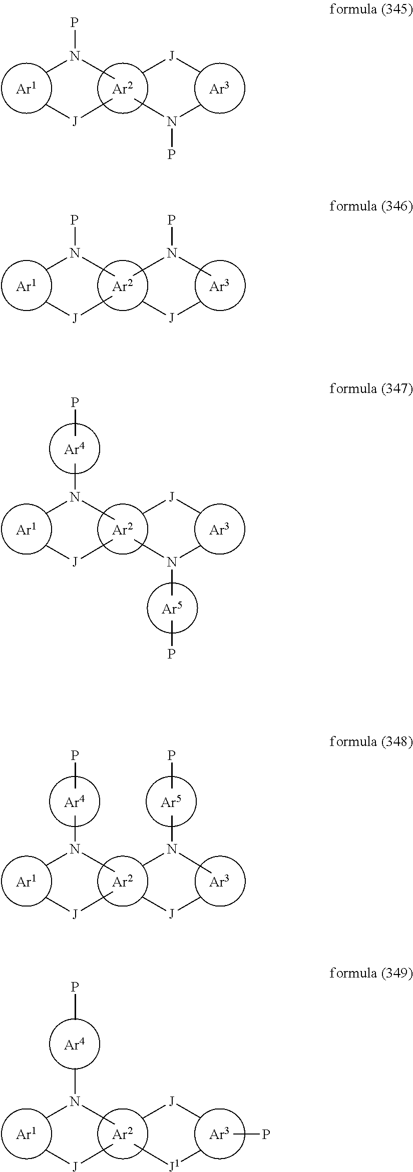 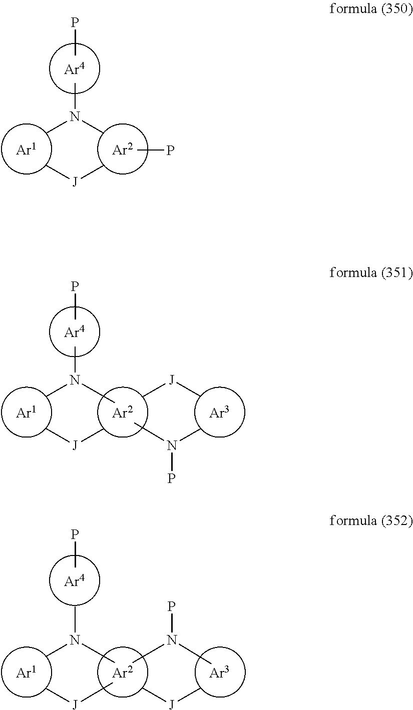
where the symbols and indices have the meaning indicated in claim 27.

29. The compound according to claim 28, wherein P is selected on each occurrence, identically or differently, from Cl, Br, I, O-tosylate, O-triflate, O-mesylate, O-nonaflate, NH,
SiMe₃₋ₙFₙ (n=1 or 2), O—SO₂R¹, B(OR¹)₂, —CR¹═C(R¹)₂, —CΞCH and Sn(R¹)₃, where R¹ has the same meaning as described above and where two or more radicals R¹ may also form a ring system with one another

30. A process for the preparation of the copolymer according to claim 20, wherein the polymer is prepared by SUZUKI, YAMAMOTO, STILLE or HARTWIG-BUCHWALD polymerisation.

31. A mixture of the copolymer according to claim 20 with further polymeric, oligomeric, dendritic and/or low-molecular-weight substances.

32. The mixture according to claim 31, wherein the low-molecular-weight substance is a phosphorescence emitter.

33. A formulation comprising at least one copolymer according to claim 20 and at least one solvent.

34. The formulation as claimed in claim 33, wherein the formulation is a solution, dispersion or miniemulsion.

35. An electronic device comprises the copolymer according to claim 20.

36. An organic electronic device which comprises at least one active layer which comprises at least one copolymer according to claim 20.

37. The device according to claim 36, wherein the device is selected from the group consisting of an organic integrated circuit, an organic field-effect transistor, an organic thin-film transistor, an organic solar cell, an organic dye-sensitised solar cell, an organic optical detector, an organic photoreceptor, an organic field-quench device, an organic laser diode, an organic plasmon emitting device or an organic solar concentrators.

38. The device according to claim 36, wherein the device is an organic electroluminescent, an organic light-emitting electrochemical cell, an organic light-emitting electrochemical transistor or an organic light-emitting transistor.

39. The device according to claim 36, wherein the at least one copolymer are used as matrix material for fluorescent or phosphorescent emitters and/or in an electron-blocking layer and/or in a hole-transport layer or exciton-blocking layer and/or in an electron-transport layer.
